(19) United States
(12) Patent Application Publication
(10) Pub. No.: US 2026/0150301 A1
(43) Pub. Date: May 28, 2026

(54) DIE-TO-WAFER BONDED MEMORY STRUCTURES AND METHODS OF MAKING THE SAME

(71) Applicant: Sandisk Technologies, Inc., Milpitas, CA (US)

(72) Inventors: Qing SHAO, San Jose, CA (US); Guangyuan LI, Santa Clara, CA (US); Yuji TOTOKI, Milpitas, CA (US); Fumiaki TOYAMA, Cupertino, CA (US)

(21) Appl. No.: 18/959,061

(22) Filed: Nov. 25, 2024

(51) Int. Cl. H10B 80/00; H01L 23/00; H01L 25/00; H01L 25/065; H01L 25/18

(52) U.S. Cl. CPC H10B 80/00; H10W 90/00; H10W 80/312; H10W 80/327; H10W 90/291; H10W 90/792

(57) ABSTRACT

A memory die is bonded to a logic die on a wafer by die-to-wafer bonding. The logic die may include surface metal pads having first planar horizontal surfaces located within a horizontal plane including a bonding interface and located within an area not overlapping with an area of the memory die. Alternatively or additionally, electrically conductive paths may be present between sense amplifiers in the logic die and first bit lines in the memory die. The electrically conductive paths may include second bit lines located in the logic die and laterally extending from within an area overlapping with the area of the memory die to an area not overlapping with the area of the memory die in a plan view. One or more memory die can be attached to the logic die.

### FIELD

The present disclosure relates generally to the field of semiconductor devices, and particularly to bonded memory structures formed through die-to-wafer bonding and methods for forming the same.

### BACKGROUND

Flash memory devices include NAND and NOR memory devices. Such memory devices may be formed by sequentially depositing memory device layers over a driver circuit located on a silicon wafer.

### SUMMARY

According to an aspect of the present disclosure, a semiconductor structure comprises: a memory die comprising an array of memory cells and an array of memory-die bonding pads; and a logic die comprising a logic circuit configured to control operation of the array of memory cells, an array of logic-die bonding pads that are bonded to the array of memory-die bonding pads, and surface metal pads having first planar horizontal surfaces located within a horizontal plane including interfaces between the array of logic-die bonding pads and the array of memory-die bonding pads and located within an area not overlapping with an area of the memory die.

According to another aspect of the present disclosure, a method of forming a semiconductor structure comprises: providing a memory die comprising an array of memory cells and an array of memory-die bonding pads; providing a wafer including a two-dimensional array of logic dies, wherein one of the logic dies comprises a logic circuit configured to control operation of the memory die and comprises an array of logic-die bonding pads and surface metal pads that are located at a same level as the array of logic-die bonding pads; bonding the array of memory-die bonding pads of the memory die to the array of logic-die bonding pads of said one of the logic dies by performing a die-to-wafer bonding process, wherein the surface metal pads are located within an area not overlapping with an area of the memory die.

According to yet another aspect of the present disclosure, a semiconductor structure comprises: a memory die comprising a memory array, first bit lines electrically connected to the memory array, and an array of memory-die bonding pads, wherein a first subset of the memory-die bonding pads is electrically connected to a respective one of the first bit lines; and a logic die comprising sense amplifiers, an array of logic-die bonding pads bonded to the memory-die bonding pads, and electrically conductive paths electrically connecting the sense amplifiers to the logic-die bonding pads, wherein the electrically conductive paths comprise second bit lines located between the logic-die bonding pads and the sense amplifiers and laterally extending from within an area of the memory die to an area beyond the memory die.

According to still another aspect of the present disclosure, a method of forming a semiconductor structure comprises: providing a memory die comprising a memory array, first bit lines electrically connected to the memory array, and an array of memory-die bonding pads, wherein a first subset of the memory-die bonding pads is electrically connected to a respective one of the first bit lines; providing a wafer including a two-dimensional array of logic dies, wherein one of the logic dies comprises sense amplifiers, an array of logic-die bonding pads bonded to the memory-die bonding pads, and electrically conductive paths electrically connecting the sense amplifiers to the logic-die bonding pads; and bonding the array of memory-die bonding pads of the memory die to the array of logic-die bonding pads of said one of the logic dies by performing a die-to-wafer bonding process, such that the electrically conductive paths comprise second bit lines located between the logic-die bonding pads and the sense amplifiers and laterally extending from within an area of the memory die to an area beyond the memory die.

According to an aspect of the present disclosure, a semiconductor structure comprises: a logic die comprising sense amplifiers, logic-die bonding pads, and electrically conductive paths electrically connecting the sense amplifiers to the logic-die bonding pads; and a plurality of memory dies bonded to the logic die, wherein each of the plurality of memory dies comprises a respective memory array, a respective set of first bit lines electrically connected to the respective memory array, and a respective array of memory-die bonding pads, wherein each first bit line within the respective set of first bit lines is electrically connected to a respective one of the memory-die bonding pads, wherein: each array of memory-die bonding pads of the plurality of memory dies is bonded to a respective subset of the logic-die bonding pads; the electrically conductive paths comprise second bit lines located between the logic-die bonding pads and the sense amplifiers; and a first subset of the second bit lines laterally extend from within an area of one of the plurality of memory dies to an outside the area of said one of the plurality of memory dies in a plan view along a vertical direction that is perpendicular to an interface between the logic die and the plurality of memory dies.

According to another aspect of the present disclosure, a semiconductor structure comprises: a memory die comprising a memory array containing a plurality of word lines, first bit lines electrically connected to the memory array and laterally extending along a bit line direction, and an array of memory-die bonding pads, wherein a first subset of the memory-die bonding pads is electrically connected to a respective one of the first bit lines, and a second subset of the memory-die bonding pads is electrically connected to a respective one of the word lines; and a logic die comprising sense amplifiers, word line drivers, an array of logic-die bonding pads bonded to the memory-die bonding pads, first electrically conductive paths electrically connecting the sense amplifiers to a first subset the logic-die bonding pads, and second electrically conductive paths electrically connecting the word line drivers to a second subset of the logic-die bonding pads, wherein the electrically conductive paths comprise second bit lines laterally extending along the bit line direction and crossed bit lines laterally extending along a word line direction that is perpendicular to the bit line direction.

According to yet another aspect of the present disclosure, a method of forming a semiconductor structure comprises: providing a plurality of memory dies, wherein each of the memory dies comprises a memory array, first bit lines electrically connected to the memory array, and an array of memory-die bonding pads, wherein a first subset of the memory-die bonding pads is electrically connected to a respective one of the first bit lines; providing a wafer supporting a two-dimensional array of logic dies, wherein one of the logic dies comprises sense amplifiers, an array of logic-die bonding pads bonded to the memory-die bonding pads, and electrically conductive paths electrically connecting the sense amplifiers to the logic-die bonding pads and comprising second bit lines; and bonding the plurality of memory dies to said one of the logic dies by performing a plurality of die-to-wafer bonding processes such that a subset of the second bit lines laterally extend from first areas having an areal overlap with the plurality of memory dies to a second area not having any areal overlap with the plurality of memory dies in a plan view along a vertical direction that is perpendicular to interfaces between the logic die and the plurality of memory dies.

### BRIEF DESCRIPTION OF THE DRAWINGS

FIG. 1 is a vertical cross-sectional view of a region of an in-process memory die after formation of a first-tier alternating stack, first stepped surfaces, and a first-tier stepped dielectric material portion according to a first embodiment of the present disclosure.

FIG. 2A is a vertical cross-sectional view of a region of the in-process memory die after formation of first-tier memory openings and first-tier support openings according to the first embodiment of the present disclosure. FIG. 2B is a top-down view of the region of the in-process memory die of FIG. 2A. The hinged vertical plane A-A′ is the cut plane of the vertical cross-sectional view of FIG. 2A.

FIG. 3 is a vertical cross-sectional view of a region of the in-process memory die after formation of first sacrificial opening fill structures according to the first embodiment of the present disclosure.

FIG. 4 is a vertical cross-sectional view of a region of the in-process memory die after formation of a second-tier alternating stack, a second-tier stepped dielectric material portion, second-tier memory openings, second-tier support openings, and second sacrificial opening fill structures according to the first embodiment of the present disclosure.

FIG. 5 is a vertical cross-sectional view of a region of the in-process memory die after formation of support pillar structures according to the first embodiment of the present disclosure.

FIG. 6 is a vertical cross-sectional view of a region of the in-process memory die after formation of inter-tier memory openings according to the first embodiment of the present disclosure.

FIGS. 7A-7E are sequential vertical cross-sectional views of a memory opening during formation of a memory opening fill structure according to an embodiments of the present disclosure.

FIG. 8A is a schematic vertical cross-sectional view of a region of the in-process memory die after formation of memory opening fill structures according to the first embodiment of the present disclosure. FIG. 8B is a top-down view of the region of the in-process memory die of FIG. 8A. The vertical plane A-A is the cut plane of the vertical cross-sectional view of FIG. 8A.

FIG. 9A is a vertical cross-sectional view of a region of the in-process memory die after formation of lateral isolation trenches according to the first embodiment of the present disclosure. FIG. 9B is a top-down view of the region of the in-process memory die of FIG. 9A. The vertical plane A-A is the cut plane of the vertical cross-sectional view of FIG. 9A.

FIG. 10 is a vertical cross-sectional view of a region of the in-process memory die after formation of laterally-extending cavities according to the first embodiment of the present disclosure.

FIG. 11A is a schematic vertical cross-sectional view of a region of the in-process memory die after formation of electrically conductive layers according to the first embodiment of the present disclosure. FIG. 11B is a magnified view of a region of a region of the in-process memory die of FIG. 11A around a memory opening fill structure.

FIG. 12A is a schematic vertical cross-sectional view of a region of the in-process memory die after formation of lateral isolation trench fill structures, layer contact via structures, drain contact via structures, and through-memory-level connection via structures according to the first embodiment of the present disclosure. FIG. 12B is a top-down view of the region of the in-process memory die of FIG. 12A. The vertical plane A-A is the cut plane of the vertical cross-sectional view of FIG. 12A.

FIG. 13A is a schematic vertical cross-sectional view of a region of the in-process memory die after formation of drain-connection via structures, first bit lines, and first-bit-line-level interconnect structures according to the first embodiment of the present disclosure. FIG. 13B is a top-down view of the region of the in-process memory die of FIG. 13A. The vertical plane A-A is the cut plane of the vertical cross-sectional view of FIG. 13A.

FIG. 14A is a vertical cross-sectional view of a region of a memory die after formation of memory-die dielectric material layers embedding memory-die metal interconnect structures and memory-die bonding pads to provide a memory die according to the first embodiment of the present disclosure. FIG. 14B is a top-down view of the region of the memory die of FIG. 14A. The vertical plane A-A is the cut plane of the vertical cross-sectional view of FIG. 14A.

FIG. 15 is a vertical cross-sectional view of a memory die, which may be obtained by dicing a wafer a two-dimensional array of memory dies.

FIG. 16A is a top-down view of a wafer supporting a two-dimensional array of logic dies according to the first embodiment of the present disclosure. FIG. 16B is a vertical cross-sectional view of a region of the wafer along the vertical plane B-B′ of FIG. 16A. FIG. 16C is a top down view of a logic die within the wafer in FIG. 16A.

FIG. 17A is a top-down view of the wafer supporting the two-dimensional array of logic dies after formation of a passivation dielectric layer thereupon according to the first embodiment of the present disclosure. FIG. 17B is a vertical cross-sectional view of a region of the wafer along the vertical plane B-B′ of FIG. 17A. FIG. 17C is a top down view of a logic die within the wafer in FIG. 17A.

FIG. 18A is a top-down view of a first exemplary structure including a bonded assembly of the wafer and a two-dimensional array of memory dies according to the first embodiment of the present disclosure. FIG. 18B is a vertical cross-sectional view of a region of the wafer along the vertical plane B-B′ of FIG. 18A. FIG. 18C is a top down view of a logic die within the wafer in FIG. 18A.

FIG. 19 is a vertical cross-sectional view of a region of the first exemplary structure after formation of a molding compound matrix according to the first embodiment of the present disclosure.

FIG. 20A is a vertical cross-sectional view of a region of the first exemplary structure after grinding a backside of a reconstituted wafer according to the first embodiment of the present disclosure. FIG. 20B is a vertical cross-sectional view of a region of bonded assembly of a logic die and a memory die within the reconstituted wafer of FIG. 20A.

FIG. 21A is a vertical cross-sectional view of a region of the first exemplary structure after formation of a backside insulating layer and backside bonding pads according to the first embodiment of the present disclosure. FIG. 21B is a vertical cross-sectional view of a region of bonded assembly of a logic die and a memory die within the reconstituted wafer of FIG. 20A. FIG. 21C is a top down view of a unit bonded assembly within the reconstituted wafer in FIG. 21A.

FIG. 22 is a vertical cross-sectional view of a bonded assembly that is obtained by dicing the reconstituted wafer illustrated in FIGS. 21A-21C according to the first embodiment of the present disclosure.

FIG. 23A is a top-down view of a wafer supporting a two-dimensional array of logic dies according to the second embodiment of the present disclosure. FIG. 23B is a vertical cross-sectional view of a region of the wafer along the vertical plane B-B′ of FIG. 23A that extends along the word line direction wld. FIG. 23C is a top down view of a logic die supported by the wafer of FIG. 23A. FIG. 23D is a magnified view of region D in FIG. 23C.

FIG. 24A is a top-down view of a second exemplary structure including a bonded assembly of the wafer and a two-dimensional array of memory dies according to the second embodiment of the present disclosure. FIG. 24B is a vertical cross-sectional view of a region of the wafer of FIG. 24A along the vertical plane B-B′ of FIG. 24A that extends along the word line direction wld. FIG. 24C is a vertical cross-sectional view of a region of the wafer of FIG. 24A along the vertical plane C-C′ of FIG. 24A that extends along the bit line direction bld. FIG. 24D is a partial see-through top down view of a logic die supported by the wafer of FIG. 24A.

FIG. 25 is a vertical cross-sectional view along the bit line direction bld of a region of the second exemplary structure after formation of a molding compound matrix according to the second embodiment of the present disclosure.

FIG. 26A is a vertical cross-sectional view along the bit line direction bld of a region of the second exemplary structure after grinding a backside of a reconstituted wafer according to the second embodiment of the present disclosure. FIG. 26B is a vertical cross-sectional view along the word line direction wld of a region of bonded assembly of a logic die and a memory die within the reconstituted wafer of FIG. 26A.

FIG. 27A is a vertical cross-sectional view along the bit line direction bld of a region of the second exemplary structure after formation of a backside insulating layer and backside bonding pads according to the second embodiment of the present disclosure. FIG. 27B is a vertical cross-sectional view along the word line direction wld of a region of bonded assembly of a logic die and a memory die within the reconstituted wafer of FIG. 27A.

FIG. 28 is a vertical cross-sectional view along the bit line direction bld of a bonded assembly that is obtained by dicing the reconstituted wafer illustrated in FIGS. 27A and 27B according to the second embodiment of the present disclosure.

FIG. 29A is a partially transparent top-down view of the bonded assembly of the second embodiment of the present disclosure. FIG. 29B is a vertical cross-sectional view along the word line direction wld of a region of the assembly of FIG. 29A along the vertical plane B-B′ of FIG. 29A which extends along the word line direction bld. FIG. 29C is a vertical cross-sectional view along the bit line direction bld of a region of the assembly of FIG. 29A along the vertical plane C-C′ of FIG. 29A which extends along the bit line direction bld. FIG. 29D is a schematic vertical cross-sectional view along the bit line direction bld of a region of the assembly of FIG. 29A along the vertical plane C-C′ of FIG. 29A which extends along the bit line direction bld.

FIG. 30A is a first vertical cross-sectional view of an alternative configuration of the bonded assembly of the second embodiment of the present disclosure. FIG. 30B is a second vertical cross-sectional view of the alternative configuration of the bonded assembly of the second embodiment of the present disclosure. FIG. 30C is a partially transparent top-down view of the alternative configuration of the bonded assembly of FIGS. 30A and 30B. The vertical plane A-A′ is the cut plane of the first vertical cross-sectional view of FIG. 30A. The vertical plane B-B′ is the cut plane of the second vertical cross-sectional view of FIG. 30B.

FIG. 31A is a top-down view of a third exemplary structure including a bonded assembly of the wafer and a two-dimensional array of memory dies according to the third embodiment of the present disclosure. FIG. 31B is a vertical cross-sectional view of a region of the wafer of FIG. 31A along the vertical plane B-B′ of FIG. 31A that extends along the word line direction wld. FIG. 31C is a vertical cross-sectional view of a region of the wafer of FIG. 31A along the vertical plane C-C′ of FIG. 31A that extends along the bit line direction bld. FIG. 31D is a partial see-through top-down view of a logic die supported by the wafer of FIG. 31A.

FIG. 32 is a vertical cross-sectional view along the bit line direction bld of a region of the third exemplary structure after formation of a molding compound matrix according to the third embodiment of the present disclosure.

FIG. 33 is a vertical cross-sectional view along the bit line direction bld of a region of the third exemplary structure after grinding a backside of a reconstituted wafer according to the third embodiment of the present disclosure.

FIG. 34 is a vertical cross-sectional view along the bit line direction bld of a region of the third exemplary structure after formation of a backside insulating layer and backside bonding pads according to the third embodiment of the present disclosure.

FIG. 35 is a vertical cross-sectional view along the bit line direction bld of a bonded assembly that is obtained by dicing the reconstituted wafer illustrated in FIG. 34 according to the third embodiment of the present disclosure.

### DETAILED DESCRIPTION

Die-to-wafer bonding can be advantageous for the manufacture of symmetric bonded memory structures. For example, memory dies can be tested and sorted for functionality, and only functional memory dies are then bonded to logic dies located on a logic wafer. In this case, each memory die can have a smaller area than the respective mating logic die. However, differences in the die sizes in a mating pair of a memory die and a logic die can lead to inefficient use of space and complications during the bonding process. Additionally, the differences in die sizes make electrical connection and signal routing between the logic die and the memory die more difficult. The embodiments of the present disclosure are directed to bonded memory structures formed by die-to-wafer bonding and methods for forming the same which more efficiently utilize die space and include improved connections between the logic die and the memory die.

The drawings are not drawn to scale. Multiple instances of an element may be duplicated where a single instance of the element is illustrated, unless the absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased in a single erase operation. Each block contains a number of pages, which are the smallest unit that can be programmed, i.e., a smallest unit on which a read operation can be performed.

As used herein, a “semiconducting material” refers to a material having electrical conductivity in the range from 1×10⁻⁵ S/m to 1×10⁵ S/m. As used herein, a “semiconductor material” refers to a material having electrical conductivity in the range from 1×10⁻⁵ S/m to 1 S/m in the absence of electrical dopants therein, and is capable of producing a doped material having electrical conductivity in a range from 1 S/m to 1×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1×10⁵ S/m. As used herein, an “insulator material” or a “dielectric material” refers to a material having electrical conductivity less than 1×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1×10⁻⁵ S/m to 1×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

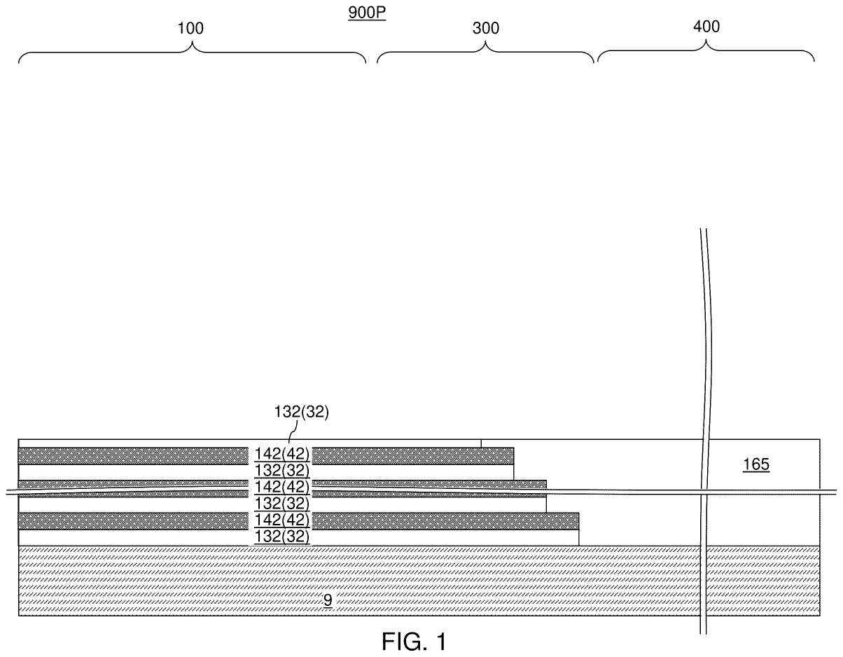

Referring to FIG. 1, an in-process memory die 900P according to a first embodiment of the present disclosure is illustrated. Generally, a plurality of memory dies can be manufactured on a wafer. The in-process memory die 900P illustrated in FIG. 1 is a portion of one die area located on a wafer which contains a two-dimensional array of die areas. Thus, multiple instances of the in-process memory die 900P illustrated in FIG. 1 may be repeated as a two-dimensional array of in-process memory dies. The in-process memory dies are processed through a sequence of processing steps described below to provide a wafer supporting an array of completed memory dies. The in-process memory die 900P is located on a substrate 9, which may be a semiconductor substrate. The substrate 9 of each in-process memory die 900P can be a portion of the wafer, which may be a commercially available silicon wafer. In one embodiment, the substrate 9 may be a carrier substrate that is subsequently removed. Each in-process memory die 900P comprises a memory array region 100 in which a three-dimensional memory array is subsequently formed, a contact region 300 in which stepped surfaces and layer contact via structures are subsequently formed, and a peripheral region 400 in which connection via structures are subsequently formed.

A first alternating stack of insulating layers 32 and spacer material layers can be formed over the substrate 9. The spacer material layers may be formed as sacrificial material layers 42. In case a second alternating stack of additional insulating layers and additional spacer material layers is subsequently formed over the first alternating stack to form a multi-tier structure, the first alternating stack is referred to as a first-tier alternating stack, and the second alternating stack is referred to as a second-tier alternating stack. In this case, the insulating layers 32 within the first-tier alternating stack are herein referred to as first insulating layers 132, and spacer material layers (such as the sacrificial material layers 42) within the first-tier alternating stack are herein referred to as first spacer material layers (such as first sacrificial material layers 142).

The first insulating layers 132 comprise an insulating material such as undoped silicate glass or a doped silicate glass, and the first sacrificial material layers 142 comprise a sacrificial material such as silicon nitride or a silicon-germanium alloy. In one embodiment, the first insulating layers 132 may comprise silicon oxide layers, and the first sacrificial material layers 142 may comprise silicon nitride layers. The first-tier alternating stack (132, 142) may comprise multiple repetitions of a unit layer stack including a first insulating layer 132 and a first sacrificial material layer 142. The total number of repetitions of the unit layer stack within the first-tier alternating stack (132, 142) may be, for example, in a range from 8 to 1,024, such as from 32 to 256, although lesser and greater number of repetitions may also be employed.

Each of the first insulating layers 132 may have a thickness in a range from 20 nm to 100 nm, such as from 30 nm to 60 nm, although lesser and greater thicknesses may also be employed. Each of the first sacrificial material layers 142 may have a thickness in a range from 20 nm to 100 nm, such as from 30 nm to 60 nm, although lesser and greater thicknesses may also be employed. The in-process memory die 900P comprises a memory array region 100 in which a three-dimensional array of memory elements is to be subsequently formed, and a contact region 300 in which layer contact via structures contacting word lines are to be subsequently formed.

While an embodiment is described in which the first spacer material layers are formed as first sacrificial material layers 142, the first spacer material layers may be formed as first electrically conductive layers in an alternative embodiment. In this case, processing steps performed to replace the first sacrificial material layers 142 with first electrically conductive layers may be omitted. Generally, spacer material layers may be formed as or may be subsequently replaced with electrically conductive layers.

Optional stepped surfaces are formed in the contact region 300. As used herein, “stepped surfaces” refer to a set of surfaces that include at least two horizontal surfaces and at least two vertical surfaces such that each horizontal surface is adjoined to a first vertical surface that extends upward from a first edge of the horizontal surface, and is adjoined to a second vertical surface that extends downward from a second edge of the horizontal surface. A first stepped cavity is formed within the volume from which portions of the first-tier alternating stack (132, 142) are removed through formation of the stepped surfaces. A “stepped cavity” refers to a cavity having stepped surfaces.

The first stepped cavity can have various stepped surfaces such that the horizontal cross-sectional shape of the first stepped cavity changes in steps as a function of the vertical distance from the top surface of the substrate 9. In one embodiment, the first stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each first sacrificial material layer 142 other than a topmost first sacrificial material layer 142 within the alternating stack (132, 142) laterally extends farther than any overlying first sacrificial material layer 142 within the first-tier alternating stack (132, 142) in the terrace region. The stepped surfaces of the first-tier alternating stack (132, 142) continuously extend from a bottommost layer within the first-tier alternating stack (132, 142) to a topmost layer within the first-tier alternating stack (132, 142).

A first stepped dielectric material portion 165 (i.e., an insulating fill material portion) can be formed in the first stepped cavity by deposition of a dielectric material therein. For example, a dielectric material such as silicon oxide can be deposited in the stepped cavity. Excess portions of the deposited dielectric material can be removed from above the top surface of the topmost layer of the first-tier alternating stack (132, 142), for example, by chemical mechanical planarization (CMP). The remaining portion of the deposited dielectric material filling the first stepped cavity constitutes the first stepped dielectric material portion 165. As used herein, a “stepped” element refers to an element that has stepped surfaces and a horizontal cross-sectional area that increases or decreases stepwise as a function of a vertical distance from a top surface of a substrate on which the element is present. If silicon oxide is employed for the first stepped dielectric material portion 165, the silicon oxide of the first stepped dielectric material portion 165 may, or may not, be doped with dopants such as B, P, and/or F.

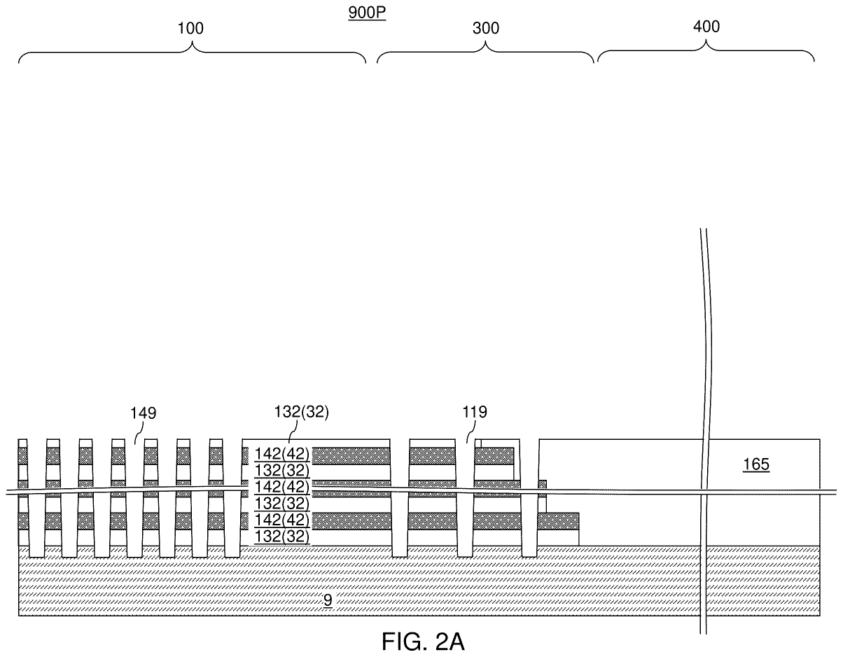

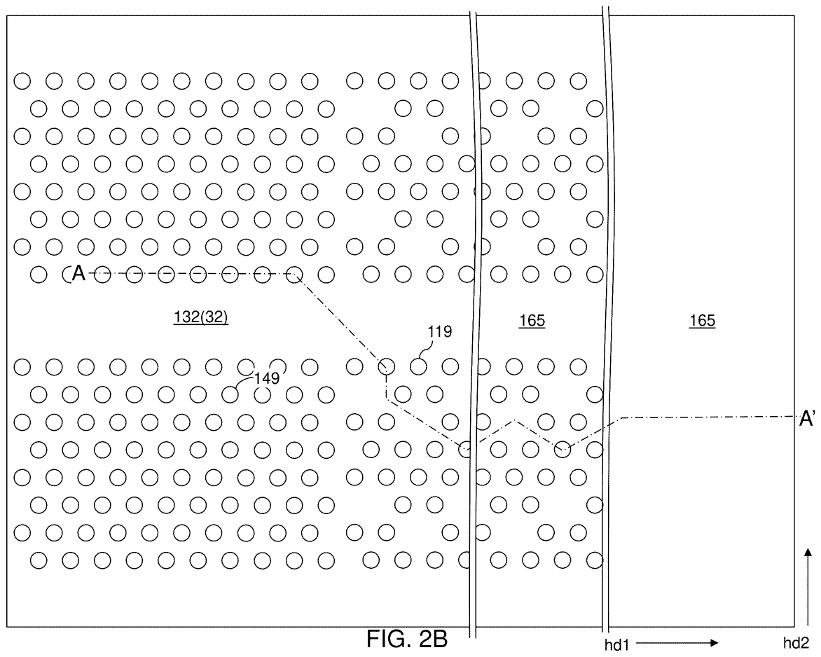

Referring to FIGS. 2A and 2B, a first etch mask layer (such as a photoresist layer) can be formed over the first-tier alternating stack (132, 142), and can be lithographically patterned to form openings therein. A first anisotropic etch process can be performed to transfer the pattern of the openings in the first etch mask layer through the first stepped dielectric material portion 165, and the first-tier alternating stack (132, 142), and into the substrate 9. First-tier memory openings 149 can be formed through the first-tier alternating stack (132, 142) in the memory array region 100, and first-tier support openings 119 can be formed through the first stepped dielectric material portion 165 and the first-tier alternating stack (132, 142) in the contact region 300. Each of the first-tier memory openings 149 and the first-tier support openings 119 can vertically extend into the substrate 9. In one embodiment, bottom surfaces of the first-tier memory openings 149 and the first-tier support openings 119 may be formed within the lower source-level semiconductor layer 112. The first-tier memory openings 149 and the first-tier support openings 119 may have a diameter in a range from 40 nm to 400 nm, such as from 80 nm to 200 nm, although lesser and greater thicknesses may be employed. The first etch mask layer can be removed, for example, by ashing after the first anisotropic etch process.

The first-tier memory openings 149 may be formed as clusters of first-tier memory openings 149. Each cluster of first-tier memory openings 149 may comprise an area of a memory block containing a plurality of rows of memory openings 49. Each row of first-tier memory openings 149 may comprise a plurality of first-tier memory openings 149 that are arranged along the first horizontal direction hd1 (which may be a word line direction) with a uniform pitch. The rows of first-tier memory openings 149 may be laterally spaced from each other along the second horizontal direction hd2 (which may be a bit line direction), which may be perpendicular to the first horizontal direction hd1. In one embodiment, each cluster of first-tier memory openings 149 may be formed as a two-dimensional periodic array of first-tier memory openings 149.

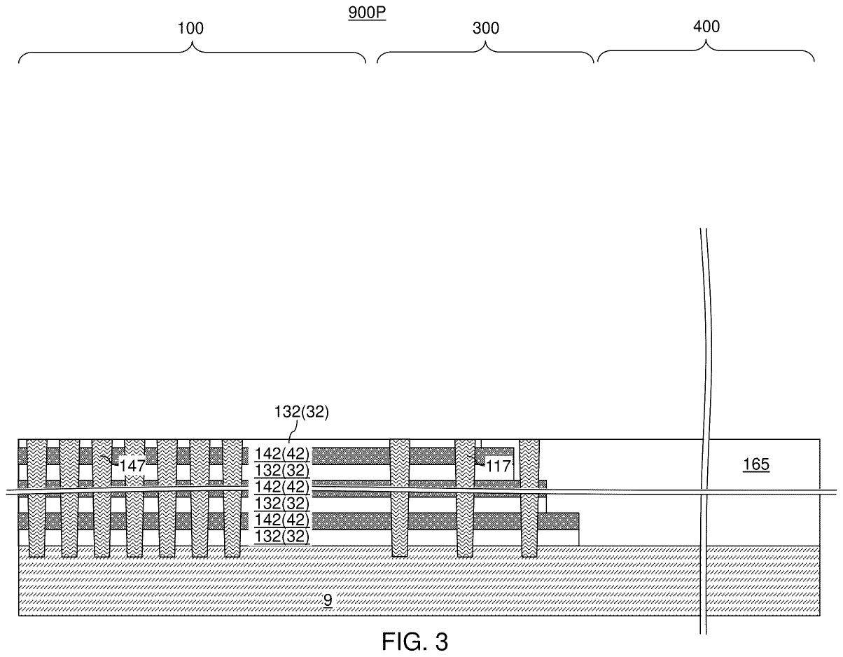

Referring to FIG. 3, a first sacrificial fill material, such as a carbon-based material (e.g., amorphous carbon, diamond-like carbon, or a doped carbon material), a high etch-rate dielectric material (e.g., borosilicate glass or organosilicate glass), or a polymer material, can be deposited in the first-tier memory openings 149 and in the first-tier support openings 119 by a conformal deposition process. Excess portions of the first sacrificial fill material can be removed from above the top surface of the first-tier alternating stack (132, 142), for example, by a recess etch process. Each remaining portion of the first sacrificial fill material that fills a respective first-tier memory opening 149 constitutes a first sacrificial memory opening fill structure 147. Each remaining portion of the first sacrificial fill material that fills a respective first-tier support opening 119 constitutes a first sacrificial support opening fill structure 117.

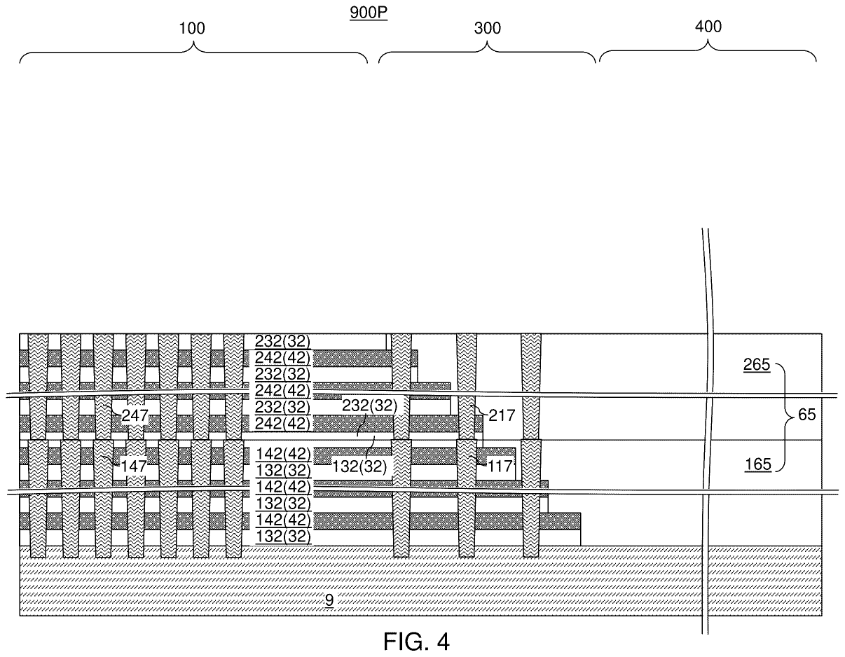

Referring to FIG. 4, a second-tier alternating stack (232, 242) of second insulating layers 232 and second spacer material layers may be formed above the first-tier alternating stack (132, 142) and the first stepped dielectric material portion 165. The second insulating layers 232 can be additional insulating layers 32 having a same material composition and a same thickness range as the first insulating layers 132. The second spacer material layers can be additional spacer material layers having a same material composition and a same thickness range as the first spacer material layers in the first-tier alternating stack (132, 142). In one embodiment, the second spacer material layers may comprise second sacrificial material layers 242. In this case, the second sacrificial material layers 242 can be additional sacrificial material layers 42 having a same material composition and a same thickness range as the first sacrificial material layers 142.

The second-tier alternating stack (232, 242) may comprise multiple repetitions of a unit layer stack including a second insulating layer 232 and a second sacrificial material layer 242. The total number of repetitions of the unit layer stack within the second-tier alternating stack (232, 242) may be, for example, in a range from 8 to 1,024, such as from 32 to 256, although lesser and greater number of repetitions may also be employed. Each of the second insulating layers 232 may have a thickness in a range from 20 nm to 100 nm, such as from 30 nm to 60 nm, although lesser and greater thicknesses may also be employed. Each of the second sacrificial material layers 242 may have a thickness in a range from 20 nm to 100 nm, such as from 30 nm to 60 nm, although lesser and greater thicknesses may also be employed.

The first-tier alternating stack (132, 142) and the second-tier alternating stack (232, 242) are collectively referred to as an alternating stack (32, 42) of insulating layers 32 and sacrificial material layers 42.

While an embodiment is described in which the second spacer material layers are formed as second sacrificial material layers 242, the second spacer material layers may be formed as second electrically conductive layers in an alternative embodiment. In this case, processing steps performed to replace the second sacrificial material layers 242 with second electrically conductive layers may be omitted.

Optional stepped surfaces are formed in the contact region 300 by patterning the second-tier alternating stack (232, 242). The stepped surfaces of the second-tier alternating stack (232, 242) may be laterally offset toward the memory array region 100 relative to the stepped surfaces of the first-tier alternating stack (132, 142) in a plan view. A second stepped cavity is formed within the volume from which portions of the second-tier alternating stack (232, 242) are removed through formation of the stepped surfaces. A “stepped cavity” refers to a cavity having stepped surfaces.

The second stepped cavity can have various stepped surfaces such that the horizontal cross-sectional shape of the second stepped cavity changes in steps as a function of the vertical distance from the top surface of the substrate 9. In one embodiment, the second stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type.

Each second sacrificial material layer 242 other than a topmost second sacrificial material layer 242 within the alternating stack (232, 242) laterally extends farther than any overlying second sacrificial material layer 242 within the second-tier alternating stack (232, 242) in the terrace region. The stepped surfaces of the second-tier alternating stack (232, 242) continuously extend from a bottommost layer within the second-tier alternating stack (232, 242) to a topmost layer within the second-tier alternating stack (232, 242).

A second stepped dielectric material portion 265 (i.e., an insulating fill material portion) can be formed in the second stepped cavity by deposition of a dielectric material therein. For example, a dielectric material such as silicon oxide can be deposited in the stepped cavity. Excess portions of the deposited dielectric material can be removed from above the top surface of the topmost layer of the second-tier alternating stack (232, 242), for example, by chemical mechanical planarization (CMP). The remaining portion of the deposited dielectric material filling the second stepped cavity constitutes the second stepped dielectric material portion 265. If silicon oxide is employed for the second stepped dielectric material portion 265, the silicon oxide of the second stepped dielectric material portion 265 may, or may not, be doped with dopants such as B, P, and/or F. The combination of the first stepped dielectric material portion 165 and the second stepped dielectric material portion 265 may be collectively referred to as stepped dielectric material portions 65.

A second etch mask layer (such as a photoresist layer) can be formed over the second-tier alternating stack (232, 242), and can be lithographically patterned to form openings therein. A second anisotropic etch process can be performed to transfer the pattern of the openings in the second etch mask layer through the second stepped dielectric material portion 265 and the second-tier alternating stack (232, 242). Second-tier memory openings can be formed through the second-tier alternating stack (232, 242) directly on a top surface of a respective first sacrificial memory opening fill structure 147 in the memory array region 100. Second-tier support openings can be formed through the second stepped dielectric material portion 265 and the second-tier alternating stack (232, 242) directly on a top surface of a respective first sacrificial support opening fill structure 117 in the contact region 300. each of the second-tier memory openings and the second-tier support openings may have about the same diameter as the diameter of a respective underlying first sacrificial opening fill structure (147, 117). The second etch mask layer can be removed, for example, by ashing after the second anisotropic etch process.

A second sacrificial fill material, such as a carbon-based material (e.g., amorphous carbon, diamond-like carbon, or a doped carbon material), a high etch-rate dielectric material (e.g., borosilicate glass or organosilicate glass), or a polymer material, can be deposited in the second-tier memory openings and in the second-tier support openings by a conformal deposition process. Excess portions of the second sacrificial fill material can be removed from above the top surface of the second-tier alternating stack (232, 242), for example, by a recess etch process. Each remaining portion of the second sacrificial fill material that fills a respective second-tier memory opening constitutes a second sacrificial memory opening fill structure 247. Each remaining portion of the second sacrificial fill material that fills a respective second-tier support opening constitutes a second sacrificial support opening fill structure 217.

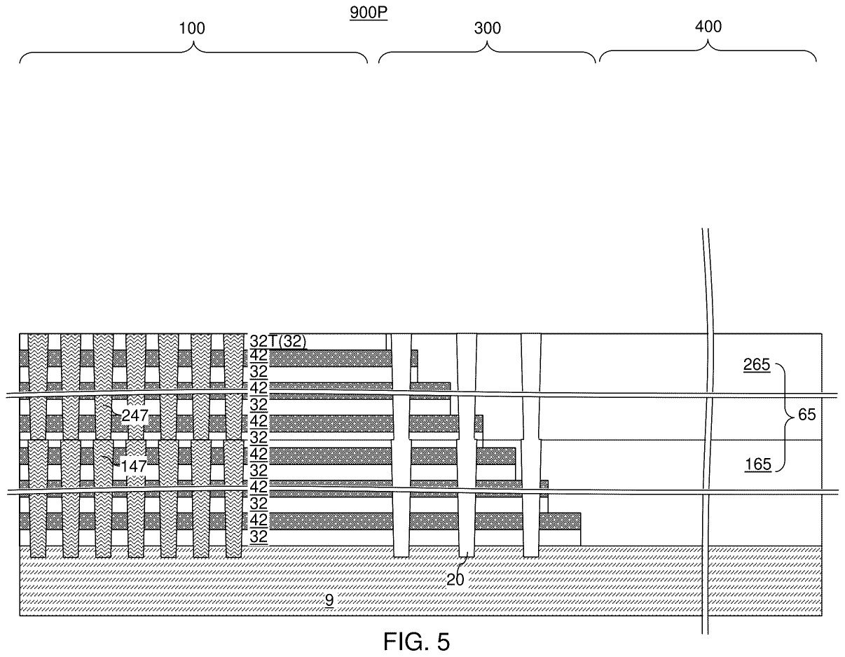

Referring to FIG. 5, a sacrificial mask layer (not shown) is formed over the memory array region 100. The exposed first and second sacrificial support opening fill structures (117, 217) in the contact region 300 are removed by selective etching or ashing to reopen the first-tier and second-tier support openings. A dielectric material, such as silicon oxide is deposited in the first-tier and second-tier support openings to form support pillar structures 20. The sacrificial mask layer is then removed by selective etching or ashing.

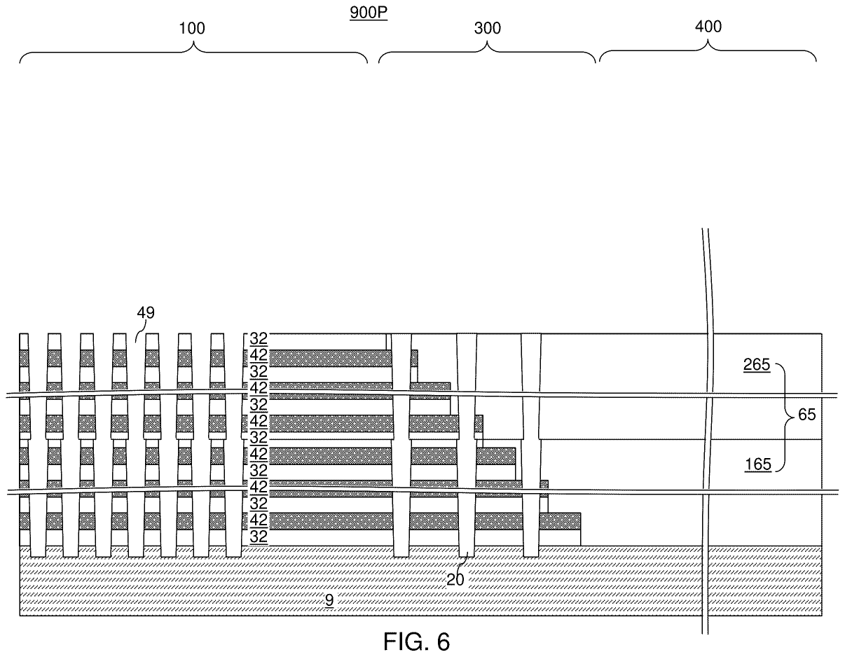

Referring to FIG. 6, the sacrificial memory opening fill structures (147, 247) in the memory array region 100 can be removed selectively to the materials of the stepped dielectric material portions 65, the support pillar structures 20, and the alternating stack (32, 42). For example, a selective etch process or an ashing process may be employed to remove the sacrificial memory opening fill structures and portions of the optional etch stop liner in the memory array region 100. Voids are formed in the volumes of the memory openings 49.

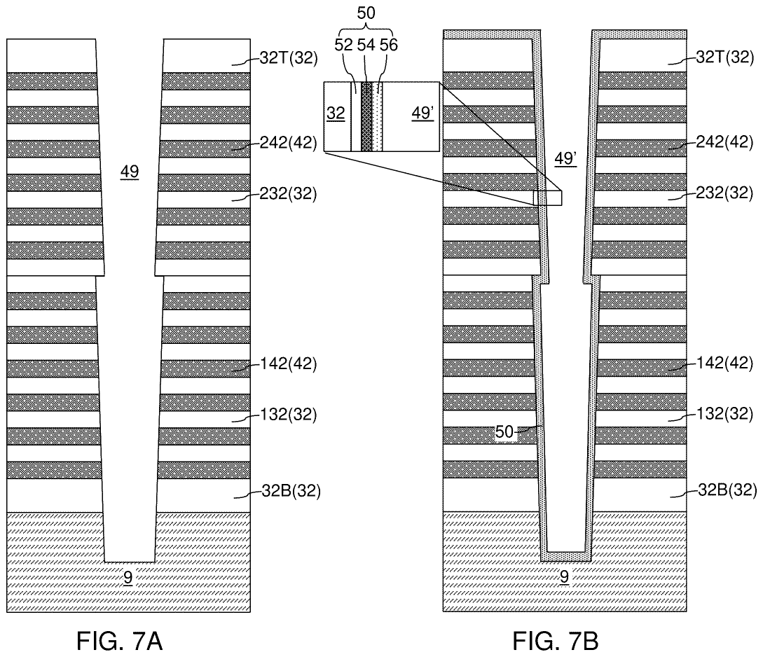

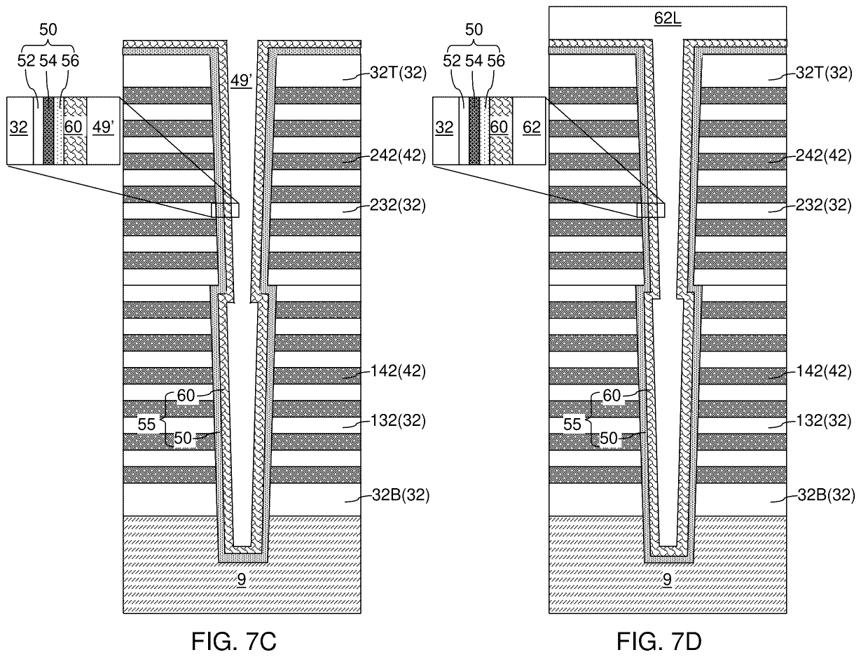

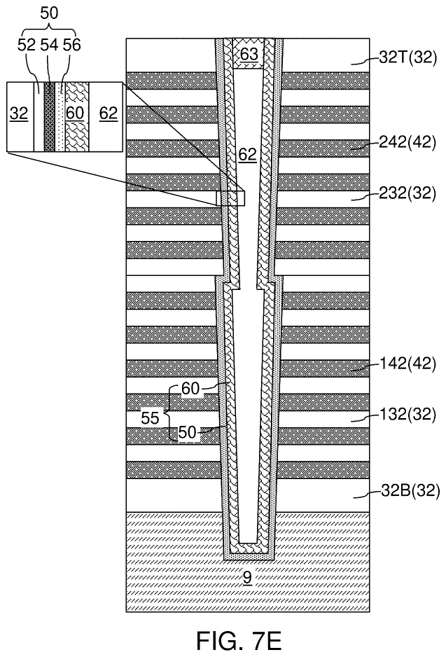

FIGS. 7A-7E are sequential vertical cross-sectional views of a memory opening 49 during formation of a memory opening fill structure 58.

Referring to FIG. 7A, a memory opening 49 is illustrated after the processing steps of FIG. 6. Each memory opening 49 vertically extends through each layer within the alternating stack (32, 42). The bottommost layer of the alternating stack (32, 42) may be a bottommost insulating layer 32B, and the topmost layer of the alternating stack (32, 42) may be a topmost insulating layer 32T.

Referring to FIG. 7B, a layer stack including a memory material layer 54 can be conformally deposited. In an illustrative example, the layer stack may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride), a ferroelectric material, a phase change memory material, or any other memory material that can store data bits by inducing a change in the electrical resistivity, ferroelectric polarization, or any other measurable physical property. In case the memory material layer 54 comprises a charge storage material, the optional dielectric liner 56 may comprise a tunneling dielectric layer. A memory cavity 49′ is present in an unfilled volume of the memory opening 49.

Referring to FIG. 7C, a semiconductor channel material layer 60L can be deposited over each memory film 50 by performing a conformal deposition process. If the semiconductor channel material layer 60L is doped, the semiconductor channel material layer 60L may have a doping of a first conductivity type, which may be p-type or n-type. The thickness of the semiconductor channel material layer 60L may be in a range from 5 nm to 50 nm, such as from 10 nm to 30 nm, although lesser and greater thicknesses may also be employed.

Referring to FIG. 7D, a dielectric core layer 62L comprising a dielectric fill material, such as silicon oxide, can be deposited in remaining volumes of the memory openings 49. While the dielectric core layer 62L can be deposited employing a conformal deposition process, such as a chemical vapor deposition process, the conformity of the conformal deposition process may not be perfect. Thus, the thickness of a bottom portion of the dielectric core layer 62L at the bottom of each memory opening 49 may be less than the thickness of an upper portion of the dielectric core layer 62L at the top of each memory opening 49.

Referring to FIG. 7E, the dielectric core layer 62L can be vertically recessed such that each remaining portion of the dielectric core layer has a top surface at, or about, the horizontal plane including the bottom surface of the topmost insulating layers 32. Each remaining portion of the dielectric core layer constitutes a dielectric core 62. A doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5×10¹⁸/cm³ to 2×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel material layer 60L can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel material layer 60L (which has a doping of the first conductivity type) constitutes a vertical semiconductor channel 60.

Each portion of the layer stack including the memory material layer 54 that remains in a respective memory opening 49 constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination a memory stack structure 55, a dielectric core 62, and a drain region 63 within a memory opening 49 constitutes a memory opening fill structure 58. Each memory opening fill structure 58 comprises a respective vertical stack of memory elements, which may comprise portions of the memory material layer 54 located at levels of the sacrificial material layers 42, or generally speaking, at levels of spacer material layers that may be formed as, or may be subsequently replaced at least partly with, electrically conductive layers.

In the alternative embodiment, the support pillar structures 20 may be formed in the support openings at the same time as the memory opening fill structures 58 are formed in the memory openings 49. In this case, the support pillar structures 20 comprise the same materials as the memory opening fill structures 58.

An anneal process can be performed to activate electrical dopants in the drain region 63 and in the vertical semiconductor channel 60. In this case, any amorphous semiconductor material in the vertical semiconductor channel 60 is converted into a polycrystalline semiconductor material. In one embodiment, grains within the vertical semiconductor channel 60 may extend predominantly along a respective local direction that is perpendicular to a respective proximal portion of an inner sidewall of the vertical semiconductor channel 60 and perpendicular to a respective proximal portion of an outer sidewall of the vertical semiconductor channel 60. As used herein, the grains extend predominantly along a specific direction if more than 50% of the grains extend along the specific direction.

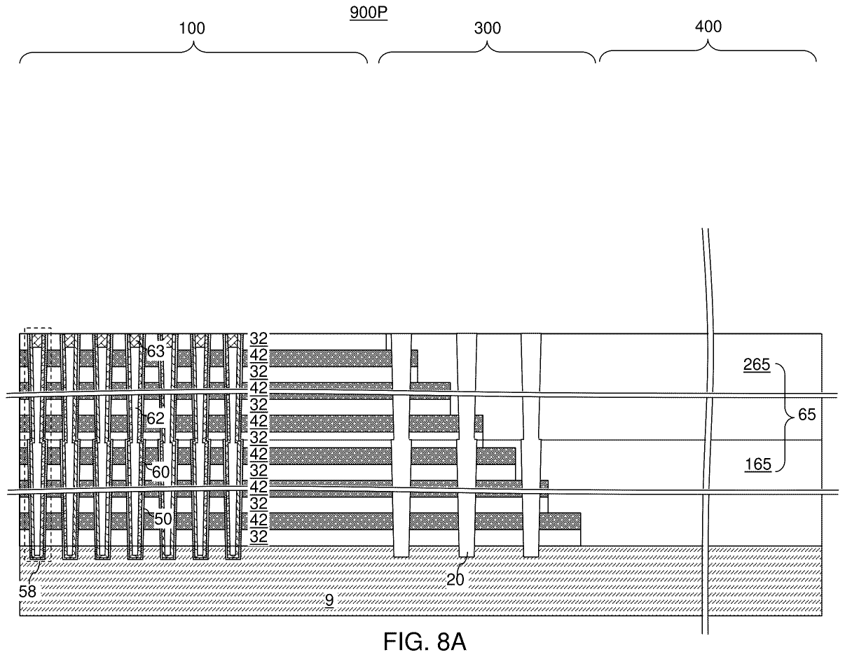

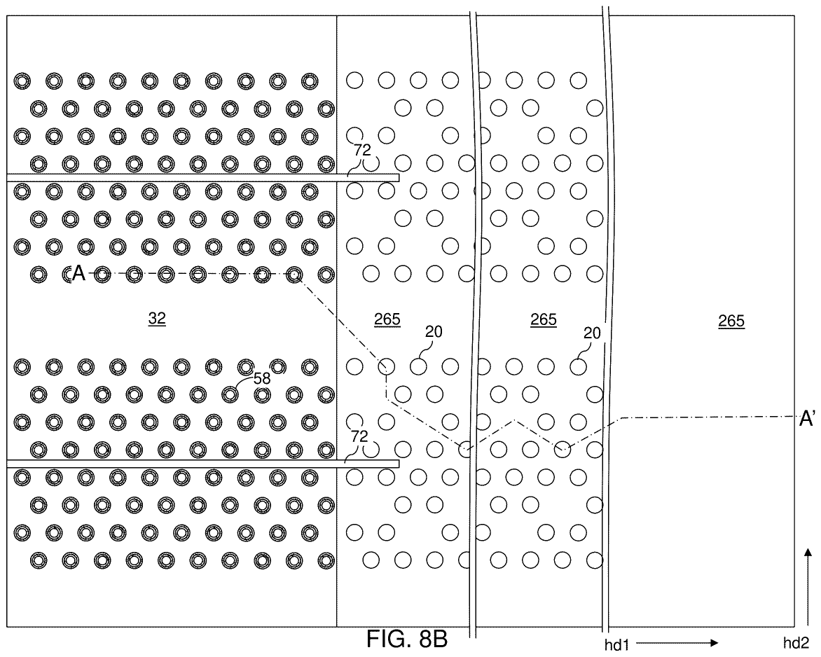

Referring to FIGS. 8A and 8B, the in-process memory die 900P is illustrated after formation of memory opening fill structures 58 within the memory openings 49. The memory opening fill structures 58 are located in the memory openings 49. Each of the memory opening fill structures 58 comprises a respective vertical semiconductor channel 60, a respective vertical stack of memory elements (which may comprise portions of a memory material layer 54) located at levels of the sacrificial material layers 42, and a respective drain region 63 contacting a first end of the respective vertical semiconductor channel 60.

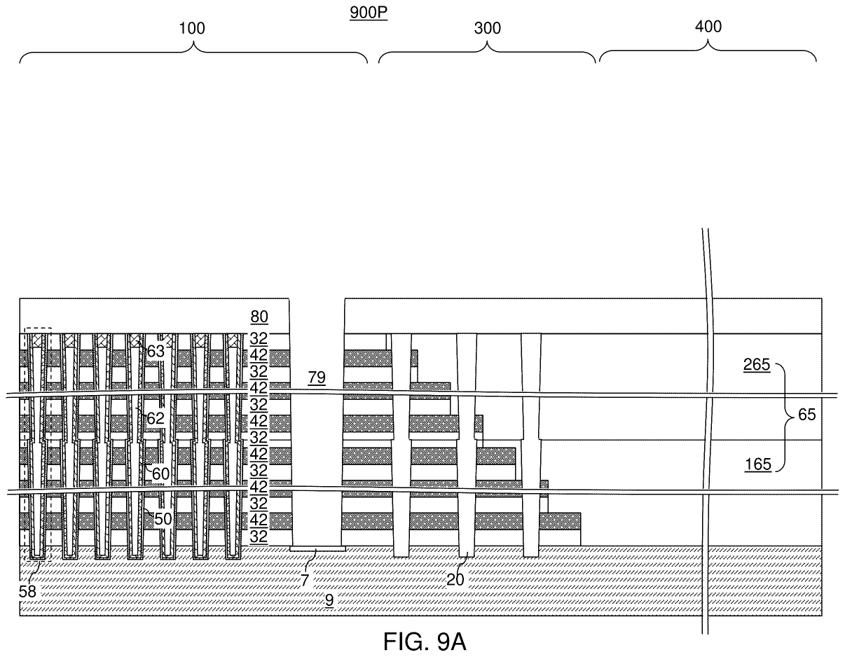

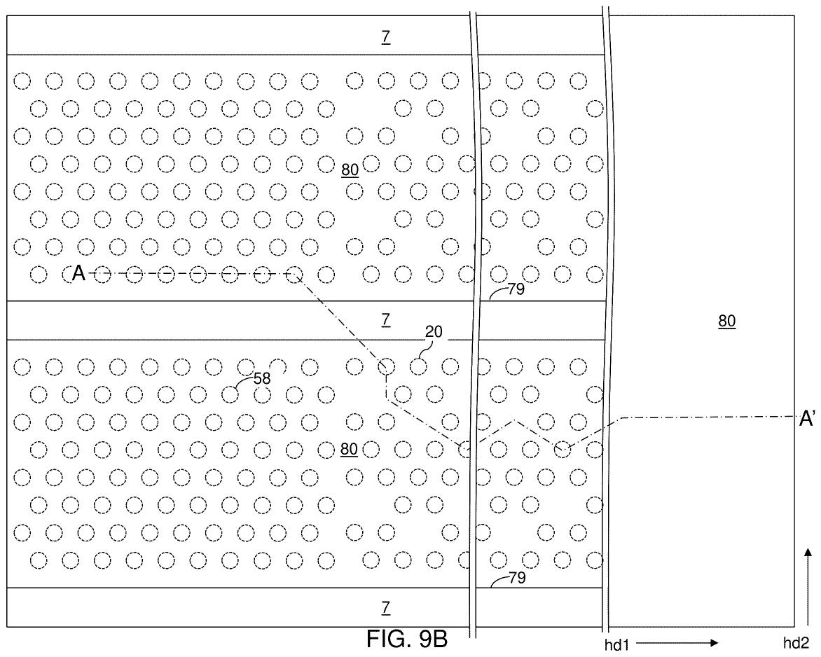

Referring to FIGS. 9A and 9B, a dielectric material, such as undoped silicate glass (i.e., silicon oxide) or a doped silicate glass can be deposited over the alternating stack (32, 42) to form a contact-level dielectric layer 80. The thickness of the contact-level dielectric layer 80 may be in a range from 100 nm to 600 nm, such as from 200 nm to 400 nm, although lesser and greater thicknesses may also be employed.

A photoresist layer (not shown) can be applied over the contact-level dielectric layer 80, and can be lithographically patterned to form elongated openings that laterally extend along the first horizontal direction hd1 between neighboring clusters of memory opening fill structures 58. An anisotropic etch process can be performed to transfer the pattern of the openings in the photoresist layer through the contact-level dielectric layer 80, the alternating stack (32, 42), and the stepped dielectric material portions 65, and into the substrate 9. Lateral isolation trenches 79 laterally extending along the first horizontal direction hd1 can be formed through the alternating stack (32, 42), the stepped dielectric material portions 65, and the contact-level dielectric layer 80. Each of the lateral isolation trenches 79 may comprise a respective pair of lengthwise sidewalls that are parallel to the first horizontal direction hd1 and vertically extend from the top surface of the contact-level dielectric layer 80 to a surface of the source-level sacrificial layer 104. A surface of the source-level sacrificial layer 104 can be physically exposed underneath each lateral isolation trench 79. The photoresist layer can be subsequently removed, for example, by ashing.

An oxidation process can be performed to convert physically exposed surface portions of the substrate 9 into semiconductor oxide liners 7. The thickness of the semiconductor oxide liners 7 may be in a range from 5 nm to 20 nm, although lesser and greater thicknesses may also be employed.

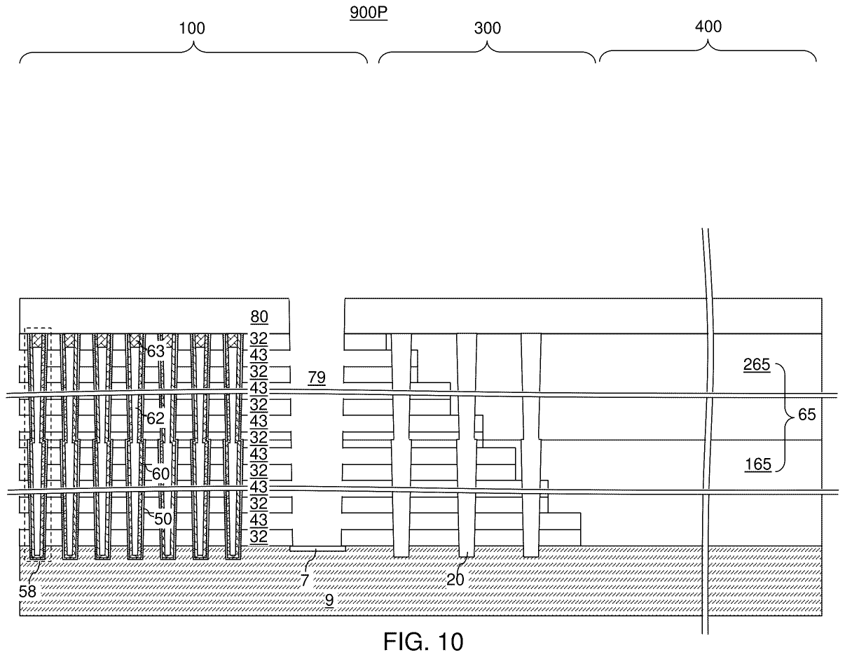

Referring to FIG. 10, an etchant that selectively etches the material of the sacrificial material layers 42 with respect to the material of the insulating layers 32 and the semiconductor oxide liner 7 can be introduced into the lateral isolation trenches 79, for example, employing an isotropic etch process. Lateral recesses 43 are formed in volumes from which the sacrificial material layers 42 are removed. The removal of the sacrificial material layers 42 can be selective to the materials of the insulating layers 32, the stepped dielectric material portions 65, and the material of the outermost layer of the memory films 50. In one embodiment, the sacrificial material layers 42 can include silicon nitride, and the materials of the insulating layers 32 and the stepped dielectric material portions 65 can include silicon oxide.

The etch process that removes the second material selectively to the first material and the outermost layer of the memory films 50 can be a wet etch process employing a wet etch solution, or can be a gas phase (dry) etch process in which the etchant is introduced in a vapor phase into the lateral isolation trenches 79. For example, if the sacrificial material layers 42 include silicon nitride, the etch process can be a wet etch process in which the in-process memory die 900P is immersed within a wet etch tank including phosphoric acid, which etches silicon nitride selectively to silicon oxide, silicon, and various other materials employed in the art. The support pillar structure 20, the stepped dielectric material portions 65, and the memory stack structures 55 provide structural support while the lateral recesses 43 are present within volumes previously occupied by the sacrificial material layers 42.

Each lateral recess 43 can be a laterally extending cavity having a lateral dimension that is greater than the vertical extent of the cavity. In other words, the lateral dimension of each lateral recess 43 can be greater than the height of the lateral recess 43. A plurality of lateral recesses 43 can be formed in the volumes from which the second material of the sacrificial material layers 42 is removed. The memory openings in which the memory stack structures 55 are formed are herein referred to as front side openings or front side cavities in contrast with the lateral recesses 43.

Each of the plurality of lateral recesses 43 can extend substantially parallel to the top surface of the substrate 9. A lateral recess 43 can be vertically bounded by a top surface of an underlying insulating layer 32 and a bottom surface of an overlying insulating layer 32. In one embodiment, each lateral recess 43 can have a uniform height throughout.

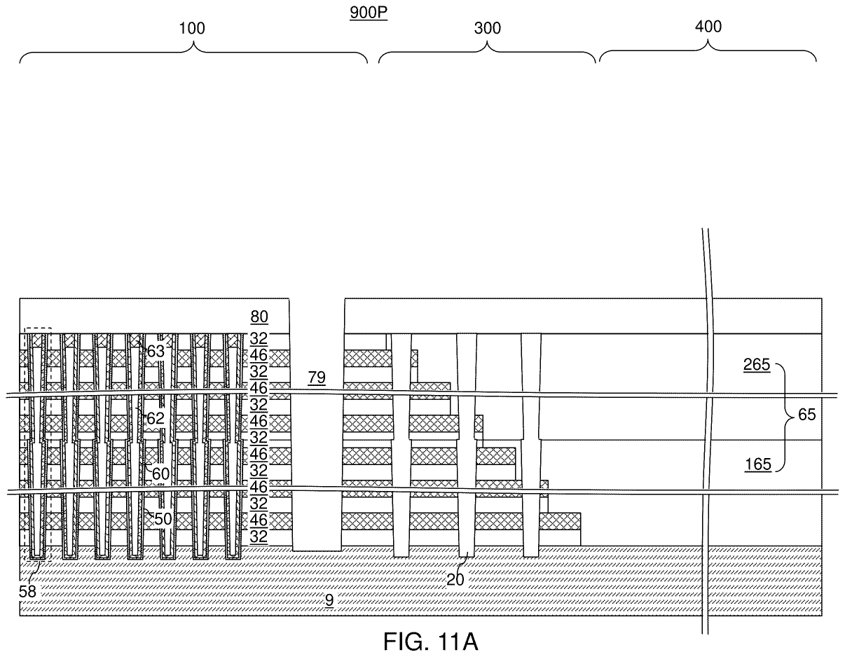

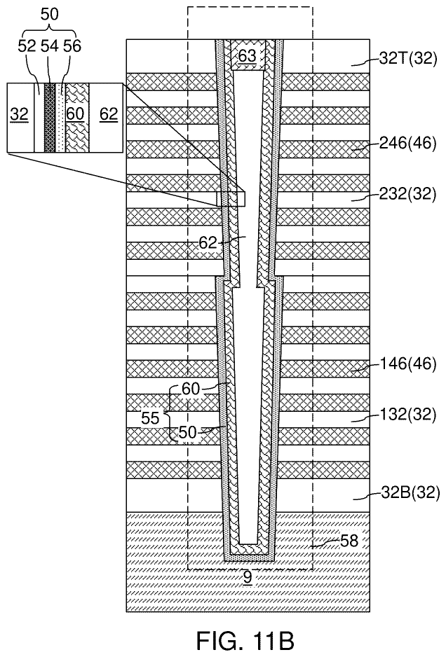

Referring to FIG. 11, an outer blocking dielectric layer (not expressly illustrated) can be optionally formed. The outer blocking dielectric layer, if present, comprises a dielectric material that functions as a control gate dielectric for the control gates to be subsequently formed in the lateral recesses 43. In case the blocking dielectric layer 52 is present within each memory opening, the outer blocking dielectric layer is optional. In case the blocking dielectric layer 52 is omitted, the outer blocking dielectric layer is present.

At least one conductive material can be deposited in the lateral recesses 43 by providing at least one reactant gas into the lateral recesses 43 through the lateral isolation trenches 79. A metallic barrier layer can be deposited in the lateral recesses 43. The metallic barrier layer includes an electrically conductive metallic material that can function as a diffusion barrier layer and/or adhesion promotion layer for a metallic fill material to be subsequently deposited. The metallic barrier layer can include a conductive metallic nitride material such as TiN, TaN, WN, or a stack thereof, or can include a conductive metallic carbide material such as TiC, TaC, WC, or a stack thereof. In one embodiment, the metallic barrier layer can be deposited by a conformal deposition process such as chemical vapor deposition (CVD) or atomic layer deposition (ALD). The thickness of the metallic barrier layer can be in a range from 2 nm to 8 nm, such as from 3 nm to 6 nm, although lesser and greater thicknesses can also be employed. In one embodiment, the metallic barrier layer can consist essentially of a conductive metal nitride such as TiN.

A metal fill material is deposited in the plurality of lateral recesses 43, on the sidewalls of the at least one lateral isolation trench 79, and over the top surface of the contact-level dielectric layer 80 to form a metallic fill material layer. The metallic fill material can be deposited by a conformal deposition method, which can be, for example, chemical vapor deposition (CVD), atomic layer deposition (ALD), electroless plating, electroplating, or a combination thereof. In one embodiment, the metallic fill material layer can consist essentially of at least one elemental metal. The at least one elemental metal of the metallic fill material layer can be selected, for example, from tungsten, cobalt, ruthenium, titanium, and tantalum. In one embodiment, the metallic fill material layer can consist essentially of a single elemental metal. In one embodiment, the metallic fill material layer can be deposited employing a fluorine-containing precursor gas such as WF₆. In one embodiment, the metallic fill material layer can be a tungsten layer including a residual level of fluorine atoms as impurities. The metallic fill material layer is spaced from the insulating layers 32 and the memory stack structures 55 by the metallic barrier layer, which is a metallic barrier layer that blocks diffusion of fluorine atoms therethrough.

A plurality of electrically conductive layers 46 can be formed in the plurality of lateral recesses 43, and a continuous metallic material layer can be formed on the sidewalls of each lateral isolation trench 79 and over the contact-level dielectric layer 80. Each electrically conductive layer 46 includes a portion of the metallic barrier layer and a portion of the metallic fill material layer that are located between a vertically neighboring pair of dielectric material layers such as a pair of insulating layers 32. The continuous metallic material layer includes a continuous portion of the metallic barrier layer and a continuous portion of the metallic fill material layer that are located in the lateral isolation trenches 79 or above the contact-level dielectric layer 80.

The deposited metallic material of the continuous electrically conductive material layer is etched back from the sidewalls of each lateral isolation trench 79 and from above the contact-level dielectric layer 80 by performing an isotropic etch process that etches the at least one conductive material of the continuous electrically conductive material layer. Each remaining portion of the deposited metallic material in the lateral recesses 43 constitutes an electrically conductive layer 46. each electrically conductive layer 46 can be a conductive line structure.

Thus, the sacrificial material layers 42 are replaced with the electrically conductive layers 46. Generally, the electrically conductive layers 46 can be formed by providing a metallic precursor gas into the lateral isolation trenches 79 and into the lateral recesses 43.

At least one uppermost electrically conductive layer 46 may comprise a drain side select gate electrode. At least one bottommost electrically conductive layer 46 may comprise a source side select gate electrode. The remaining electrically conductive layers 46 may comprise word lines. Each word line functions as a common control gate electrode for the plurality of vertical NAND strings (e.g., memory opening fill structures 58).

Generally, a memory device can be formed, which comprises an alternating stack (32, 46) of insulating layers 32 and electrically conductive layers 46, memory openings 49 vertically extending through the alternating stack (32, 46), and memory opening fill structures 58 located in the memory openings 49. Each of the memory opening fill structures 58 comprises a respective vertical semiconductor channel 60, a respective vertical stack of memory elements (which may comprise portions of a memory material layer 54) located at levels of the sacrificial material layers 42, and a respective drain region 63 contacting a first end of the respective vertical semiconductor channel 60. The electrically conductive layers 46 comprise select gate electrodes and word lines of the respective vertical stack of memory elements.

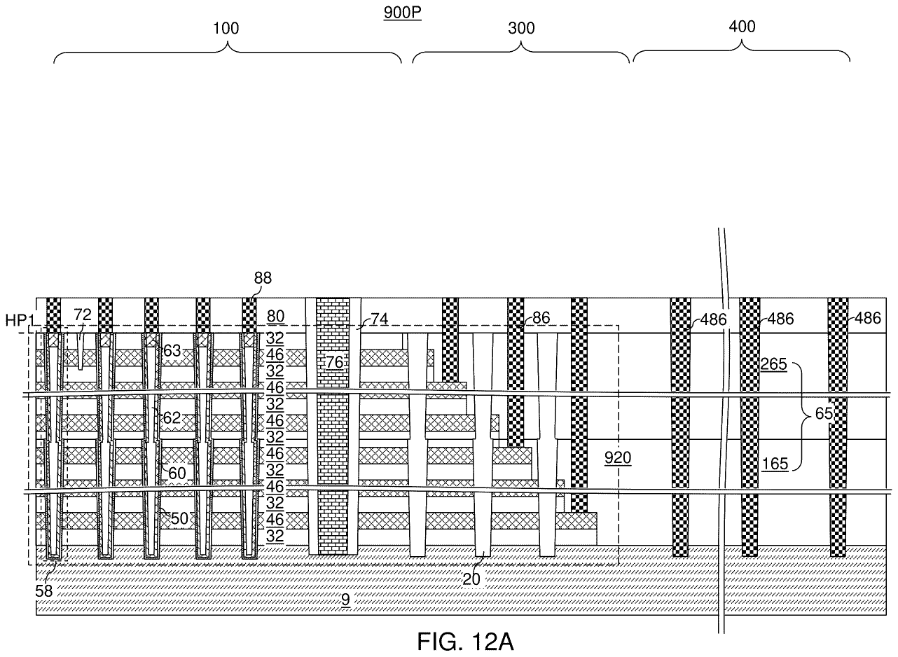

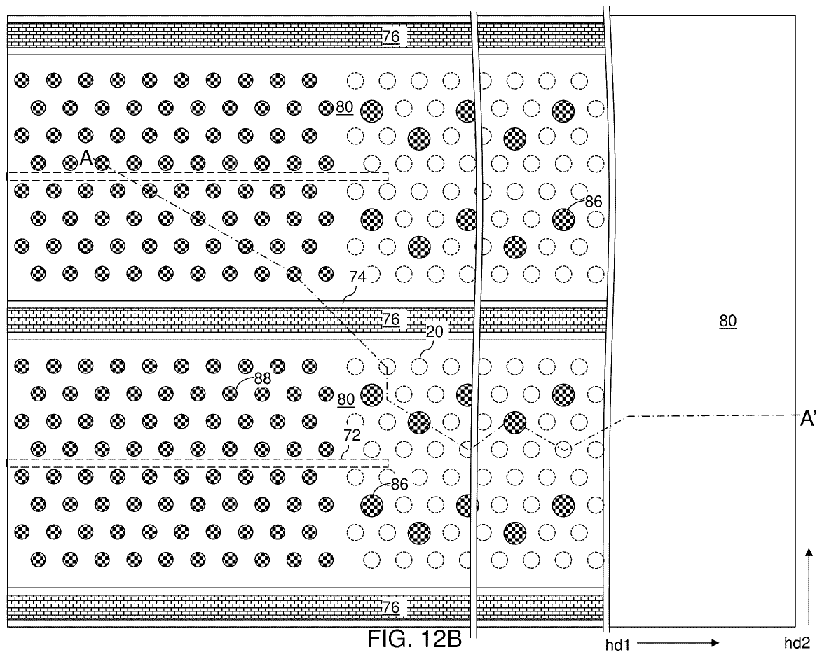

Referring to FIGS. 12A and 12B, at least one trench fill material may be deposited in the lateral isolation trenches 79 to form lateral isolation trench fill structures (74, 76). For example, an insulating material layer can be conformally deposited in peripheral regions of the lateral isolation trenches 79, and an anisotropic etch process can be performed to remove horizontally-extending portions of the insulating material layer. Each remaining vertically extending portion of the insulating material layer constitutes an insulating spacer 74. Each insulating spacer 74 may be elongated along the first horizontal direction hd2, and may be topologically homeomorphic to a torus. An electrically conductive material may be deposited in remaining unfilled volumes of the lateral isolation trenches 79, and excess portions of the electrically conductive material can be removed from above the horizontal plane including the top surface of the contact-level dielectric layer 80. Each remaining portion of the electrically conductive material filling a respective lateral isolation trench 79 constitutes a conductive wall structure 76. Each lateral isolation trench 79 may be filled with a respective combination of an insulating spacer 74 and a conductive wall structure 76, which is herein referred to as a lateral isolation trench fill structure (74, 76).

In an alternative embodiment, a dielectric fill material, such as silicon oxide, can be deposited in the lateral isolation trenches 79. Excess portions of the dielectric fill material can be removed from above the contact-level dielectric layer 80. Each remaining portion of the dielectric fill material that fills a respective one of the lateral isolation trenches 79 constitutes a lateral isolation trench fill structure, which may be a dielectric wall structure. Generally, each lateral isolation trench 79 can be filled with a respective lateral isolation trench fill structure.

Contact via structures (88, 86) can be formed through the contact-level dielectric layer 80, and optionally through the stepped dielectric material portions 65. For example, drain contact via structures 88 can be formed through the contact-level dielectric layer 80 on each drain region 63. Layer contact via structures 86 can be formed on the electrically conductive layers 46 through the contact-level dielectric layer 80, and through the stepped dielectric material portions 65. In addition, connection via structures 486 can be formed through the contact-level dielectric layer 80 and the stepped dielectric material portions 65 in the peripheral region 400. In one embodiment, the connection via structures 486 may extend into an upper portion of the substrate 9. At least one three-dimensional memory array 920 can be formed within each in-process memory die 900P. In one embodiment, each in-process memory die 900P may comprise a plurality of three-dimensional memory arrays 920.

In summary, a semiconductor structure can be provided. The semiconductor structure comprises: first alternating stacks (32, 46) of first insulating layers 32 and first electrically conductive layers 46. The first alternating stacks (32, 46) are laterally spaced apart from each other by first lateral isolation trenches 79 that laterally extend along a first horizontal direction (e.g., word line direction) hd1. The first lateral isolation trenches 79 may be filled with first lateral isolation trench fill structures (74, 76). The semiconductor structure further comprises: first memory openings 49 vertically extending through the first alternating stacks (32, 46); and first memory opening fill structures 58 located in the first memory openings 49. Each of the first memory opening fill structures 58 comprises a respective first vertical semiconductor channel 60, a respective vertical stack of first memory elements (e.g., memory cells comprising portions of a respective memory material layer 54), and a respective first drain region 63 contacting a first end of the respective first vertical semiconductor channel 60. The first electrically conductive layers 46 includes first word lines of the first memory elements of the first memory opening fill structures 58 as well as source side and drain side select gat electrodes.

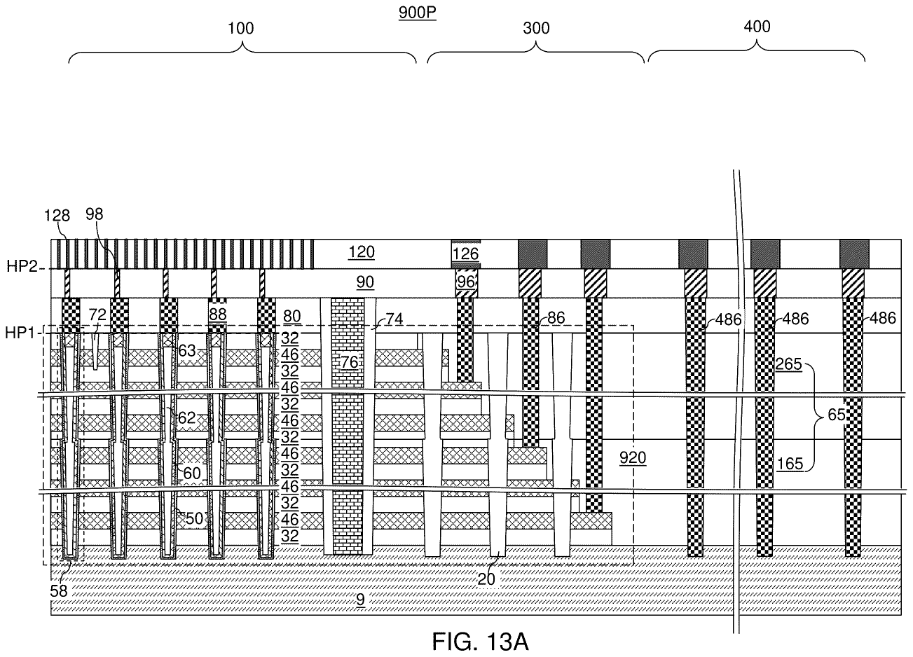

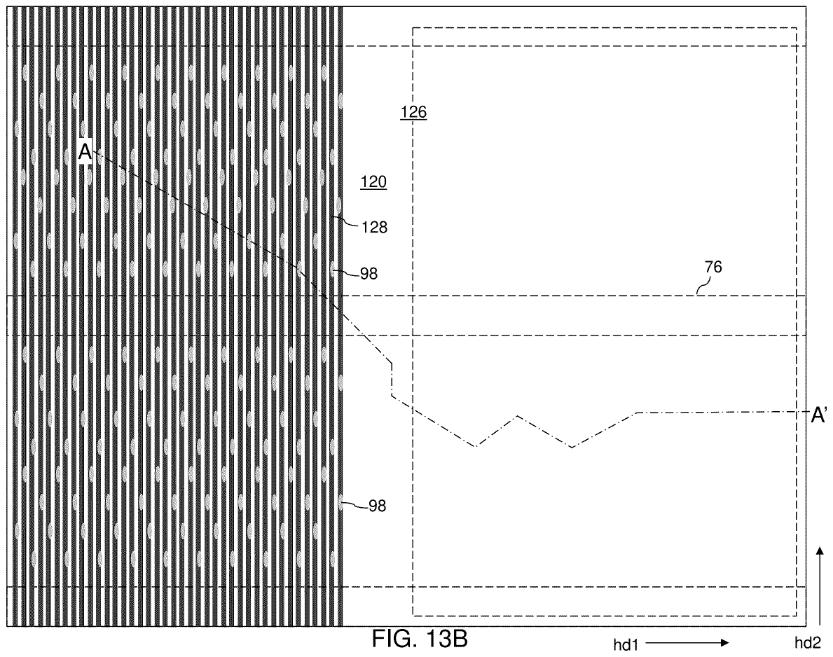

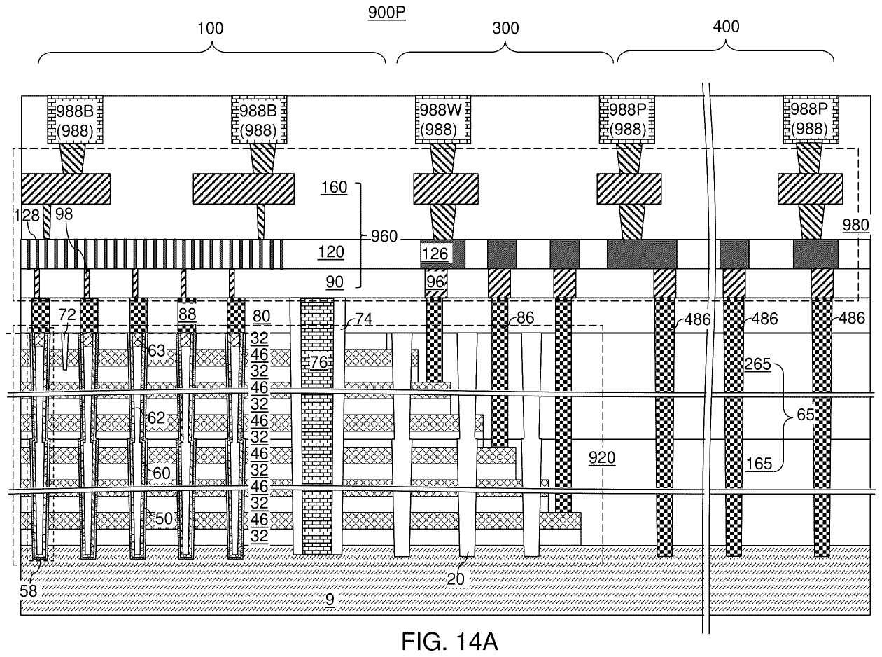

Referring to FIGS. 13A and 13B, a first via-level dielectric layer 90 can be formed over the contact-level dielectric layer 80. The first via-level dielectric layer 90 comprises a dielectric material, such as undoped silicate glass (e.g., silicon oxide), a doped silicate glass, or a porous or non-porous organosilicate glass. The first via-level dielectric layer 90 may be deposited by a chemical vapor deposition or by spin coating. The thickness of the first via-level dielectric layer 90 may be in a range from 50 nm to 300 nm, although lesser and greater thicknesses may also be employed. Drain-connection via structures 98 and additional connection via structures 96 can be formed in the first via-level dielectric layer 90. The drain-connection via structures 98 can be formed directly on the top surfaces of the drain contact via structures 88. Each drain contact via structure 88 can be contacted by a respective drain-connection via structure 98. The additional connection via structures 96 can be formed on a respective one of the layer contact via structures 86 and the connection via structures 486.

A first bit-line-level dielectric layer 120 can be formed over the first via-level dielectric layer 90. The first bit-line-level dielectric layer 120 comprises a dielectric material, such as undoped silicate glass (e.g., silicon oxide), a doped silicate glass, or a porous or non-porous organosilicate glass. The first bit-line-level dielectric layer 120 may be deposited by a chemical vapor deposition or by spin coating. The thickness of the first bit-line-level dielectric layer 120 may be in a range from 50 nm to 300 nm, although lesser and greater thicknesses may also be employed.

First bit lines 128 and first-bit-line-level metal lines 126 can be formed in the first bit-line-level dielectric layer 120. As used herein, “bit lines” refer to horizontal metal interconnect structures formed at a metal line level and configured to transmit electrical signals between drain regions 63 of memory opening fill structures (e.g., drain regions of the vertical NAND strings) 58 and a bit line driver circuit, such as a bit line bias circuit that includes sense amplifiers. in one embodiment that will be described below, a bonded assembly of a logic die 700 and a memory die 900 includes the first bit lines 128 which are a first subset of the bit lines that are located in the memory die, and second bit lines 778 and optional crossed bit lines 728 which are a second subset of the bit lines that are located in a logic die which is bonded to the memory die. Each of the first bit lines 128 may be formed on a respective drain-connection via structure 98 within a first subset of the drain-connection via structures 98. The first bit lines 128 can be parallel to each other. The lateral extension direction of the first bit lines 128 is herein referred to as a bit line direction. The first-bit-line-level metal lines (e.g., word line interconnect lines) 126 may be formed on a respective one of the additional connection via structures 96.

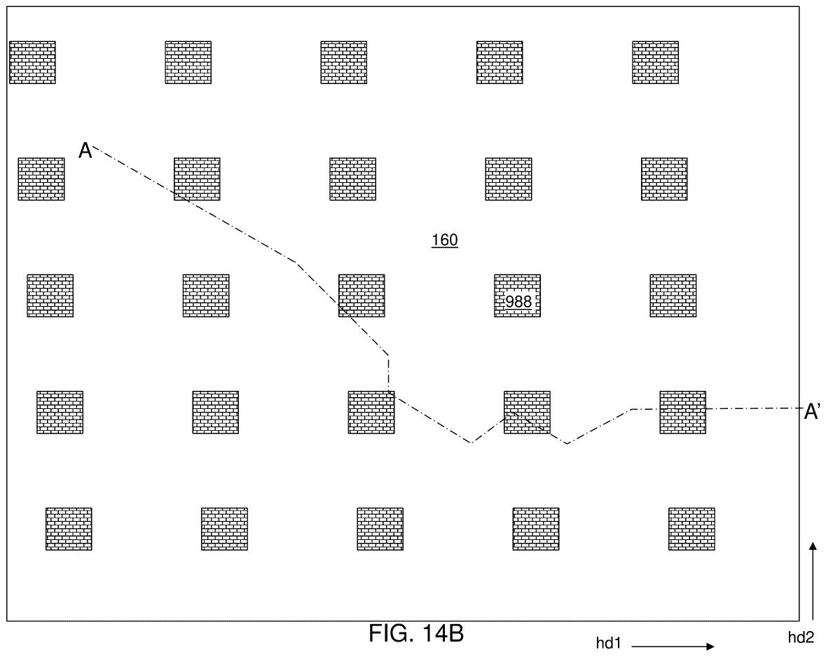

Referring to FIGS. 14A and 14B, additional dielectric material layers 160 and additional metal interconnect structures can be formed. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The first via-level dielectric layer 90, the first bit-line-level dielectric layer 120, and the additional dielectric material layers 160 that are formed above the contact-level dielectric layer 80 are herein referred to as memory-die dielectric material layers 960. The drain-connection via structures 98, the additional connection via structures 96, the first bit lines 128, the first bit-line-level metal lines 126, and any additional metal interconnect structures located there above are collectively referred to as memory-die metal interconnect structures 980. In other words, the set of all metal interconnect structures that are formed above the horizontal plane including the top surfaces of the drain contact via structures 88 is herein referred to as memory-die metal interconnect structures 980.

Metal bonding pads, which are herein referred to memory-die bonding pads 988, may be formed at the topmost level of the memory-die dielectric material layers 960 to complete a memory die. A subset of the memory-die bonding pads 988 may be electrically connected to the memory-die metal interconnect structures 980 and various nodes of the three-dimensional memory array including the electrically conductive layers 46 and the drain regions 63 of the memory opening fill structures 58. For example, the memory-die bonding pads 988 may comprise bit-line-connection memory-die bonding pads 988B that are electrically connected to a respective one of the first bit lines 128, word-line-connection memory-die bonding pads 988W that are electrically connected to a respective one of the layer contact via structures 86, and peripheral memory-die bonding pads 988B that are electrically connected to a respective one of the connection via structures 488. In summary, the memory-die dielectric material layers 960 are formed over the alternating stacks (32, 46). The memory-die metal interconnect structures 980 are embedded in the memory-die dielectric material layers 960. The memory-die bonding pads 988 can be embedded within the memory-die dielectric material layers 960, and specifically, within the topmost layer among the memory-die dielectric material layers 960. The memory-die bonding pads 988 can be electrically connected to the memory-die metal interconnect structures 980.

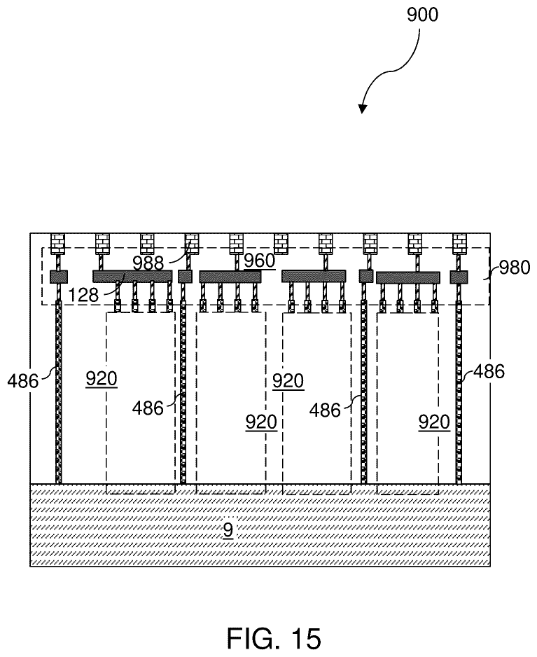

Referring to FIG. 15, the wafer (e.g., entire substrate 9) including a two-dimensional array of in-process memory dies 900P can be diced along dicing channels to provide singulated memory dies 900. As such, each memory die 900 may comprise a set of physically exposed surfaces which include a top surface, sidewalls, and a bottom surface. Each memory die 900 comprises at least one three-dimensional memory array 920 (e.g., am array of memory cells which comprise portions of the memory film 50 located at levels of the word lines 46) and an array of memory-die bonding pads 988. The memory die 900 has a rectangular-type first planar projection shape in a plan view along a vertical direction. As used herein, a “planar projection shape” refers to a shape that is obtained by projecting a physical element onto a two-dimensional planar plane, i.e., a two-dimensional Euclidean plane. Thus, a planar projection shape of a physical element along a vertical direction refers to a shape that is obtained by projecting the physical element onto a horizontal two-dimensional plane, or an x-y plane as known in the art. In one embodiment, the first planar projection shape of the memory die 900 may be a first rectangle. In one embodiment, the memory die 900 may have an overall shape of a rectangular parallelopiped, and horizontal cross-sectional shapes of the memory die 900 at any horizontal cross-sectional plane that cuts through the memory die 900 may be the same as the first planar projection shape.

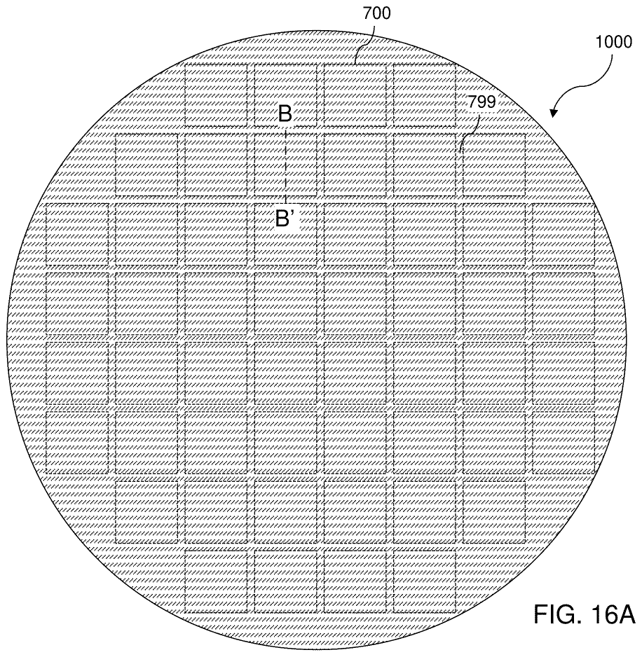

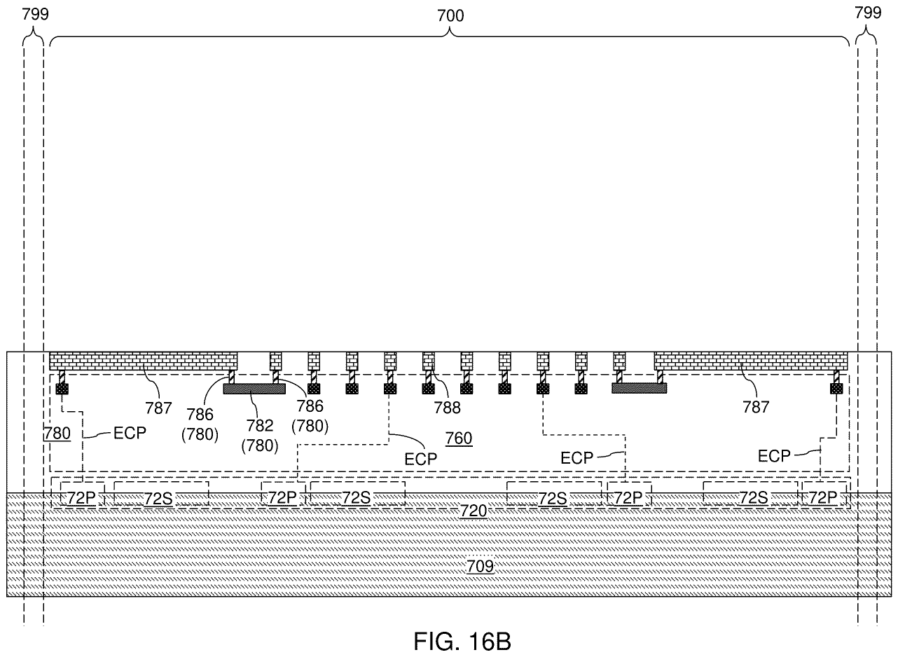

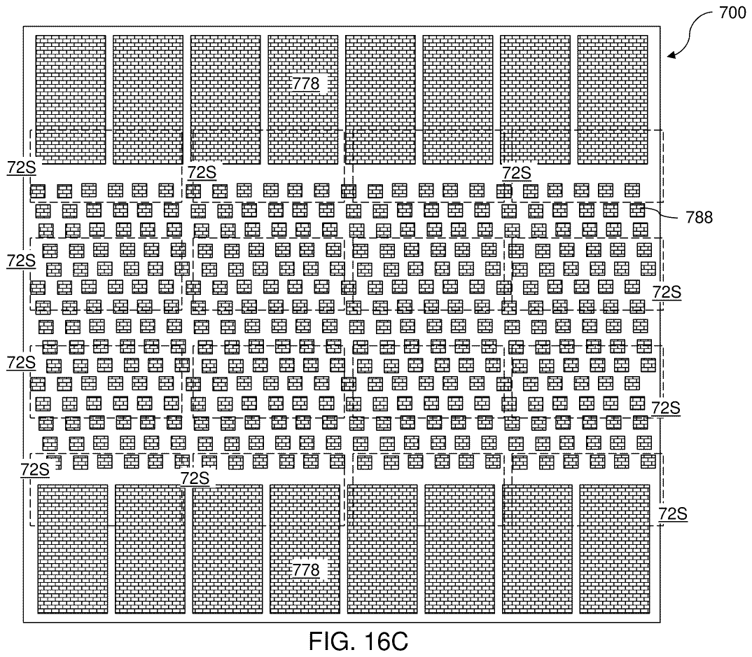

Referring to FIGS. 16A-16C, a wafer 1000 supporting a two-dimensional array of logic dies 700 can be provided. The wafer 1000 may comprise a semiconductor substrate, such as a silicon wafer. Each portion of the wafer 1000 supporting a respective logic die 700 is herein referred to as a logic-die substrate 709. The two-dimensional array of logic dies 700 may be laterally spaced apart from each other by dicing channels 799. Each logic die 700 may be laterally bounded by and may be laterally surrounded by a set of dicing channels 799.

Each of the logic dies 700 comprises a logic circuit 720 configured to control operation of memory cells within the respective memory die 900, and an array of logic-die bonding pads 788 and surface metal pads 787 that are located at a same level as the array of logic-die bonding pads 788.

The logic circuit 720 comprises logic-die semiconductor devices (such as field effect transistors). The logic circuit 720 can be configured to control operation of the memory array 920 within the memory die 900. Specifically, the logic circuit 720 can be configured to drive various electrical components within the memory array including, but not limited to, the electrically conductive layers (e.g., word lines and select gate electrodes) 46, the drain regions 63 (via the first bit lines 128), and optionally at least one source layer that is either formed as part of the memory array 920 or that will be formed during a subsequent step described below. The logic circuit 720 can be configured to control operation of the vertical stack of memory elements (e.g., memory cells comprising portions of the memory film 50) in the memory array in the memory die 900. In one embodiment, the logic circuit 720 includes word line drivers, bit line drivers and an optional source line driver,. Generally, the logic circuit 720 can be configured to electrically bias the word lines and each of the first bit lines 128.

The logic circuit 720 of each logic die 700 may comprise a plurality of sense amplifiers 72S and a plurality of power supply circuits 72P, as shown in FIG. 16B. Each logic die 700 may comprise logic-die metal interconnect structures 780 embedded within logic-die dielectric material layers 760. The logic-die dielectric material layers 760 may comprise any suitable interlayer dielectric material, such as silicon oxide, silicon nitride, silicon carbonitride, silicon oxynitride, and/or organosilicate glass.

The array of logic-die bonding pads 788 is configured to be bonded to the array of memory-die bonding pads 988 in a memory die 900. As such, the array of logic-die bonding pads 788 may be arranged in a mirror image pattern of the pattern of the memory-die bonding pads 988 of a memory die. each logic die 700 has a greater lateral extent than a memory die 900 in a configuration in which the memory die 900 is aligned to the logic die 700 for bonding. Specifically, each logic die 700 may have a second planar projection shape in a plan view such that, upon alignment of a memory die 900 having a first planar projection shape to the logic die 700, the second planar projection shape contains the entirety of the first planar projection shape and a first additional planar projection shape located on an outside of a periphery of the first planar projection shape. The first additional planar projection shape may be a frame shape having an inner periphery that coincides with the periphery of the first planar projection shape in the plan view. Thus, all of the logic-die bonding pads 788 may be provided within the area of the first planar projection shape, i.e., may be provided entirely within an area to have an areal overlap with the memory die 900 upon subsequently alignment of the memory die 900 to the logic die 700. For example, the logic die 700 may have a rectangular horizontal area which is larger than a rectangular horizontal are of the memory die 900.

According to an embodiment of the present disclosure, each logic die 700 comprises surface metal pads 787 having first planar horizontal surfaces located within a horizontal plane including top surfaces of the array of logic-die bonding pads 788. The surface metal pads 787 can be formed entirely within the area of the first additional planar projection shape in the plan view, i.e., entirely within the area that does not have any areal overlap with a memory die 900 to be subsequently bonded to a the logic die 700. The surface metal pads 787 generally extend across the entire area not to be covered by a memory die 900 upon bonding to provide laterally-extending electrically conductive paths. The surface metal pads 787 and the logic-die bonding pads 788 can be formed simultaneously employing a same set of metal patterning steps and a same set of dielectric material patterning steps. Thus, the surface metal pads 787 may comprise peripheral bonding pads which are located at a periphery of the logic die 700 and which are not used for bonding to memory-die bonding pads 988.

In one embodiment, the logic-die bonding pads 788 and the surface metal pads 787 may be formed during the same damascene deposition and planarization steps. In this embodiment, pad cavities may be formed in the topmost level of the logic-die dielectric material layers 760, and may be filled with at least one conductive material (such as a combination of a metallic barrier material (e.g., Ti and/or TiN) and copper), followed by planarization (e.g., CMP) to form the logic-die bonding pads 788 and the surface metal pads 787. Thus, the surface metal pads 787 may have the same material composition as and the same vertical extent as the logic-die bonding pads 788. In one embodiment, each of the surface metal pads 787 may have a larger area than each of the logic-die bonding pads 788.

The logic-die metal interconnect structures 780 may comprise multiple levels of metal line structures and multiple levels of metal via structures. A subset of the logic-die metal interconnect structures 780 may be employed to provide electrical connections between a respective pair of a surface metal pad 787 and a logic-die bonding pad 788. For example, each of the surface metal pads 787 may be electrically connected to a respective one of the logic-die bonding pads 788 by a respective first metal via structure 786 electrically connected to and/or contacting a bottom end of the respective one of the surface metal pads 787, a respective second metal via structure 786 electrically connected to and/or contacting a bottom end of the respective one of the logic-die bonding pads 788, and a respective interconnect-level metal line 782 electrically connected to and/or contacting bottom surfaces of the respective first metal via structure 786 and the respective second metal via structure 786.

Each power supply circuit 72P can be configured to provide a power supply voltage to devices in the logic die 700 and/or memory die 900. For example, the power supply circuit 72P may supply electric power to one or more sense amplifiers 72S. In one embodiment, at least a subset of the power supply circuit 72P may be electrically connected to a respective surface metal pads 787 through a respective subset of logic-die metal interconnect structures 780 embedded within the logic die 700.

The logic-die metal interconnect structures 780 of each logic die 700 are also configured to provide electrically conductive paths ECP between the power supply circuits 72P and the respective interconnect level metal lines 782. Additional electrically conductive paths may be provided between the sense amplifiers 72S and other interconnect level metal lines 782.

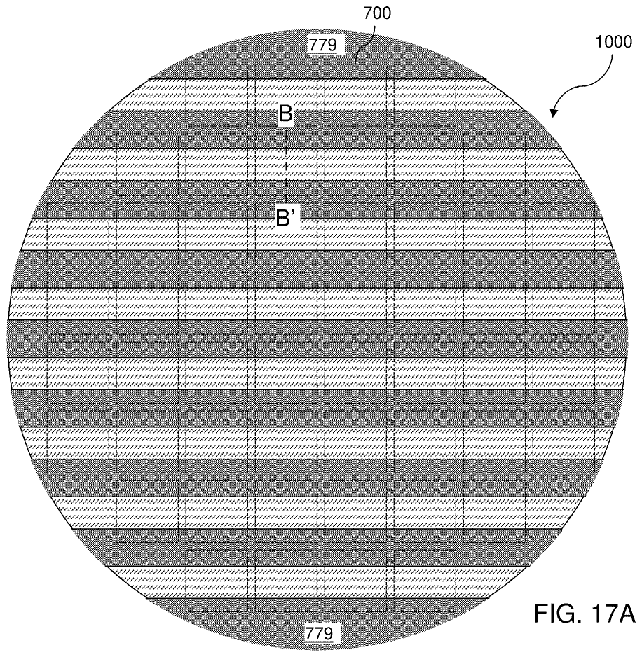

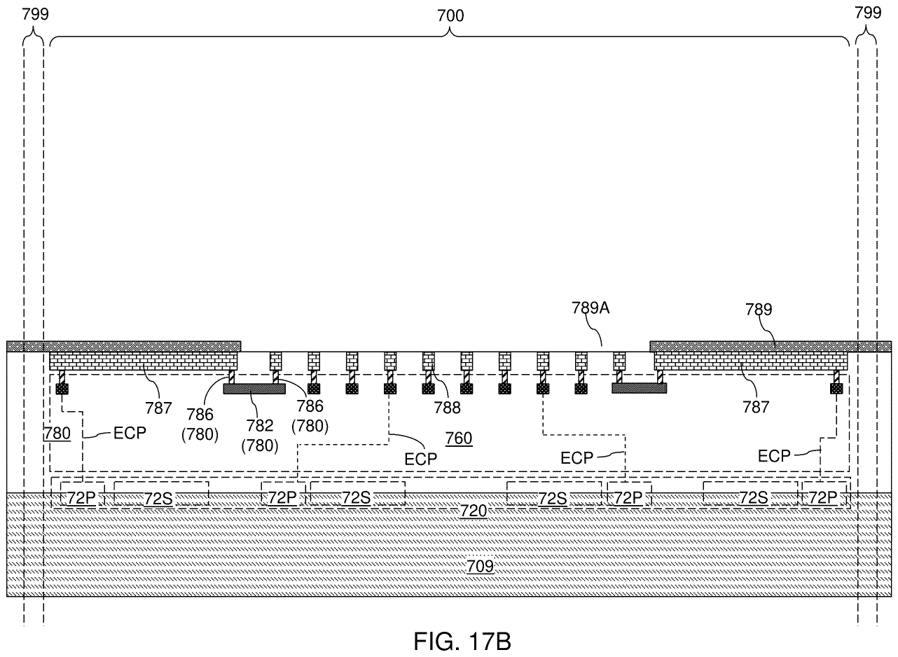

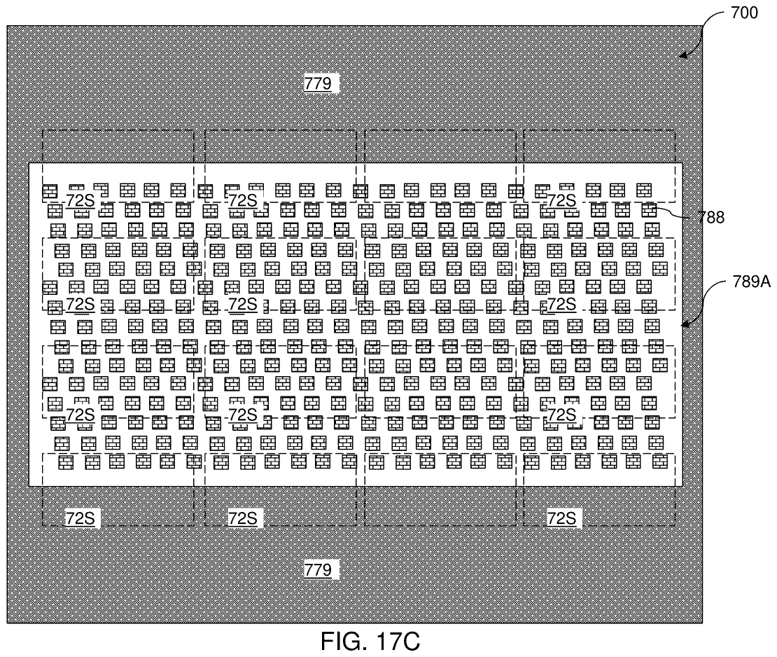

Referring to FIGS. 17A-17C, a passivation dielectric layer 789 can be formed over the wafer 1000 supporting the two-dimensional array of logic dies 700. The passivation dielectric layer 789 comprises a passivation dielectric material, such as silicon nitride or silicon carbonitride. The passivation dielectric layer 789 may be deposited, for example, by a chemical vapor deposition process as a blanket material layer (i.e., as an unpatterned material layer) having a uniform thickness throughout. The thickness of the passivation dielectric layer 789 may be in a range from 50 nm to 1,000 nm, such as from 100 nm to 300 nm, although lesser and greater thicknesses may also be employed. The passivation dielectric layer 789 may be subsequently patterned, for example, by applying a photoresist layer over the passivation dielectric layer 789, by forming a pattern of openings in the photoresist layer, and by performing an etch process (which may be an anisotropic etch process or an isotropic etch process) that etches unmasked portions of the passivation dielectric layer 789. The photoresist layer can be subsequently removed, for example, by ashing.

An opening 789A in the passivation dielectric layer 789 can be formed in each area in which a memory die 900 is to be subsequently bonded to a respective underlying logic die 700. According to an aspect of the present disclosure, each of the surface metal pads 787 may be entirely covered by the passivation dielectric layer 789, and each of the logic-die bonding pads 788 may be physically exposed within a respective opening 789A in the passivation dielectric layer 789. The size of each opening 789A in the passivation dielectric layer 789 may be selected such that each opening has a greater area than the area of a memory die 900. In other words, each opening 789A may have a shape that includes an entirety of a first planar projection shape of a memory die 900 to be subsequently disposed therein, and may further comprise an additional frame shape that laterally surrounds the first planar projection shape. The shape of each opening 189A is smaller than and is laterally offset inward from the periphery of the second planar projection shape of a respective underlying logic die 700.

In one embodiment, all first planar horizontal surfaces of the surface metal pads 787 that are located within a horizontal plane including the topmost surface of the logic-die dielectric material layers 760 may be in contact with the passivation dielectric layer 789. Thus, the passivation dielectric layer 789 contacts the logic dies 700 at the horizontal plane including the physically exposed surfaces of the arrays of logic-die bonding pads 788. The passivation dielectric layer 789 protects the logic-die dielectric material layers 760 and the surface metal pads 787 from moisture ingress and inward diffusion of contaminants.

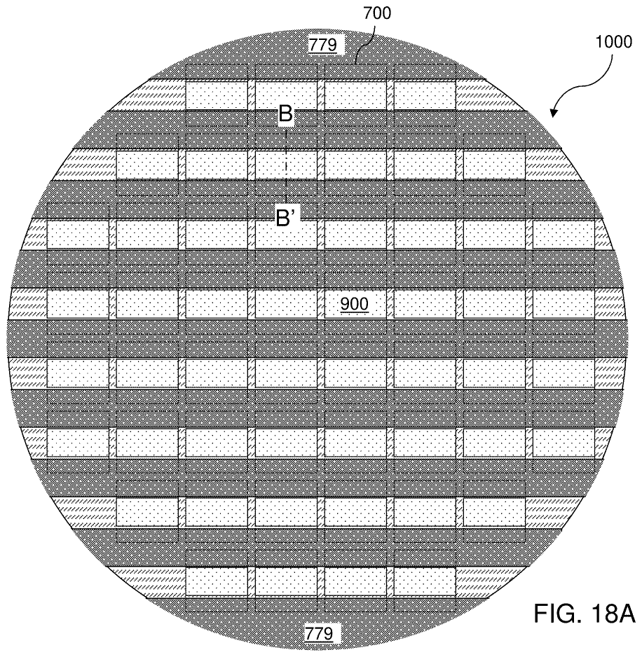

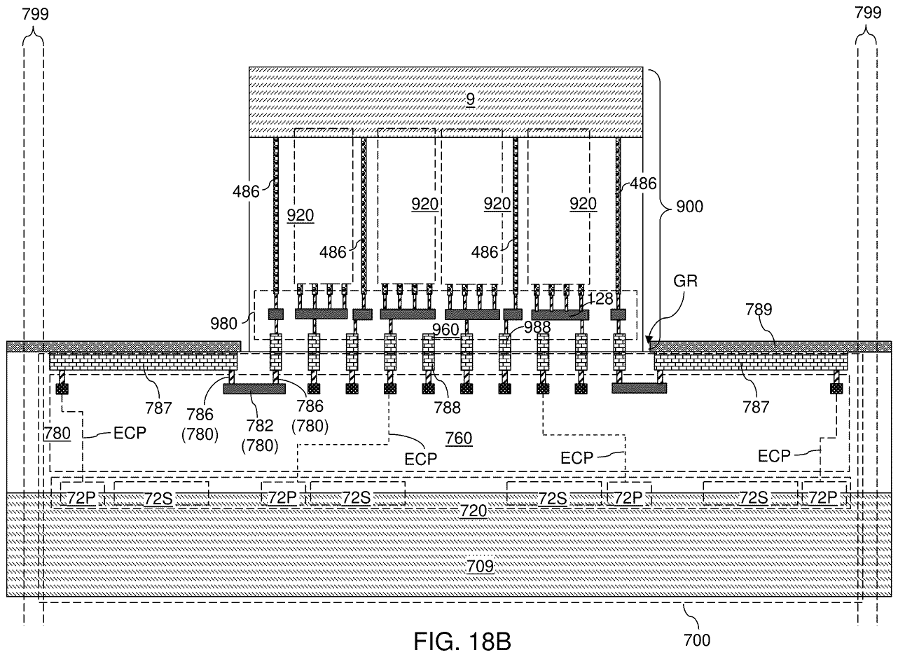

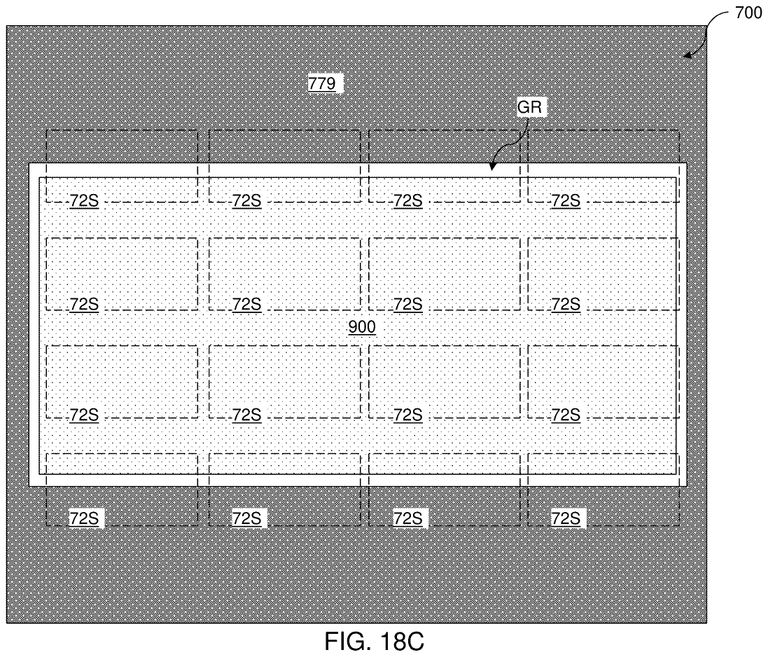

Referring to FIGS. 18A-18C, memory dies 900 can be individually bonded to a respective logic die 700 within the two-dimensional array of logic dies 700 on the wafer 1000. In other words, the memory dies 900 can be bonded to the wafer 1000 supporting the two-dimensional array of logic dies 700 by performing a die-to-wafer bonding process. Each memory die 900 comprises an array 920 of memory cells and an array of memory-die bonding pads 988. Each logic die 700 comprises a logic circuit 720 configured to control operation of the array 920 of memory cells, and further comprises an array of logic-die bonding pads 788 that is bonded to the array of memory-die bonding pads 988.

Plasma treatment processes and chemical cleaning processes can be performed to clean the surfaces of the memory-die bonding pads 988 and the logic-die bonding pads 788 prior to bonding the logic-die bonding pads 788 to the memory-die bonding pads 988. A bonded assembly of a two-dimensional array of logic dies 700 on a wafer 1000 and a two-dimensional array of laterally spaced memory dies 900 can be formed. The logic-die bonding pads 788 can be bonded to the memory-die bonding pads 988 via metal-to-metal bonding, such as copper-to-copper bonding, by bringing the bonding pads in contact with each other and heating the assembly to a suitable bonding temperature, which may be in a range from 300 degrees Celsius to 400 degrees Celsius. Further, dielectric-to-dielectric bonding may be performed at interfaces between logic-die dielectric material layers 760 and memory-die dielectric material layers 960.

Upon bonding the memory dies 900 to the logic dies 700, each memory die 900 has a first planar projection shape in a plan view along a vertical direction, and a respective underlying logic die 700 that is bonded to the memory die 900 has a second planar projection shape in the plan view. The second planar projection shape contains the entirety of the first planar projection shape and a first additional planar projection shape located on an outside of a periphery of the first planar projection shape.

In one embodiment, the logic die 700 comprises surface metal pads 787 having first planar horizontal surfaces located within a horizontal plane including interfaces between the array of logic-die bonding pads 788 and the array of memory-die bonding pads 988 and located within an area of the first additional planar projection shape in the plan view. In one embodiment, the entirety of the surface metal pads 787 of the logic die 700 may be located within the area of the first additional planar projection shape of the logic die 700. In one embodiment, the surface metal pads 787 do not have any areal overlap with the first planar projection shape in the plan view. In one embodiment, the surface metal pads 787 may have a same material composition and a same vertical extent as the array of logic-die bonding pads 788.

In one embodiment, each of the surface metal pads 787 may be electrically connected to a respective one of the logic-die bonding pads 788 through a respective first subset of logic-die metal interconnect structures 780 located within said one of the logic dies 700. In one embodiment, the logic circuit 720 comprises a power supply circuit 72P configured to provide a power supply voltage to devices in the memory die 900 and/or the logic die 700, and an output node of the power supply circuit 72P may be electrically connected to at least one of the surface metal pads 787 through a second subset of logic-die metal interconnect structures 780.

The logic-die dielectric material layer 760 of each logic die 700 can be contacted by the passivation dielectric layer 789 at the horizontal plane including the interfaces between the array of logic-die bonding pads 788 and the array of memory-die bonding pads 988. For each logic die 700, the contact area with the passivation dielectric layer 789 may be located entirely within the first additional planar projection shape of the bonded memory die 900 in the plan view. In one embodiment, the passivation dielectric layer 789 is laterally spaced from the memory die 900 by a gap region GR. In one embodiment, the gap region GR may have a shape of a frame in the plan view.

In one embodiment, each memory die 900 comprises an alternating stack (32, 46) of insulating layers 32 and electrically conductive layers 46, memory openings 49 vertically extending through the alternating stack (32, 46), and memory opening fill structures 58 located in the memory openings 49. Each of the memory opening fill structures 58 comprises a respective vertical stack of memory elements (e.g., portions of the memory film 50) located at levels of the electrically conductive layers 46 and a vertical semiconductor channel 60. In one embodiment, a subset of memory-die metal interconnect structures within the memory die 900 comprises a connection via structure 486 that vertically extends through a stepped dielectric material portion 65.

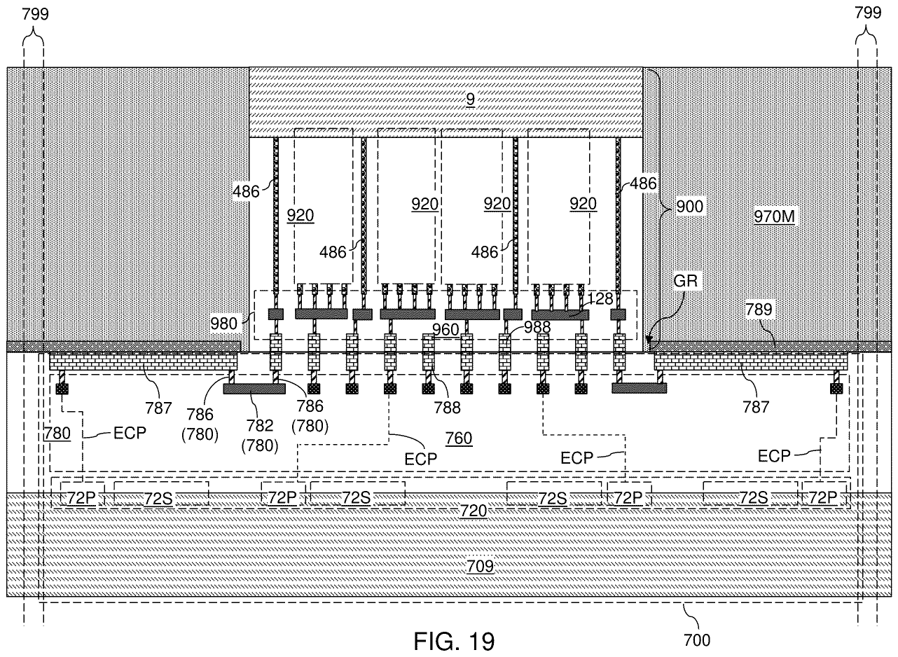

Referring to FIG. 19, a molding compound may be applied over the two-dimensional array of logic dies 700 around the memory dies 900. The molding compound may include an epoxy-containing compound that can be hardened (i.e., cured) to provide a dielectric material portion having sufficient stiffness and mechanical strength. The molding compound may include epoxy resin, hardener, silica (as a filler material), and other additives. The molding compound may be provided in a liquid form or in a solid form depending on the viscosity and flowability.

The molding compound may be cured at a curing temperature to form a molding compound matrix 970M. The molding compound matrix 970M laterally encloses each of the memory dies 900. The combination of the two-dimensional array of logic dies 700 sharing the logic-die substrate 709 (e.g., the wafer 1000), the two-dimensional array of memory dies 900, and the molding compound matrix 970M constitutes a reconstituted wafer. The molding compound matrix 970M may be a continuous material layer that extends across the entirety of the area of the reconstituted wafer.

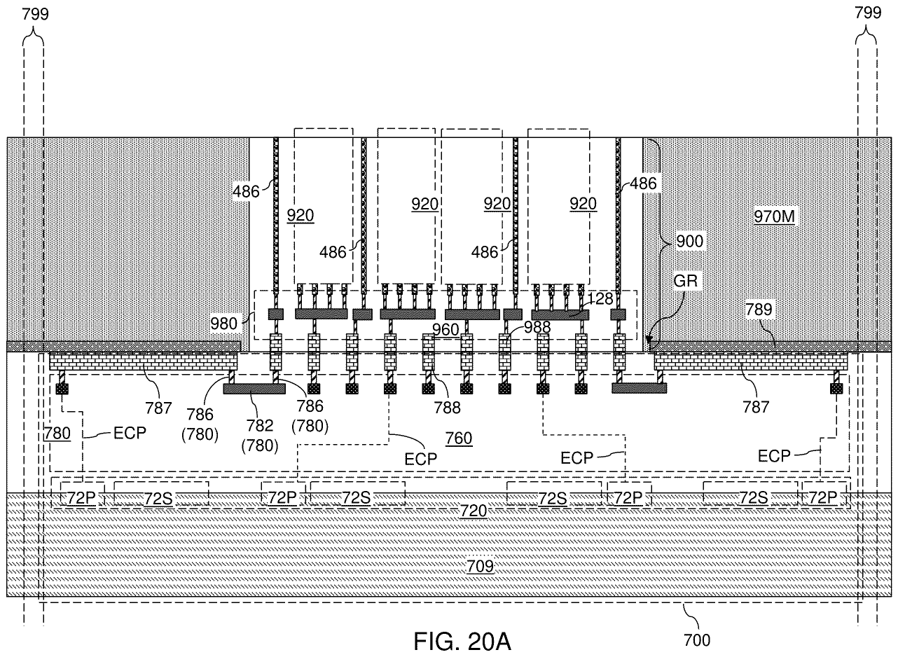

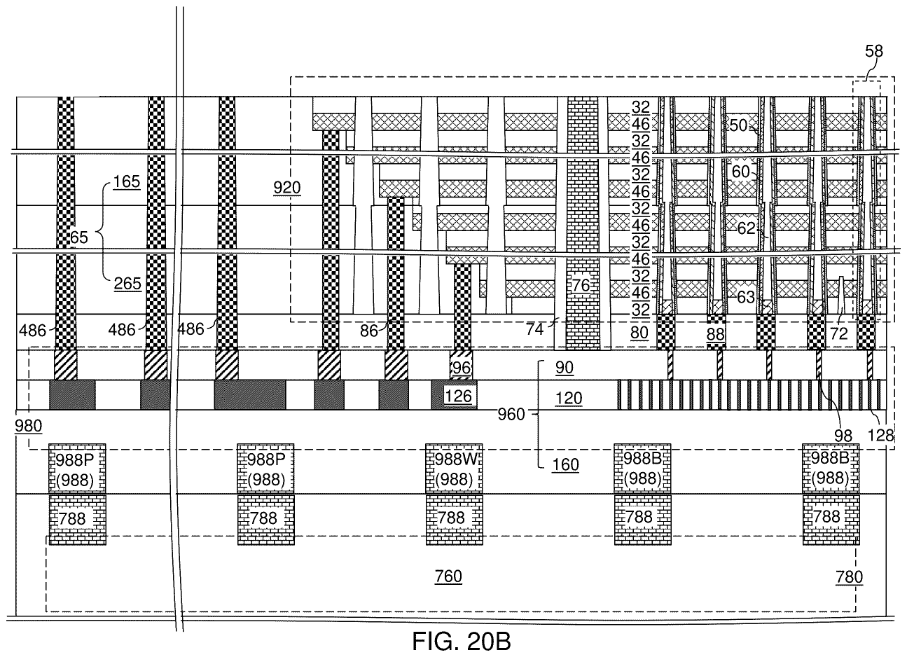

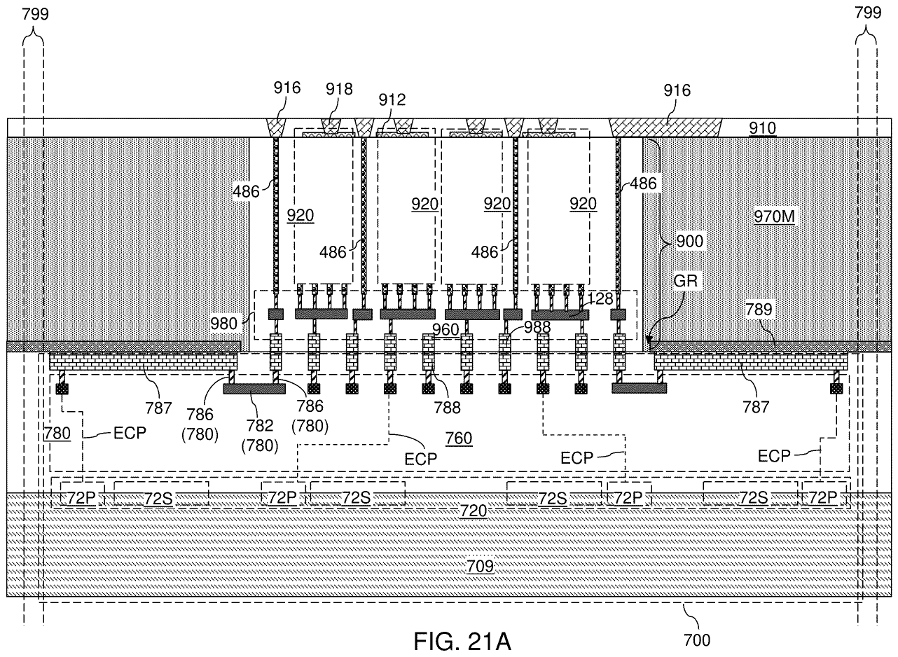

Referring to FIGS. 20A and 20B, material portions overlying the horizontal plane including the backside surfaces of the alternating stacks (32, 46) may be removed. For example, the entirety of the substrate 9 of each memory die 900 and excess portions of the molding compound matrix 970M that overlie the horizontal plane including the backside surfaces of the alternating stacks (32, 46) may be removed by performing a set of at least one material removal processes including a grinding process, a polishing process, an anisotropic etch process, and/or an isotropic etch process. In one embodiment, a terminal step of the set of at least one material removal process may comprise a chemical mechanical polishing process that removes the materials of the substrates 9 of the memory dies 900 and the molding compound matrix 970M selectively to the material of the insulating layers 32 and the stepped dielectric material portions 65. Physically exposed backside surfaces of the alternating stacks (32, 46), the stepped dielectric material portions 65, and the remaining portion of the molding compound matrix 970M may be located within a same horizontal plane. Generally, backside surfaces of the three-dimensional memory arrays 920 may be physically exposed. Further, end surfaces of the vertical semiconductor channels 60 and end surfaces of the connection via structures 486 may be physically exposed.

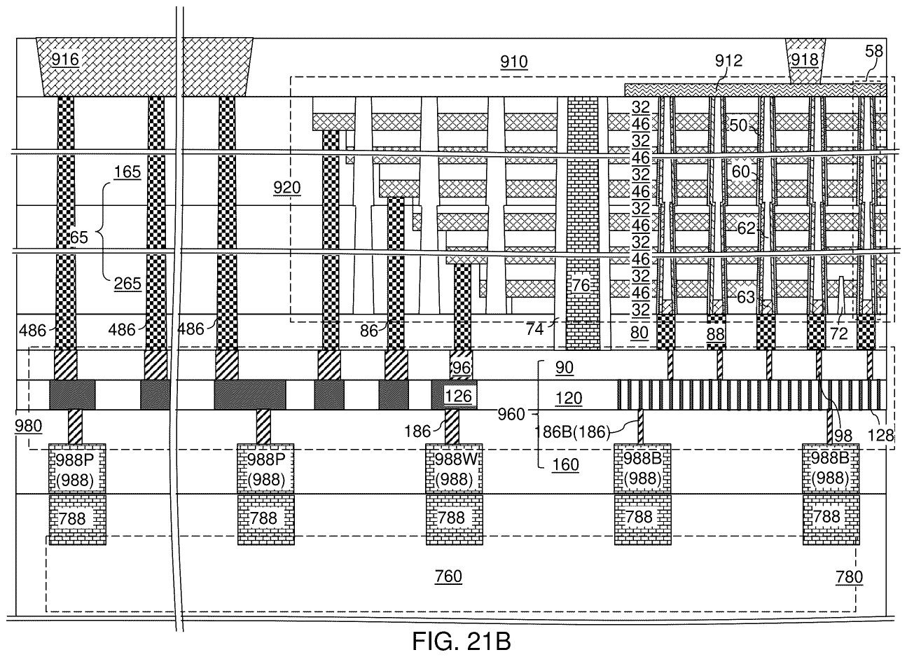

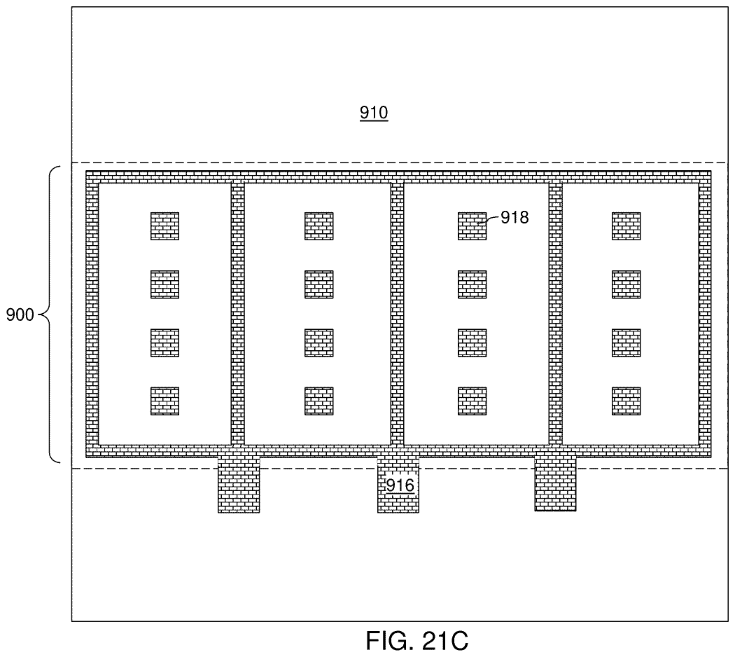

Referring to FIGS. 21A-21C, at least one source layer 912 can be formed on each memory die 900 on the physically exposed bottom surfaces of a respective subset of the vertical semiconductor channels 60. The source layer 912 may comprise a heavily doped semiconductor layer (e.g., heavily doped polysilicon layer) and/or an electrically conductive layer (e.g., Ti, TiN, W, WN, etc.). A backside insulating layer 910 can be formed over the at least one source layer 912, backside surfaces of the alternating stacks (32, 46), backside surfaces of the first stepped dielectric material portions 165, and the backside horizontal surface of the molding compound matrix 970M. The backside insulating layer 910 comprises an insulating material such as silicon oxide, silicon nitride, and/or polyimide.

Backside bonding pads (918, 916) can be formed within the backside insulating layer 910. The backside bonding pads (918, 916) may comprise source-connection backside bonding pads 918 that are electrically connected to the source layer(s) 912, and power-connection backside bonding pads 916 that are electrically connected to, and may contact, a respective subset of the connection via structures 486. In some embodiments, one or more power-connection backside bonding pads 916 may be formed as at least one ring structure, at least one multi-ring structure, and/or at least one nested structure within the area of a respective memory die 900, as shown in FIG. 21C. Alternatively, a plurality of power-connection backside bonding pads 916 may be laterally spaced apart from each other within the area of a respective memory die 900.

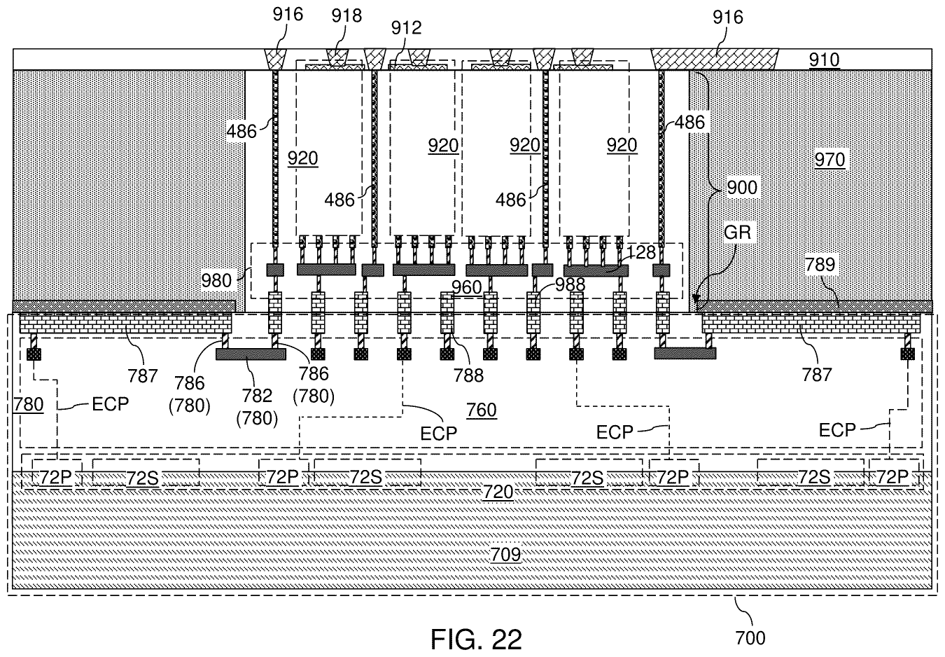

Referring to FIG. 22, the reconstituted wafer may be diced along the dicing channels 799. Each diced portion of the reconstituted wafer comprises a memory structure that includes a bonded assembly of a logic die 700, a memory die 900, a passivation dielectric layer 789, a molding compound frame 970 which is diced portion of the molding compound matrix 970M, a backside insulating layer 910, and backside bonding pads (918, 916). In one embodiment, the sidewalls of the logic die 700, the outer sidewalls of the molding compound frame 970, and the outer sidewalls of the backside insulating layer 910 of each bonded assembly (700, 900, 789, 970, 910, 918, 916) may be formed within a same set of vertical planes.

In one embodiment, outer sidewalls of the molding compound frame 970 are located within a set of vertical planes that defines a planar projection shape that is the same as the second planar projection shape in the plan view for each bonded assembly (700, 900, 970, 910, 918, 916). In one embodiment, all outer sidewalls of the passivation dielectric layer 789 may be located within the set of vertical planes containing the outer sidewalls of the molding compound frame 970.

Referring to FIGS. 1-22 and according to the first embodiment of the present disclosure, a semiconductor structure comprises: a memory die 900 comprising an array 920 of memory cells (e.g., portions of the memory film 50) and an array of memory-die bonding pads 988, and a logic die 700 comprising a logic circuit 720 configured to control operation of the array 920 of memory cells, an array of logic-die bonding pads 788 that is bonded to the array of memory-die bonding pads 988, and surface metal pads 787 having first planar horizontal surfaces located within a horizontal plane including interfaces between the array of logic-die bonding pads 788 and the array of memory-die bonding pads 988 and located within an area not overlapping with an area of the memory die 900.

In one embodiment, the surface metal pads 787 have a same material composition as and a same vertical extent as the logic-die bonding pads 788. In one embodiment, one of the surface metal pads 787 is electrically connected to one of the logic-die bonding pads 788 by a first metal via structure 786 connected to a bottom end of said one of the surface metal pads 787, a second metal via structure 786 connected to a bottom end of said one of the logic-die bonding pads 788, and an interconnect-level metal line 782 connected to bottom ends of the first metal via structure 786 and the second metal via structure 786.

In one embodiment, the memory die 900 has a first planar projection shape in a plan view along a vertical direction; the logic die 900 has a second planar projection shape in the plan view, wherein the second planar projection shape contains an entirety of the first planar projection shape and a first additional planar projection shape located on an outside of a periphery of the first planar projection shape; the surface metal pads 787 are located within an area of the first additional planar projection shape in the plan view; and the surface metal pads 787 do not have any areal overlap with the first planar projection shape in the plan view.

In one embodiment, the semiconductor structure further comprises a backside insulating layer 910 located on a planar surface of the memory die 900 that is located on an opposite side of the logic die 700, wherein the backside insulating layer 910 has a set of outer sidewalls that defines a third planar projection shape containing the entirety of the first planar projection shape and a second additional planar projection shape located on the outside of the periphery of the first planar projection shape in the plan view. The second additional planar projection shape may be the same as the first additional planar projection shape. The third planar projection shape may be the same as the second planar projection shape if the sidewalls of the logic die 700 are vertically coincident with the set of outer sidewalls of the backside insulating layer 910.

In one embodiment, the semiconductor structure further comprises backside bonding pads (918, 916) embedded within the backside insulating layer 910, wherein one of the backside bonding pads (918, 916) is electrically connected to said one of the logic-die bonding pads 788 through one of the memory-die bonding pads 988 and through a subset of memory-die metal interconnect structures within the memory die 900. In one embodiment, the subset of memory-die metal interconnect structures comprises a connection via structure 486 that vertically extends through a stepped dielectric material portion 65 located within the memory die 900 and contacting said one of the backside bonding pads (918, 916).

In one embodiment, the memory die 900 comprises: an alternating stack (32, 46) of insulating layers 32 and electrically conductive layers 46; memory openings 49 vertically extending through the alternating stack (32, 46); and memory opening fill structures 58 located in the memory openings 49, wherein each of the memory opening fill structures 58 comprises a respective vertical stack of memory elements (e.g., portions of the memory film 50) located at levels of the electrically conductive layers 46 and a vertical semiconductor channel 60.

In one embodiment, the logic circuit 720 comprises a power supply circuit 72P configured to provide a power supply voltage to devices in the memory die 900 and/or the logic die 700; and an output node of the power supply circuit 72P is electrically connected to said one of the surface metal pads 787 through a subset of logic-die metal interconnect structures 780 embedded within the logic die 700.

In one embodiment, the semiconductor structure comprises a passivation dielectric layer 789 contacting the surface metal pads 787 at the horizontal plane including the interfaces between the array of logic-die bonding pads 788 and the array of memory-die bonding pads 988 and located entirely within the first additional planar projection shape in the plan view. In one embodiment, the passivation dielectric layer 789 is laterally spaced from the memory die 900 by a gap region GR. In one embodiment, the semiconductor structure further comprises a molding compound frame 970 laterally surrounding the memory die 900 and contacting a horizontal surface segment of the logic die 700 in the gap region GR.

In one embodiment, outer sidewalls of the molding compound frame 970 are located within a set of vertical planes that defines a planar projection shape that is the same as the second planar projection shape in the plan view. In one embodiment, all outer sidewalls of the passivation dielectric layer 789 are located within the set of vertical planes containing the outer sidewalls of the molding compound frame 970. In one embodiment, all first planar horizontal surfaces of the surface metal pads 787 are in contact with the passivation dielectric layer 789.

According to a second embodiment of the present disclosure, the logic-die metal interconnect structures 780 in the logic dies 700 may be configured to facilitate electrical routing between the first bit lines 128 and the sense amplifiers 72S. The features employed for the second embodiment of the present disclosure may be employed in conjunction with the features described with respect to the first embodiment of the present disclosure as described above, or may be employed in lieu of the features described with respect to the first embodiment of the present disclosure.

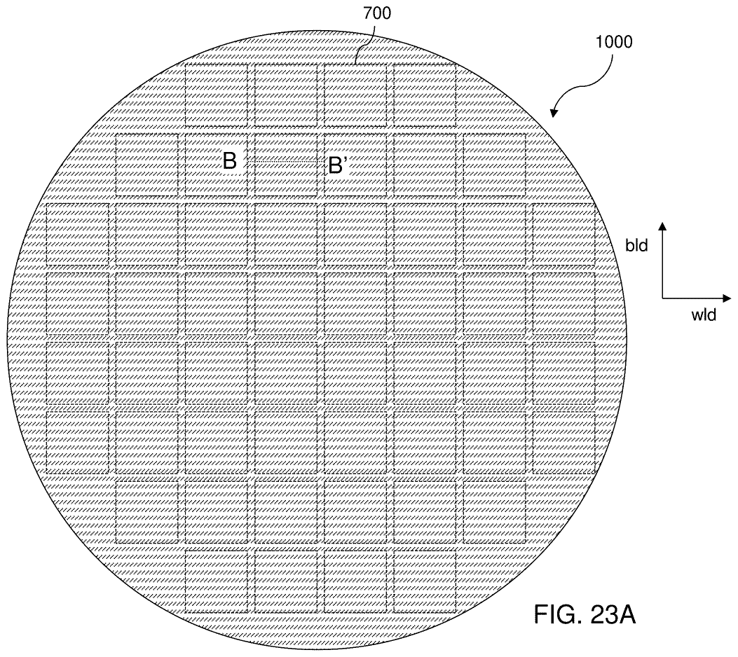

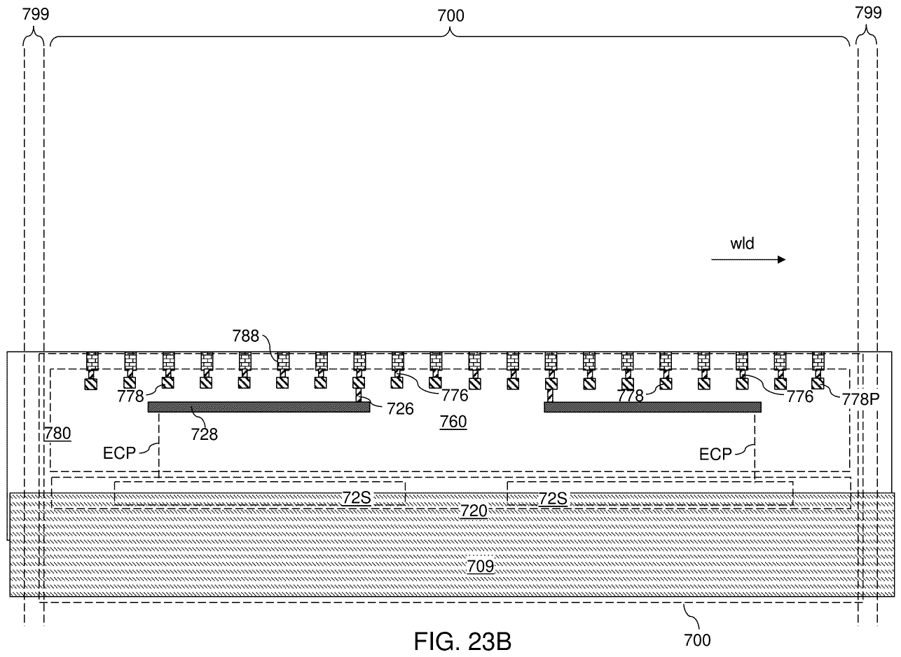

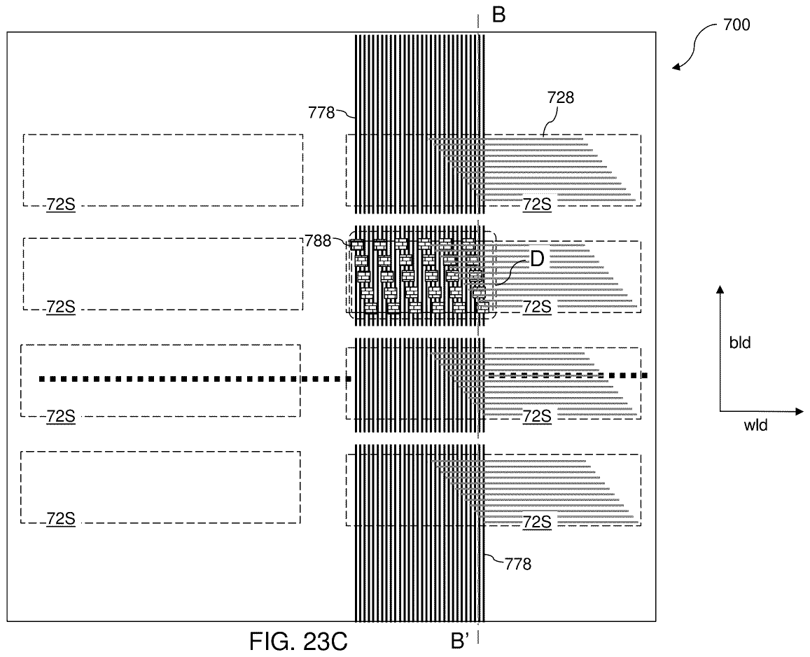

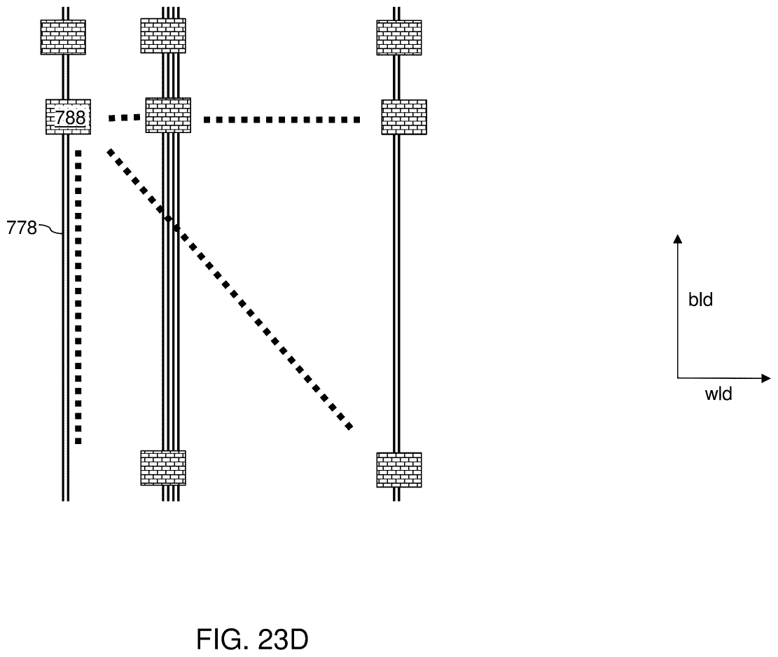

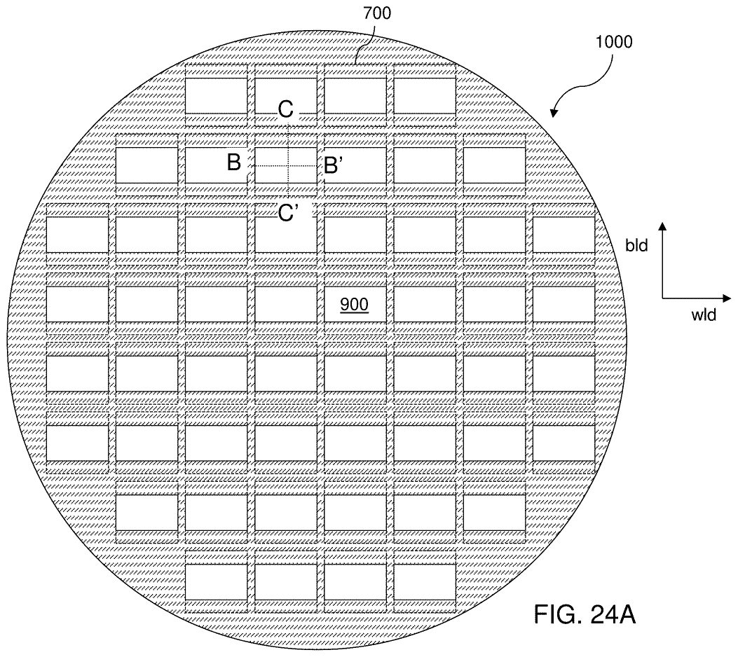

FIGS. 23A-23D illustrate a wafer 1000 supporting a two-dimensional array of logic dies 700 which may be employed to form a reconstituted wafer including a two-dimensional array of bonded assemblies of a respective logic die 700 and a respective memory die 900, according to the second embodiment of the present disclosure.

The wafer 1000 illustrated in FIGS. 23A-23D may be derived from the wafer 1000 illustrated in FIGS. 16A-16C by adding second bit lines 778 and optional crossed bit lines 728 as a subset of the logic-die metal interconnect structures 780. Thus, the second bit lines 778 and optional crossed bit lines 728 are located in the logic die 700 rather than in the memory die 900.

As used herein, “crossed bit lines” 728 refer to a subset of bit lines that extend in a different horizontal direction than the first bit lines 128 and the second bit lines 778. For example, the first bit lines 128 and the second bit lines 778 may extend in the same horizontal bit line direction “bld”, and the crossed bit lines 728 may extend in a horizontal word line direction wld that is perpendicular to the bit line direction bld. The word line direction wld is parallel to the direction of the word lines 46 in the memory die 900.

In one embodiment, the crossed bit lines 728 are formed at a different (e.g., lower) vertical level than the second bit lines 778 in the logic die 700. Thus, the second bit lines 778 may be located between the first bit lines 128 and the crossed bit lines 728 in the vertical direction. The crossed bit lines 728 may be more distal from the drain regions 63 than the first bit lines 128 and the second bit lines 778. As such, the crossed bit lines 778 can be third bit lines that are more distal from the drain regions 63 than the first bit lines 128 and the second bit lines 778.

The surface metal pads 787 of the first embodiment described with reference to FIGS. 16A-16C may optionally be present as part of the logic-die metal interconnect structures 780 of each logic die 700 or they may be omitted. While FIGS. 23A-23D illustrate an embodiment in which surface metal pads 787 are not formed, other embodiments are expressly contemplated herein in which surface metal pads 787 are formed in addition to the second bit lines 778 and the crossed bit lines 728 in each of the logic dies 700.

Each logic die 700 comprises sense amplifiers 72S which apply operating voltages to the first bit lines 128, the second bit lines 778 and the crossed bit lines 728, and an array of logic-die bonding pads 788. The crossed bit lines 728 are vertically located between the logic-die bonding pads 788 and the sense amplifiers 72S. According to an aspect of the present disclosure, the logic-die metal interconnect structures 780 of each logic die 700 are configured to provide electrically conductive paths ECP between the sense amplifiers 72S of the logic die 700 and the first bit lines 128 of a memory die 900 to be subsequently bonded to the logic die 700. In one embodiment, the logic-die metal interconnect structures 780 in each logic die 700 comprise, from bottom to top, the crossed bit lines 728, first metal via structures 726, the second bit lines 778, optional peripheral second-bit-line-level metal lines 778P, second metal via structures 776, and logic-die bonding pads 788 and optional surface metal pads 787.

The crossed bit lines 128 electrically connect the sense amplifiers 72S to the second bit lines 778 using the first metal via structures 726 and the electrically conductive path ECP. The crossed bit lines 728 extend perpendicular to the bit line direction bld to permit an easier electrical connection between the sense amplifiers 72S and the second bit lines 778. The second bit lines 778 are electrically connected to the first bit lines 128 using the second via structures 776, the bonding pads (788, 988) and the memory-die metal interconnect structures 980. Thus, the crossed bit lines 728 are a subset of the bit lines that are employed to provide electrically conductive paths between the drain regions 63 of memory devices in a memory die 900 and the sense amplifiers 72S in the logic die 700.

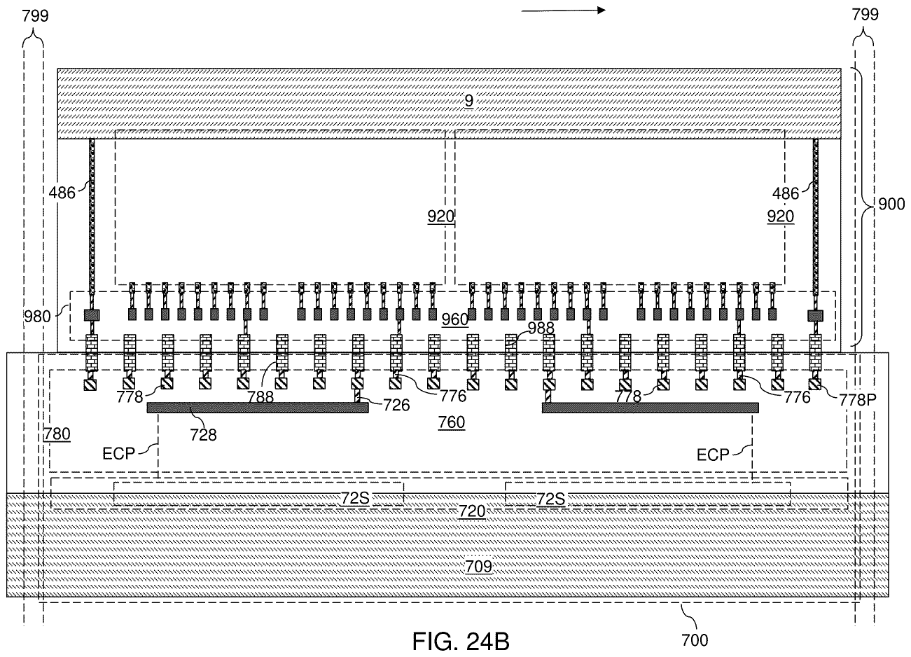

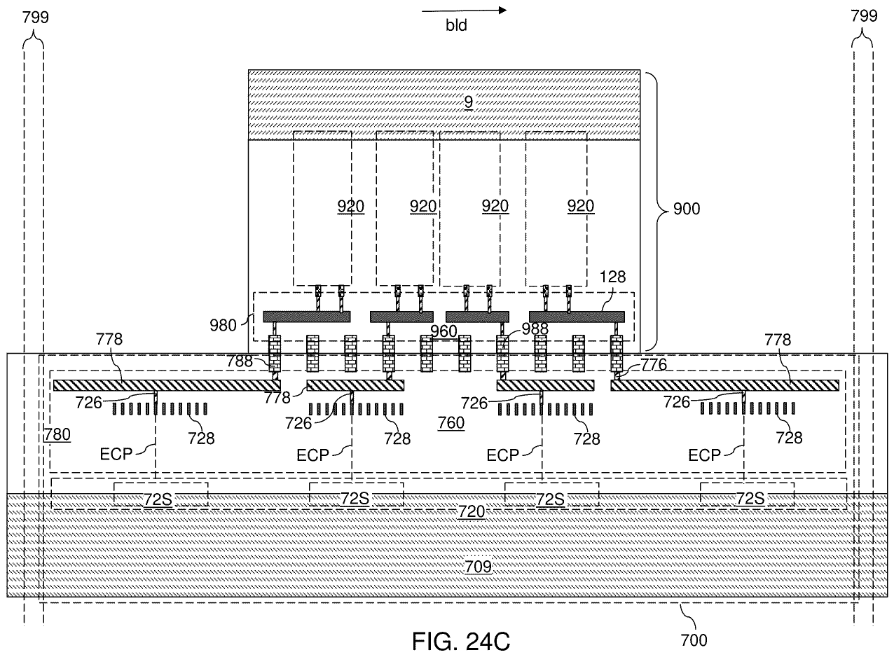

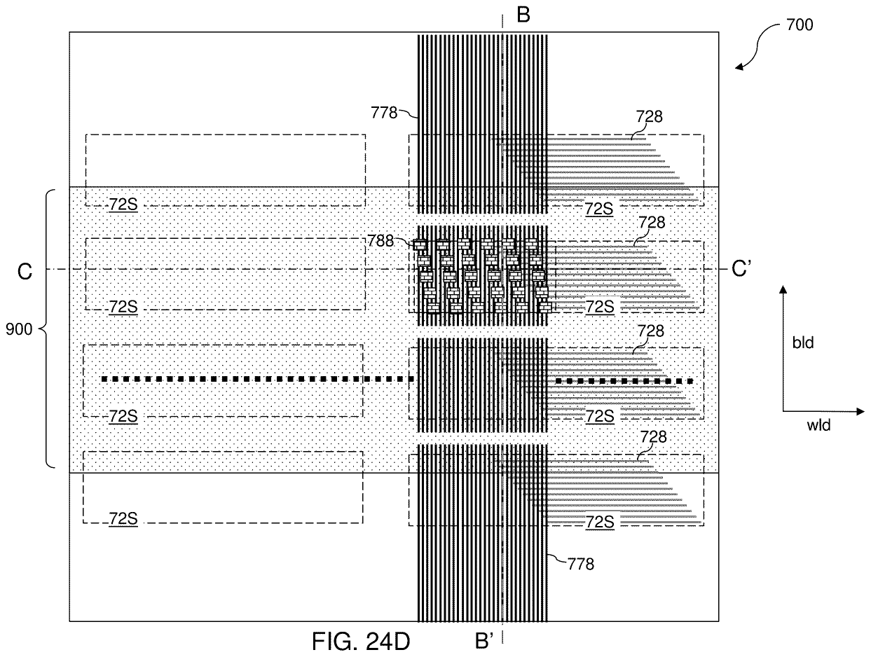

Referring to FIGS. 24A-24D, the processing steps described with reference to FIGS. 18A-18C can be performed to bond memory dies 900 to the logic dies 700 located in the wafer. Specifically, memory dies 900 can be individually bonded to a respective logic die 700 within the two-dimensional array of logic dies 700 located on the wafer 1000, as described above with respect to the first embodiment.

Upon bonding the memory dies 900 to the logic dies 700, each memory die 900 has a first planar projection shape in a plan view along a vertical direction, and a respective underlying logic die 700 that is bonded to the memory die 900 has a second planar projection shape in the plan view. The second planar projection shape contains the entirety of the first planar projection shape and a first additional planar projection shape located on an outside of a periphery of the first planar projection shape. For example, as shown in FIGS. 24A and 24C, the memory die 900 may have shorter lateral length than the logic die 700 along the bit line direction bld. The memory die 900 may have about the same lateral length as the logic die 700 along the word line direction wld, as shown in FIGS. 24A and 24B.

In one embodiment, the memory die 900 may comprise a first pair of parallel sidewalls that are parallel to the bit line direction bld, and a second pair of parallel sidewalls that are perpendicular to the bit line direction bld and are parallel to the word line direction wld. In one embodiment, a first subset of the second bit lines 778 intersect a respective sidewall of the memory die 900 that is perpendicular to the bit line direction bld in the plan view. In one embodiment, a second subset of the second bit lines 778 does not intersect any sidewall of the memory die 900, and is located entirely within a projection shape of the memory die 900.

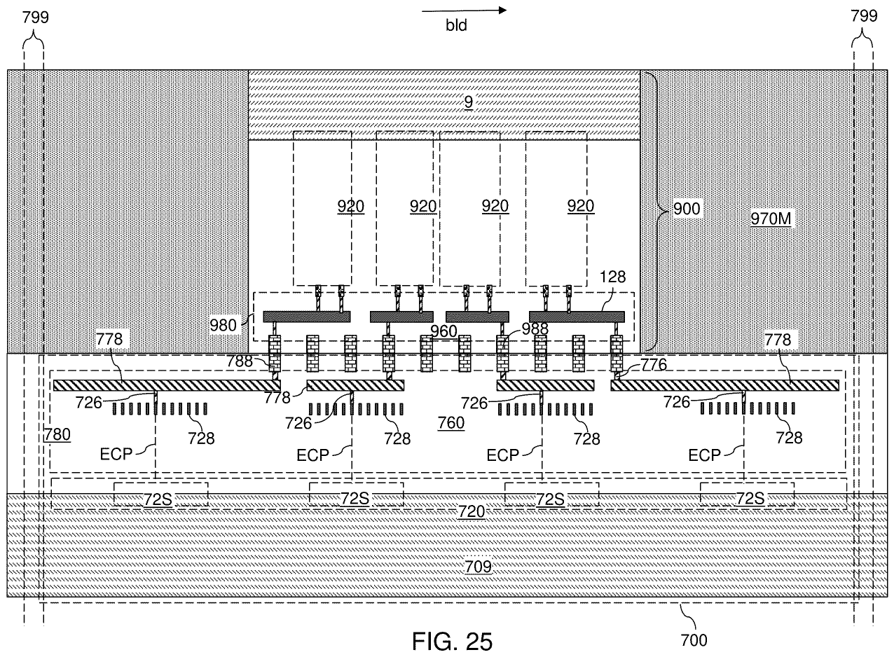

Referring to FIG. 25, the processing steps described with reference to FIG. 19 may be performed to form a molding compound matrix 970M. The molding compound matrix 970M laterally encloses each of the memory dies 900. The combination of the two-dimensional array of logic dies 700 sharing the logic-die substrate 709, the two-dimensional array of memory dies 900, and the molding compound matrix 970M constitutes a reconstituted wafer. The molding compound matrix 970M may be a continuous material layer that extends across the entirety of the area of the reconstituted wafer.

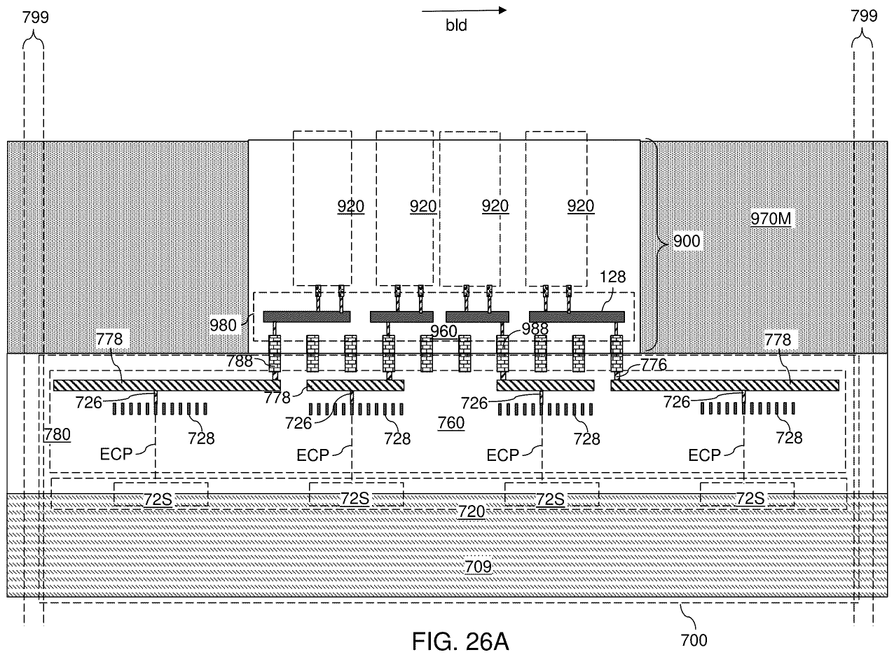

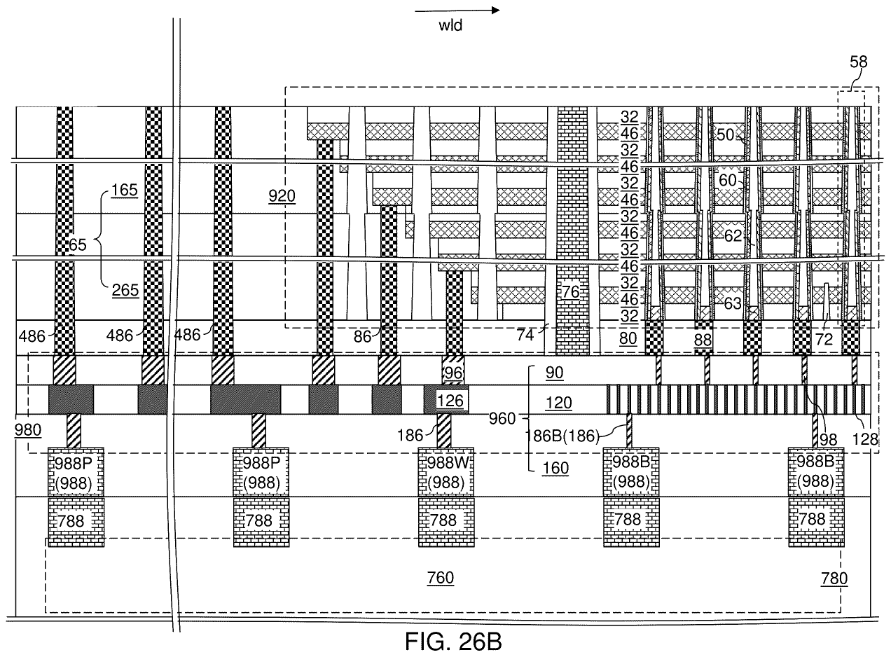

Referring to FIGS. 26A and 26B, the processing steps described with reference to FIGS. 20A and 20B may be performed to remove material portions overlying the horizontal plane including the backside surfaces of the alternating stacks (32, 46). For example, the entirety of the substrate 9 of each memory die 900 and excess portions of the molding compound matrix 970M that overlie the horizontal plane including the backside surfaces of the alternating stacks (32, 46) may be removed by performing a set of at least one material removal processes including a grinding process, a polishing process, an anisotropic etch process, and/or an isotropic etch process. In one embodiment, a terminal step of the set of at least one material removal process may comprise a chemical mechanical polishing process that removes the materials of the substrates 9 of the memory dies 900 and the molding compound matrix 970M selectively to the material of the insulating layers 32 and the stepped dielectric material portions 65. Physically exposed backside surfaces of the alternating stacks (32, 46), the stepped dielectric material portions 65, and the remaining portion of the molding compound matrix 970M may be located within a same horizontal plane. Generally, backside surfaces of the three-dimensional memory arrays 920 may be physically exposed. Further, end surfaces of the vertical semiconductor channels 60 and end surfaces of the connection via structures 486 may be physically exposed.

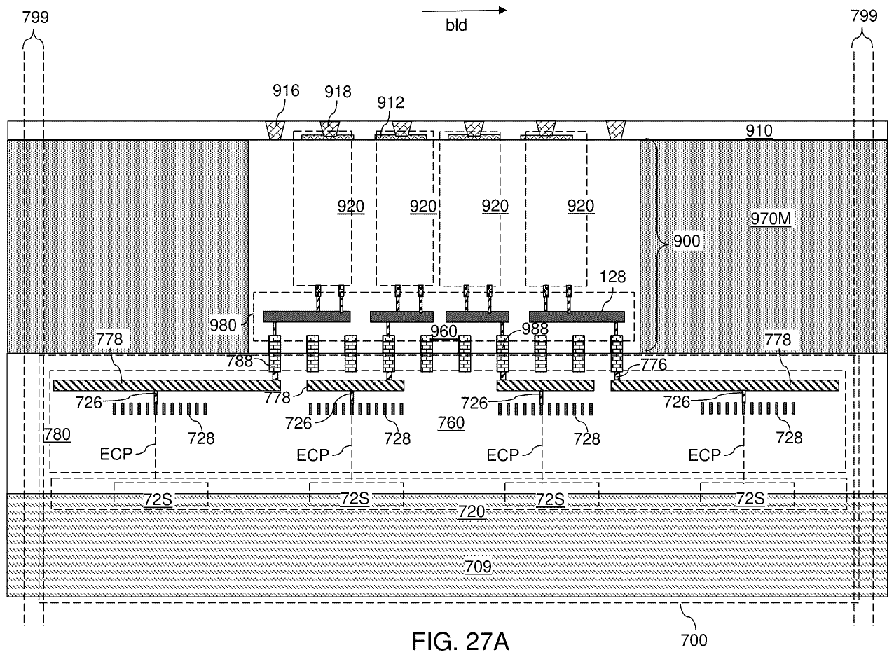

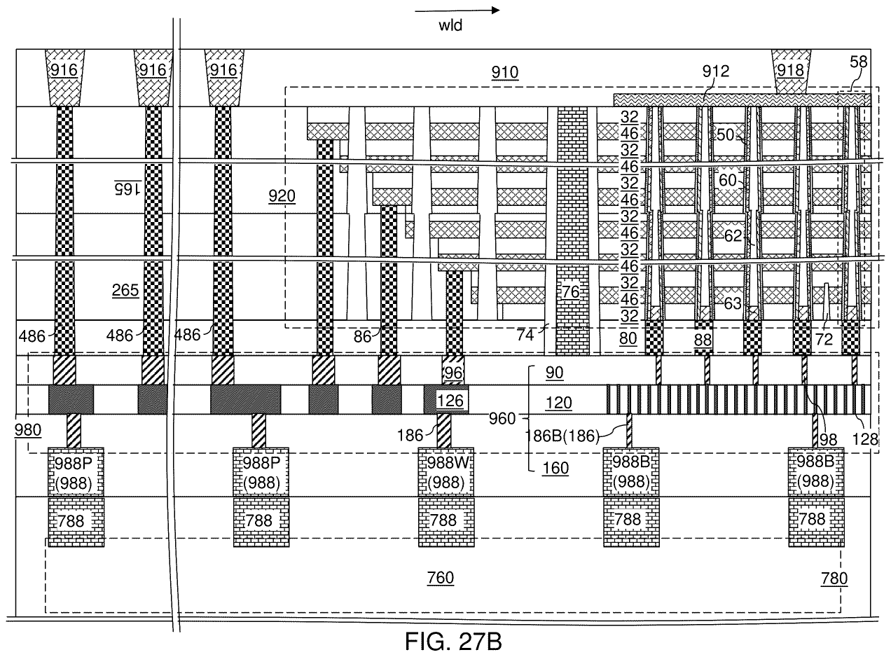

Referring to FIGS. 27A and 27B, at least one source layer 912 can be formed on each memory die 900 on the physically exposed bottom surfaces of a respective subset of the vertical semiconductor channels 60. A backside insulating layer 910 can be formed over the backside surfaces of the alternating stacks (32, 46), backside surfaces of the first stepped dielectric material portions 165, and the backside horizontal surface of the molding compound matrix 970M. The backside insulating layer 910 comprises an insulating material such as silicon oxide, silicon nitride, and/or polyimide.

Backside bonding pads (918, 916) can be formed within the backside insulating layer 910. The backside bonding pads (918, 916) may comprise source-connection backside bonding pads 918 that are electrically connected to a respective one of the source layers 912, and power-connection backside bonding pads 916 that are electrically connected to. and may contact. a respective subset of the connection via structures 486.

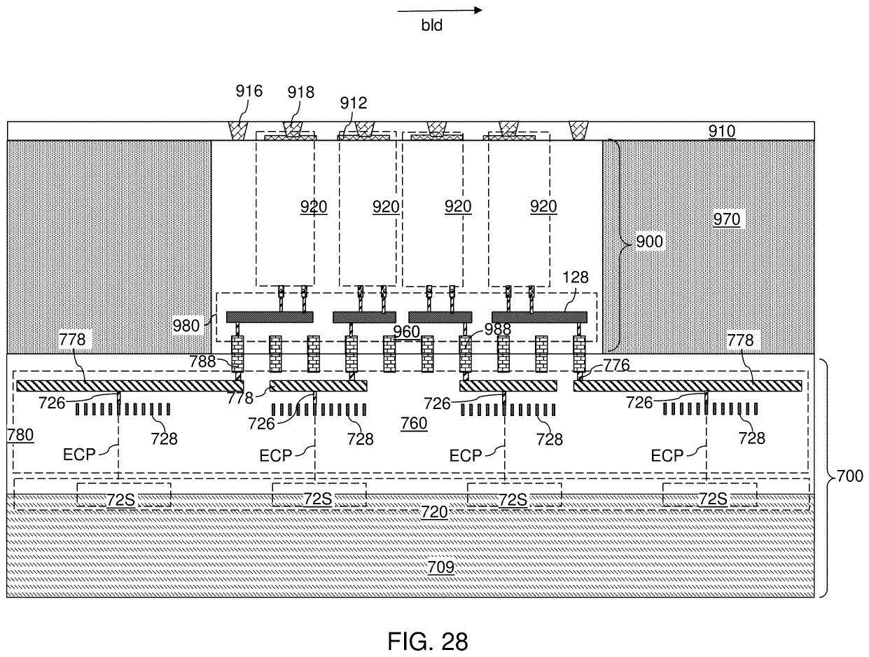

Referring to FIG. 28, the reconstituted wafer may be diced along the dicing channels 799. Each diced portion of the reconstituted wafer comprises a memory structure that includes a bonded assembly of a logic die 700, a memory die 900, a molding compound frame 970, a backside insulating layer 910, and backside bonding pads (918, 916).

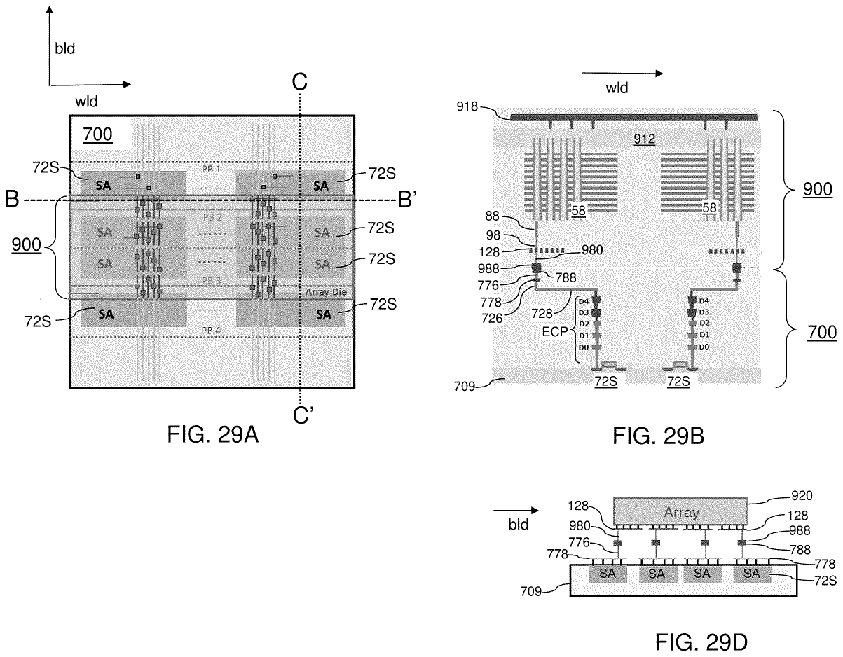

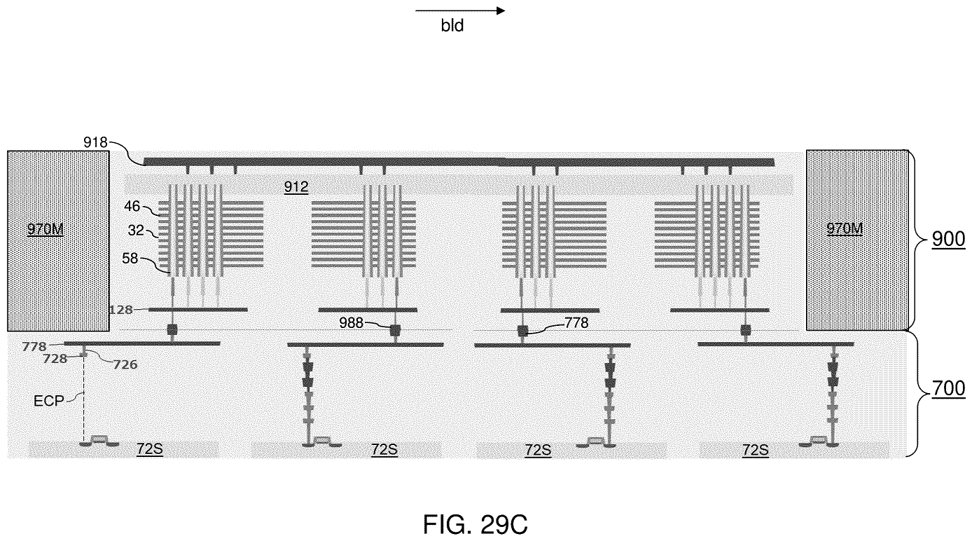

Referring to FIGS. 28 and 29A-29D, each memory die 900 has a first planar projection shape in a plan view, and each logic die 700 has a second planar projection shape in the plan view, as discussed above. Upon bonding of the memory die 900 and the logic die 700, the second planar projection shape of the logic die 700 contains the entirety of the first planar projection shape of the memory die 900 and a first additional planar projection shape located on an outside of a periphery of the first planar projection shape in the plan view.

According to an aspect of the present disclosure, the second bit lines 778 laterally extend in the bit line direction bld across an area of the logic die 700 that has an areal overlap with the memory die 900 bonded thereto and areas of the logic die 700 that do not have any areal overlap with the memory die 900 bonded thereto. In other words, the second bit lines 778 are configured to provide laterally-extending conductive paths such that the second bit lines 778 laterally extend beyond the area of the memory die 900 to electrically connect the sense amplifiers 72S located outside the area of the memory die 900 to the first bit lines 128 located in the memory die. Thus, the second bit lines 778 extend through the area of the first planar projection shape of the memory die 900 and beyond the area of the first planar projection shape in the plan view to electrically connect sense amplifiers 72S located in the logic die 700 laterally beyond the area of the memory die 900 (i.e., beyond area of the first planar projection shape in the area of the first additional planar projection shape). For example, the second bit lines 778 connect the sense amplifiers 72S located in logic die planes PB1 and PB4 that are located outside the area of the memory die 900 to the first bit lines 128 located in the memory die.

In one embodiment, a first subset of the sense amplifiers 72S is located at least partly within the first additional planar projection shape in the plan view (e.g., in logic die planes PB1 and PB4 outside the area of the logic die 900), while a second subset of the sense amplifiers 72S is located entirely within the first planar projection shape in the plan view (e.g., in logic die planes PB2 and PB3 under the logic die 900). In one embodiment, the electrically conductive paths ECP are electrically connected to a first subset of the logic-die bonding pads 788 which is bonded to the first subset of the memory-die bonding pads 988. In one embodiment, the sense amplifiers 72S are electrically connected to the first bit lines 128 via the bonding pads (788, 988) and the electrically conductive paths comprising second bit lines 778 (which are located within the logic die 700 between the logic-die bonding pads 788 and the crossed bit lines 728 and laterally extending along the bit line direction bld that is parallel to the first bit lines 128), the first metal via structures 726 connecting a respective one of the crossed bit lines 728 and a respective one of the second bit lines 778, the second metal via structures 776 connecting a respective second bit line 778 and a respective logic-die bonding pad 788, and optionally additional metal line and/or via structures of the electrically conductive path ECP. As shown in FIG. 29B, the additional metal line and/or via structures may include one or more metal lines (e.g., lines D0-D5) and intervening via structures which electrically connect a respective sense amplifier 72S to the crossed bit lines 128.

In one embodiment, the first metal via structures 726 and the second metal via structures 776 are located entirely within the area of the first planar projection shape in the plan view. In one embodiment, the first bit lines 128 laterally extend along a bit line direction bld; and some of the second bit lines 778 laterally extend along the bit line direction bld and have a lateral extent along the bit line direction bld that is greater than a lateral extent of the memory die 900 along the bit line direction bld. In one embodiment, the first planar projection shape is a first rectangular shape; and the first additional planar projection shape is a frame-shaped shape that is derived from a second rectangular shape by removing an area of the first rectangular shape.

The second bit lines 778 are electrically connected to the first bit lines 128 in the memory die 900 through mating pairs of logic-die bonding pads 788 and memory-die bonding pads 988. The first bit lines 128 in the memory die 900 provide the initial routing of signals between the memory cells and the sense amplifiers 72S. Thus, the signal transfer between the first bit lines 128 and the second bit lines 778 is performed along a vertical direction within the area of the memory die 900 in the plan view. The crossed bit lines 728 extend along the word line direction wld and route signals between the second bit lines 778 and the respective sense amplifier 72S across part of the area of the logic die 700.

Referring collectively to FIGS. 23A-29D and related drawings and according to the second embodiment of the present disclosure, a semiconductor structure comprises: a memory die 900 comprising a memory array 920, first bit lines 128 electrically connected to the memory array 920, and an array of memory-die bonding pads 988, wherein a first subset of the memory-die bonding pads 988 is electrically connected to a respective one of the first bit lines 128; and a logic die 700 comprising sense amplifiers 72S, an array of logic-die bonding pads 788 bonded to the memory-die bonding pads 988, and electrically conductive paths ECP electrically connecting the sense amplifiers 72S to the logic-die bonding pads 788, wherein the electrically conductive paths comprise second bit lines 778 located between the logic-die bonding pads 788 and the sense amplifiers 72S, and laterally extending from within an area of the memory die 900 to an area beyond the memory die 900.

In one embodiment, the memory die 900 has a first planar projection shape in a plan view along a vertical direction; the logic die 700 has a second planar projection shape in the plan view, wherein the second planar projection shape contains an entirety of the first planar projection shape and a first additional planar projection shape located on an outside of a periphery of the first planar projection shape; and the second bit lines 778 extend from an area within the first planar projection shape to an area within the first additional planar projection shape in the plan view.

In one embodiment shown in FIG. 29A, a first subset of the sense amplifiers 72S located in logic planes PB1 and PB4 is located at least partly within the first additional planar projection shape in the plan view, and a second subset of the sense amplifiers 72S located in logic plantes PB2 and PB3 is located entirely within the first planar projection shape in the plan view.

The combination of the second bit lines 778 and the crossed bit lines 728 provides a highly efficient signal routing system within die-to-wafer bonded memory devices, leading to improvements in signal delivery, area efficiency, and compatibility with various memory die sizes.

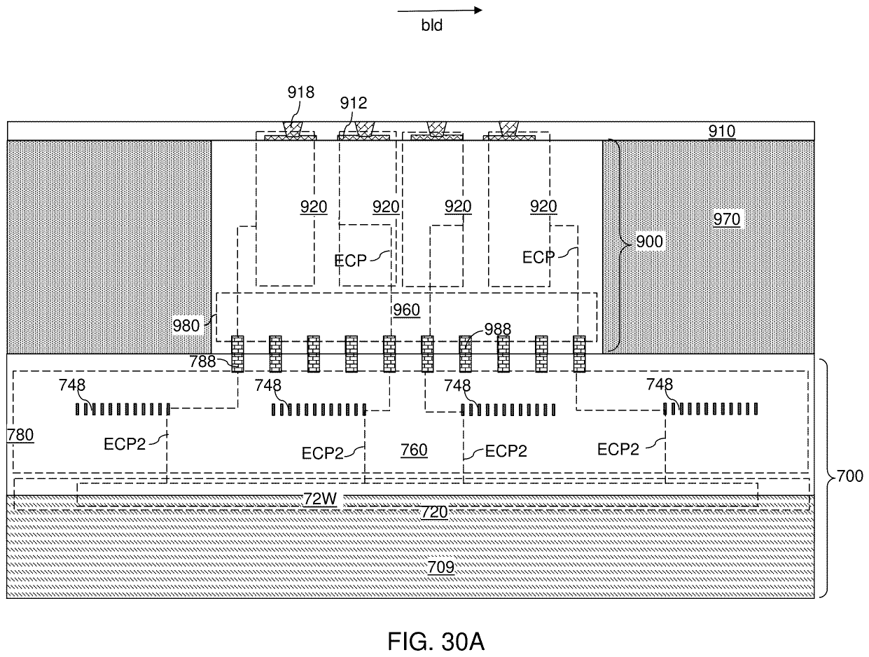

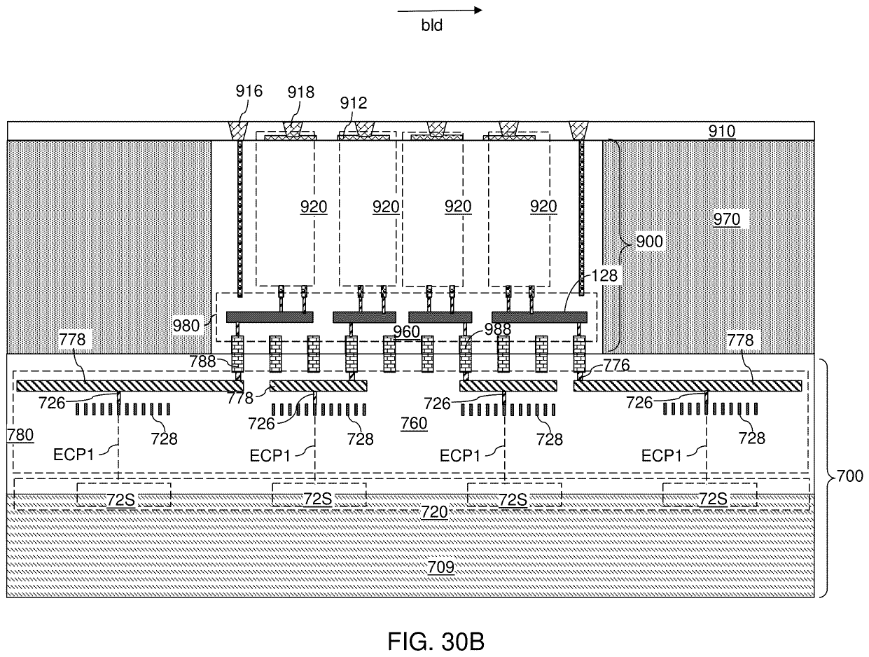

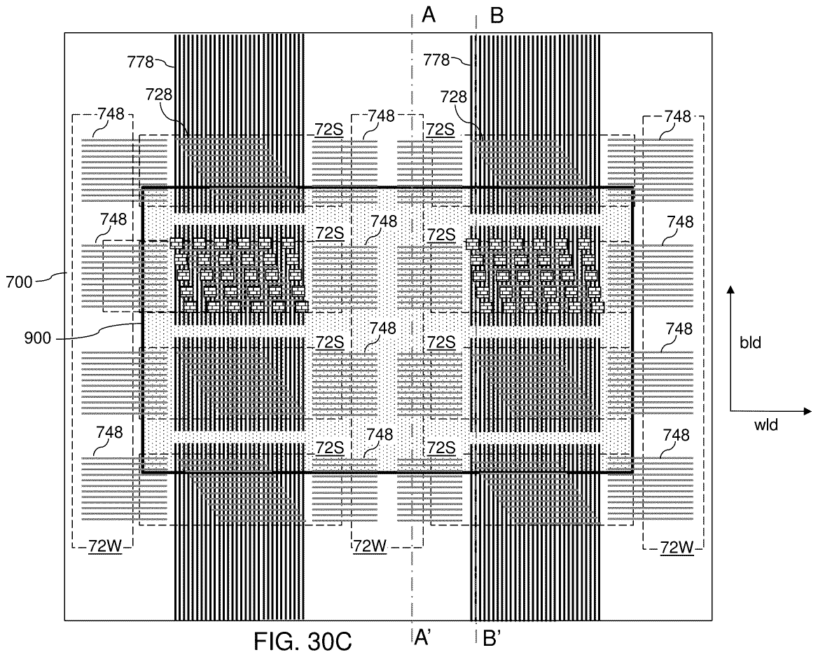

Referring to FIGS. 30A-30C, an alternative configuration of the bonded assembly of the second embodiment of the present disclosure is illustrated. The alternative configuration of the bonded assembly of the second embodiment of the present disclosure can be derived from the bonded assembly of the second embodiment of the present disclosure illustrated in FIGS. 28 and 29A-29C by employing a memory die 900 having lesser lateral extents than the memory die along the word line direction wld and along the bit line direction bld. In other words, as shown in FIG. 30C, the lateral extent of the memory die 900 along the bit line direction bld is less than the lateral extent of the logic die 700 along the bit line direction bld, and the lateral extent of the memory die 900 along the word line direction wld is less than the lateral extent of the logic die 700 along the word line direction wld. As shown in FIG. 30B, the configurations for the second bit lines 778 and the crossed bit lines 728 may be generally the same as described in the previously described embodiments.

In the alternative configuration of the bonded assembly of the second embodiment of the present disclosure, a first subset of the word line drivers 72W shown on the left and right side of FIG. 30C may be formed within regions of the logic die 700 that do not have any areal overlap with the memory die 900. In this case, word-line-connection lines 748 may be formed at the same level of metal wiring as the crossed bit lines 728 within the logic die 700. The word-line-connection lines 748 may provide electrical connections to various electrical nodes of the word line drivers 72W and a subset of the logic-die bonding pads 788 that are electrically connected to the word lines 46 of the three-dimensional memory arrays 920 in the memory die 900. As discussed above, the word lines of the three-dimensional memory arrays in the memory die 900 may be comprise a set of the electrically conductive layers 46 within the alternating stacks (32, 46). Additionally, a second subset of the word line drivers 72W (e.g., the middle word line driver 72W shown in FIG. 30C) may be formed within regions of the logic die 700 that have an areal overlap with the memory die 900. For example, the second subset of the word line drivers 72W may be located between neighboring areas of the second bit lines 778 that are laterally spaced from each other along the word line direction wld. In this case, additional word-line-connection lines 748 may overlie the second subset of the word line drivers 72W, and may provide electrical connections between the second subset of the word line drivers 72W and another subset of the logic-side bonding pads 788.

In this configuration, the memory die 900 comprises the memory array 920, the first bit lines 128 electrically connected to the memory array 920 and laterally extending along the bit line horizontal direction, and the array of memory-die bonding pads 988. A first subset of the memory-die bonding pads 988 is electrically connected to a respective one of the first bit lines 128, and a second subset of the memory-die bonding pads 988 is electrically connected to a respective word line (e.g., one of the electrically conductive layers 46) in the memory die 900. The logic die 700 comprises the sense amplifiers 72S, the word line drivers 72W, the array of logic-die bonding pads 788, the first electrically conductive paths ECP1 electrically connecting the sense amplifiers 72S to a first subset of the logic-die bonding pads 788 (as shown in FIG. 30B), and second electrically conductive paths ECP2 electrically connecting the word line drivers 72W to a second subset of the logic-die bonding pads 788 (as shown in FIG. 30A). The first electrically conductive paths ECP1 comprise second bit lines 778 that laterally extend along the bit line horizontal direction and crossed bit lines 728 laterally extending along a perpendicular word line horizontal direction. It should be understood that in each embodiment of the present disclosure, the logic circuit 720 comprises word line drivers 72W that are electrically connected to a respective one of the logic-die bonding pads 788 even if such drivers are not be expressly illustrated in the previous figures.

The array of logic-die bonding pads 788 of the logic die 700 can be bonded to the memory-die bonding pads 988 such that lateral extension direction of the first bit lines 128 is parallel to the lateral extension direction of the second bit lines 778. Upon bonding of the memory die 900 with the logic die 700, the lateral extension direction of the first bit lines 128 and the second bit lines 778 is herein referred to as a bit line direction bld, and the lateral extension direction of the crossed bit lines 728 is herein referred to as a word line direction wld. As shown in FIG. 30C, a first subset of the sense amplifiers 72S and a second subset of the sense amplifiers 72S are laterally spaced apart along the word line direction wld. A first subset of the word line drivers 72W is located within an area that does not have any areal overlap with the memory die 900, and a second subset of the word line drivers 72W is located within an area having an areal overlap with the memory die 900. In one embodiment, a subset of the word-line-connection lines 748 has an areal overlap with a respective subset of the word line drivers 72W, as shown in FIG. 30C.

In one embodiment shown in FIG. 30C, the memory die 900 has a first planar projection shape (such as a rectangular shape) in a plan view along a vertical direction, and the logic die 700 has a second planar projection shape (such as a larger rectangular shape) in the plan view. The second planar projection shape contains the entirety of the first planar projection shape and a first additional planar projection shape (which may be a frame shape) located on an outside of a periphery of the first planar projection shape. In one embodiment, the second bit lines 778 extend from an area within the first planar projection shape to an area within the first additional planar projection shape in the plan view.

The bonded assembly (700, 900) illustrated in FIGS. 30A-30C comprises a semiconductor structure. The semiconductor structure comprises a memory die 900 comprising the memory array 920 including a plurality of word lines 46, the first bit lines 128 electrically connected to the memory array 920 and laterally extending along the bit line direction bld, and the array of memory-die bonding pads 988, wherein a first subset of the memory-die bonding pads 988 is electrically connected to a respective one of the first bit lines 128, and a second subset of the memory-die bonding pads 988 is electrically connected to a respective one of the word lines 46. The semiconductor structure also comprises a logic die 700 comprising the sense amplifiers 72S, the word line drivers 72W, the array of logic-die bonding pads 788 bonded to the memory-die bonding pads 988, the first electrically conductive paths ECP1 electrically connecting the sense amplifiers 72S to a first subset of the logic-die bonding pads 788, and the second electrically conductive paths ECP2 electrically connecting the word line drivers 72W to a second subset of the logic-die bonding pads 788. The first electrically conductive paths ECP1 comprise second bit lines 778 laterally extending along the bit line direction bld and crossed bit lines 728 laterally extending along the word line direction wld that is perpendicular the bit line direction bld. The second electrically conductive paths ECP2 comprise word-line-connection lines 748 which extend along the word line direction wld from an area within the first planar projection shape of the memory die 900 to an area within the first additional planar projection shape of the logic die 700 that is outside the memory die 900 in the plan view.

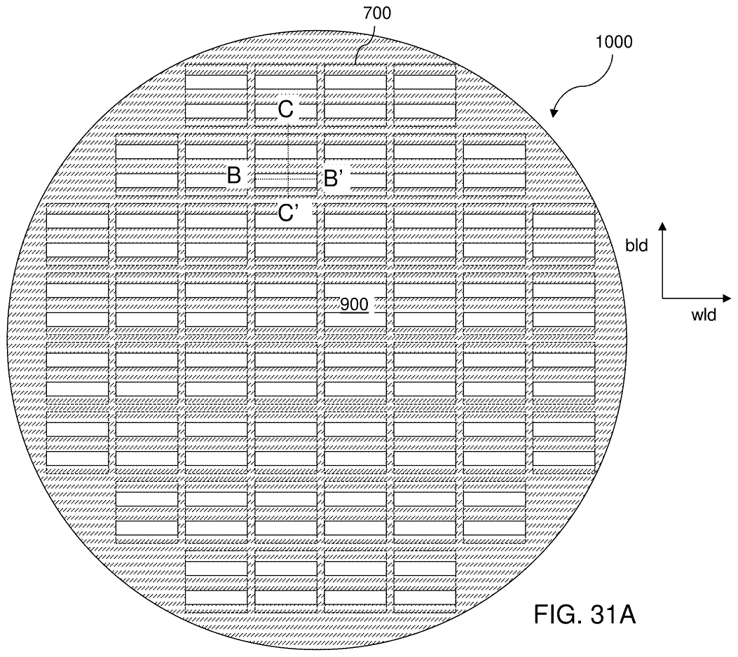

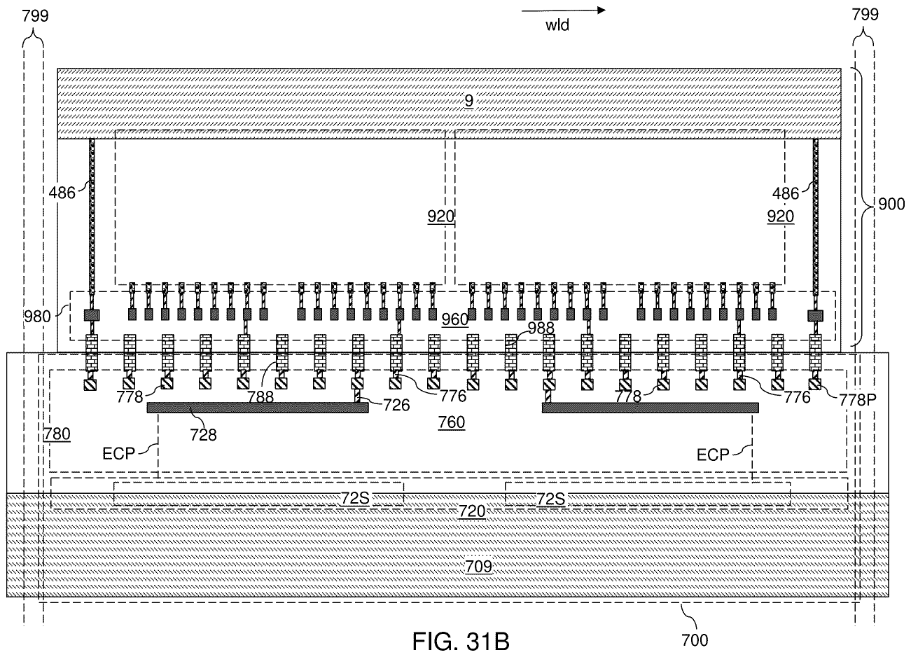

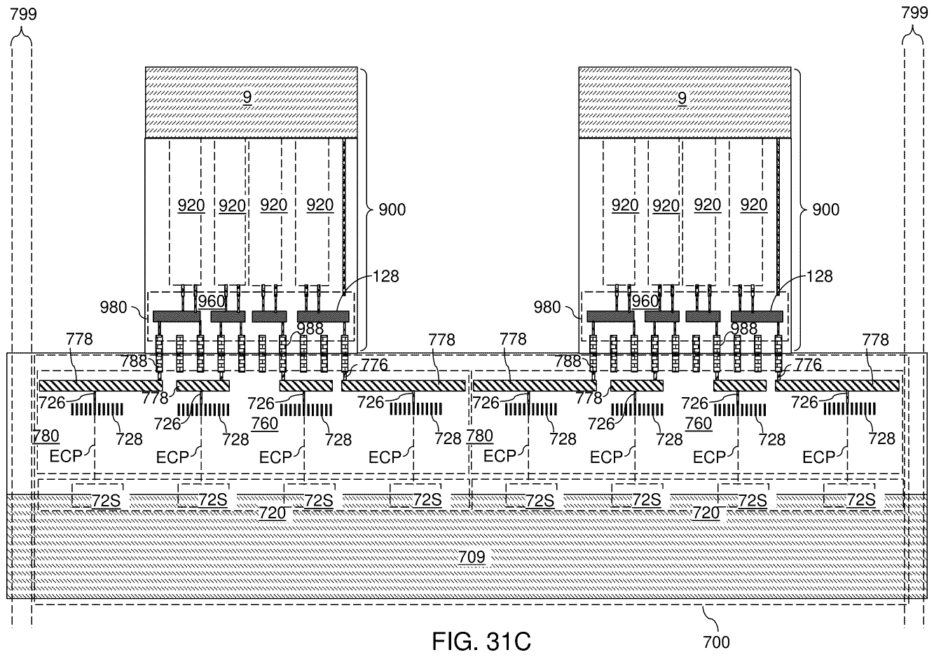

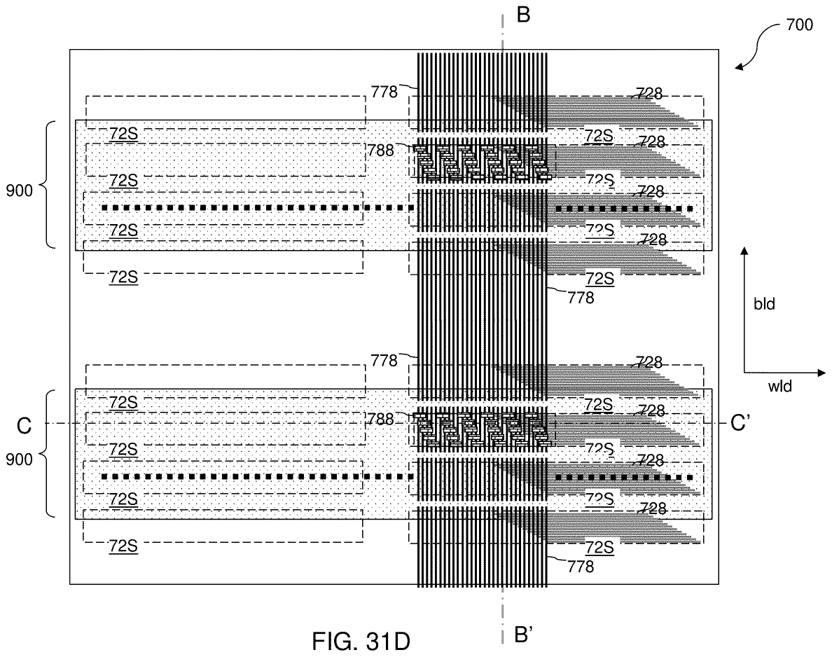

Referring to FIGS. 31A-31D, a third exemplary structure according to the third embodiment of the present disclosure can be derived from the first embodiment or from the second embodiment by bonding multiple memory dies 900 to a respective single logic die 700. In this case, the logic-die bonding pads 788 of each logic die 700 can be configured as a plurality of arrays of logic-die bonding pads 788. Each array of logic-die bonding pads 788 can be configured to bond with an array of memory-die bonding pads 988 of a respective memory die 900. Likewise, each memory die 900 may comprise a respective array of memory-die bonding pads 988 that is configured to bond with the array of logic-die bonding pads 788 of a respective one of the memory dies 900.

In the third embodiment, a plurality of memory dies 900 are provided. Each of the memory dies 900 comprises the memory array 920, the first bit lines 128 electrically connected to the memory array 920, and the array of memory-die bonding pads 988. A first subset of the memory-die bonding pads 988 is electrically connected to a respective one of the first bit lines 128. A wafer 1000 supporting a two-dimensional array of logic dies 700 is also provided. Each of the logic dies 700 comprises the sense amplifiers 72S, the array of logic-die bonding pads 788 bonded to the memory-die bonding pads 988, and the electrically conductive paths ECP electrically connecting the sense amplifiers 72S to the logic-die bonding pads 788 and comprising second bit lines 778. It should be understood that the word line drivers 72W, while not shown in FIGS. 31A-31D, are also present and are electrically connected via second electrically conductive paths to the word lines of the memory array 920, as described above.

A plurality of memory dies 900 can be bonded to each of the logic dies 700. Thus, for each logic die 700 supported by the wafer 1000, a respective plurality of memory dies 900 (e.g., two memory dies 900) can be bonded to the logic die 700 by performing a plurality of die-to-wafer bonding processes. The logic die 700 and the memory dies 900 are designed such that a subset of the second bit lines 778 laterally extend from first areas having an areal overlap with the plurality of memory dies 900 to a second area not having any areal overlap with the plurality of memory dies 900 in a plan view along a vertical direction that is perpendicular to interfaces between the logic die 700 and the plurality of memory dies 900. For each bonded assembly of a logic die 700 and a plurality of memory dies 900, the first areas correspond to the areas of the plurality of memory dies 900, and the second area corresponds to the region of the logic die 700 that does not have any areal overlap with the plurality of memory dies 700 in the plan view.

Generally, the first areas have first planar projection shapes in the plan view, and the second area has a second planar projection shape in the plan view. The second planar projection shape contains the entirety of the first planar projection shapes and a first additional planar projection shape located outside peripheries of the first planar projection shapes (which is the shape of the second area). In one embodiment, the plurality of memory dies 900 are bonded to the logic die 700 such that a first subset of the sense amplifiers 72S is located at least partly within the second area in the plan view, and a second subset of the sense amplifiers 72S is located entirely within the first areas in the plan view. In one embodiment, the first bit lines 128 laterally extend along the bit line direction bld, the second bit lines 778 laterally extend along the bit line direction bld, and a subset of the second bit lines 778 intersects a sidewall of a respective one of the plurality of memory dies 900 that is perpendicular to the bit line direction bld in the plan view.

The bonded assembly of the third exemplary structure comprises a semiconductor structure that contains a logic die 700 comprising the sense amplifiers 72S, the logic-die bonding pads 788, and the electrically conductive paths ECP electrically connecting the sense amplifiers 72S to the logic-die bonding pads 788. The semiconductor structure also includes a plurality of memory dies 900. Each of the plurality of memory dies 900 comprises a respective memory array 920, a respective set of first bit lines 128 electrically connected to the respective memory array 920, and a respective array of memory-die bonding pads 988, where each first bit line 128 within the respective set of first bit lines is electrically connected to a respective one of the memory-die bonding pads 988. Each array of memory-die bonding pads 988 of the plurality of memory dies 900 is bonded to a respective subset of the logic-die bonding pads 788. The electrically conductive paths ECP comprise second bit lines 778 located between the logic-die bonding pads 788 and the sense amplifiers 72S. A first subset of the second bit lines 778 laterally extends from within an area of one of the plurality of memory dies 900 to outside the area of said one of the plurality of memory dies 900 in a plan view along a vertical direction that is perpendicular to an interface between the logic die 700 and the plurality of memory dies 900.

In one embodiment, the memory dies 900 have first planar projection shapes in the plan view, and the logic die 700 has a second planar projection shape in the plan view. The second planar projection shape contains the entirety of the first planar projection shapes and a first additional planar projection shape located outside of peripheries of the first planar projection shapes. The first additional planar projection shape comprises a shape including multiple openings therethrough. The shape of each opening may be the projection shape of a respective one of the memory dies 900 as seen in the plan view along the vertical direction. In one embodiment, each of the first planar projection shapes is a respective rectangular shape, the first additional planar projection shape is a shape containing a plurality of rectangular openings therethrough, each of the plurality of rectangular openings having the same shape as a respective one of the first planar projection shapes.

In one embodiment, a plurality of second bit lines 778 within the first subset of the second bit lines 778 laterally extend from within the area of a respective one of the plurality of memory dies 900 through a region of the second planar projection shape and into an area of another of the plurality of memory dies 900. In one embodiment, a first subset of the sense amplifiers 72S is located at least partly within the first additional planar projection shape in the plan view, and a second subset of the sense amplifiers 72S is located entirely within the first planar projection shapes in the plan view.

In one embodiment, the first bit lines 128 laterally extend along a bit line direction bld, and the second bit lines 778 laterally extend along the bit line direction bld. In one embodiment, a subset of the second bit lines 778 intersects a respective sidewall of the memory die 900 that is perpendicular to the bit line direction bld in the plan view. In one embodiment, another subset of the second bit lines 778 may be located entirely within a respective first planar projection shape in the plan view.

In one embodiment, each logic die 700 may comprise crossed bit lines 728. Generally, the geometrical and electrical characteristics of the crossed bit lines 728 may be the same as any set of crossed bit lines 728 described with reference to previously described embodiments. In one embodiment, the electrically conductive paths ECP also include the crossed bit lines 728 located within the logic die 700 between the second bit lines 778 and the sense amplifiers 72S, and laterally extending along the word line direction wld that is perpendicular to the bit line direction bld.

In one embodiment, the electrically conductive paths ECP further comprise first metal via structures 726 connecting a respective one of the crossed bit lines 728 and a respective one of the second bit lines 778, and second metal via structures 776 connecting a respective one of the second bit lines 778 and a respective logic-die bonding pad 788. In one embodiment, the second metal via structures 776 are located entirely within the areas of the first planar projection shapes in the plan view.

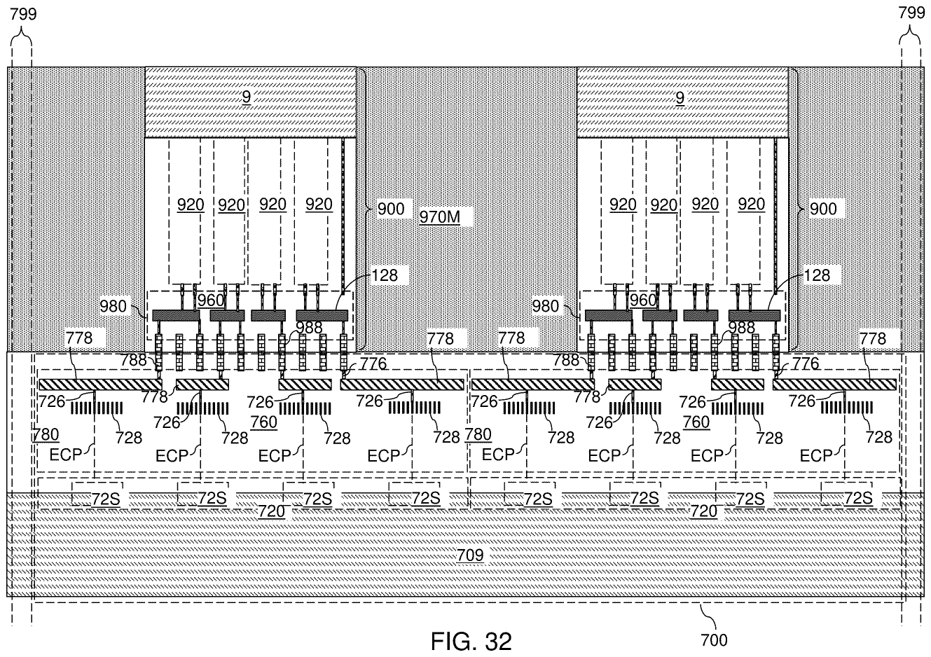

Referring to FIG. 32, the processing steps described with reference to FIG. 19 may be performed to form a molding compound matrix 970M. The molding compound matrix 970M laterally encloses each of the memory dies 900. The combination of the two-dimensional array of logic dies 700 sharing the logic-die substrate 709, the two-dimensional array of memory dies 900, and the molding compound matrix 970M constitutes a reconstituted wafer. The molding compound matrix 970M may be a continuous material layer that extends across the entirety of the area of the reconstituted wafer.

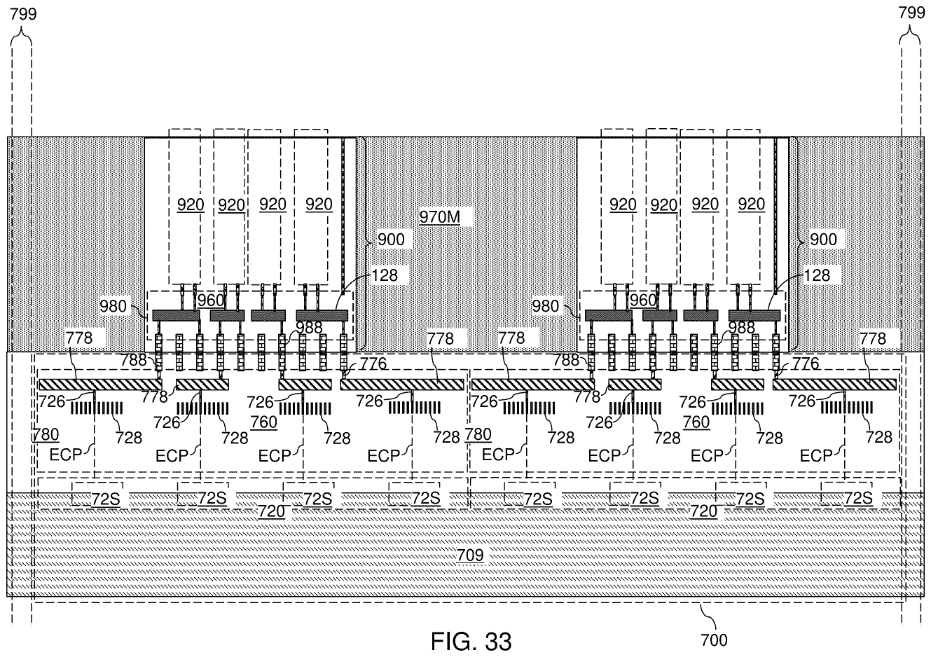

Referring to FIG. 33, the processing steps described with reference to FIGS. 20A and 20B may be performed to remove material portions overlying the horizontal plane including the backside surfaces of the alternating stacks (32, 46). For example, the entirety of the substrate 9 of each memory die 900 and excess portions of the molding compound matrix 970M that overlie the horizontal plane including the backside surfaces of the alternating stacks (32, 46) may be removed by performing a set of at least one material removal processes including a grinding process, a polishing process, an anisotropic etch process, and/or an isotropic etch process. In one embodiment, a terminal step of the set of at least one material removal process may comprise a chemical mechanical polishing process that removes the materials of the substrates 9 of the memory dies 900 and the molding compound matrix 970M selectively to the material of the insulating layers 32 and the stepped dielectric material portions 65. Physically exposed backside surfaces of the alternating stacks (32, 46), the stepped dielectric material portions 65, and the remaining portion of the molding compound matrix 970M may be located within a same horizontal plane. Generally, backside surfaces of the three-dimensional memory arrays 920 may be physically exposed. Further, end surfaces of the vertical semiconductor channels 60 and end surfaces of the connection via structures 486 may be physically exposed.

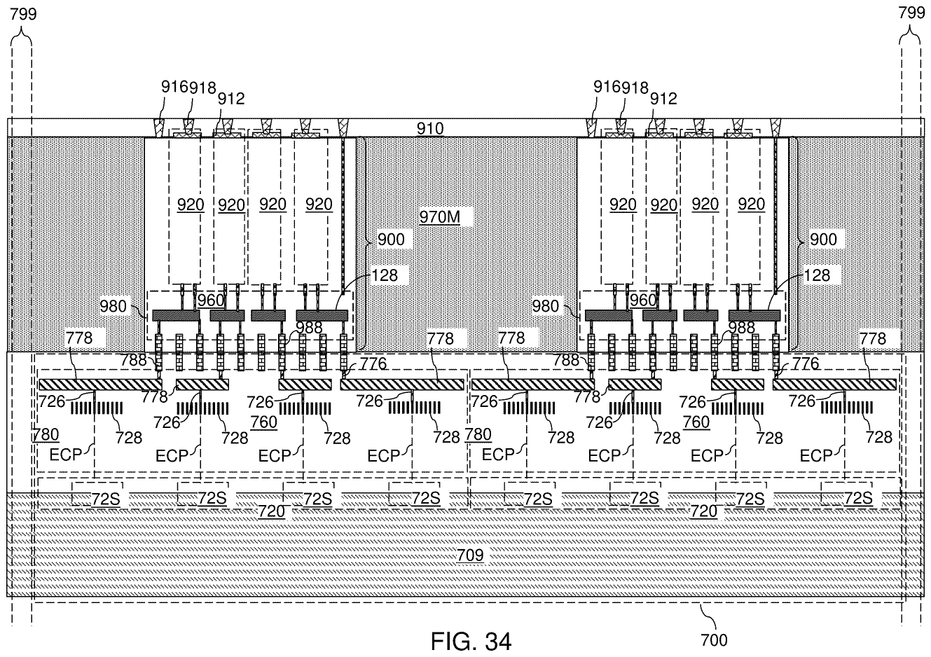

Referring to FIG. 34, at least one source layer 912 can be formed on each memory die 900 on the physically exposed bottom surfaces of a respective subset of the vertical semiconductor channels 60. A backside insulating layer 910 can be formed over the backside surfaces of the alternating stacks (32, 46), backside surfaces of the first stepped dielectric material portions 165, and the backside horizontal surface of the molding compound matrix 970M. The backside insulating layer 910 comprises an insulating material such as silicon oxide, silicon nitride, and/or polyimide.

Backside bonding pads (918, 916) can be formed within the backside insulating layer 910. The backside bonding pads (918, 916) may comprise source-connection backside bonding pads 918 that are electrically connected to a respective one of the source layers 912, and power-connection backside bonding pads 916 that are electrically connected to, and may contact, a respective subset of the connection via structures 486.

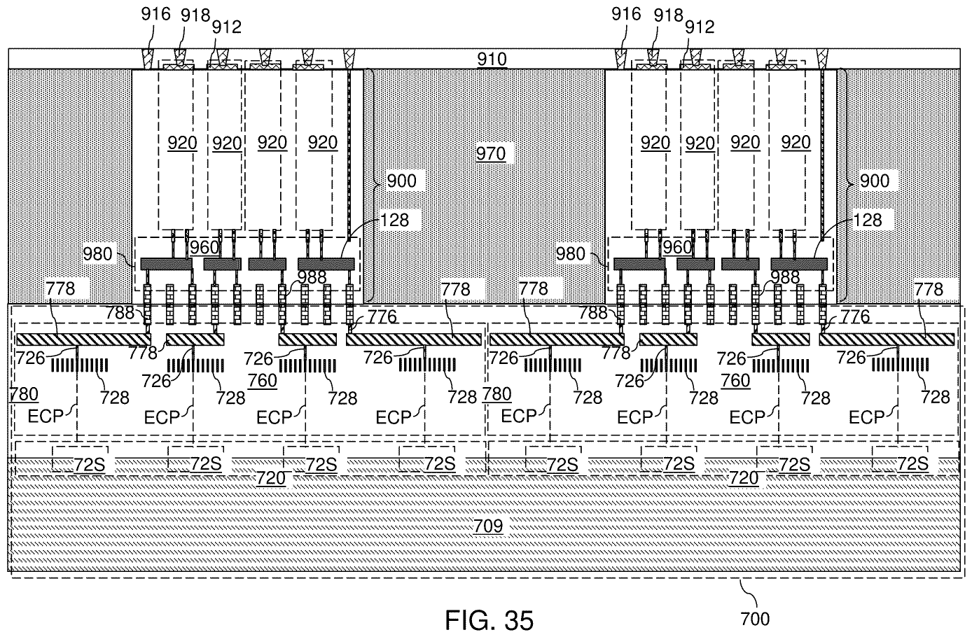

Referring to FIG. 35, the reconstituted wafer may be diced along the dicing channels 799. Each diced portion of the reconstituted wafer comprises a memory structure that includes a bonded assembly of a logic die 700, at least two memory dies 900, a molding compound frame 970, a backside insulating layer 910, and backside bonding pads (918, 916). Within the bonded assembly of FIG. 35, a backside insulating layer 910 can be located on planar surfaces of the plurality of memory dies 900 that are located on an opposite side of the logic die 700. The backside insulating layer 910 has a set of outer sidewalls that define a third planar projection shape containing the entirety of the first planar projection shapes and an additional planar projection shape located on the outside of the peripheries of the first planar projection shapes in the plan view. The third planar projection shape may be the same as the second planar projection shape if the sidewalls of the logic die 700 are vertically coincident with the set of outer sidewalls of the backside insulating layer 910.

Referring collectively to FIGS. 31A-35 and related drawings and according to various embodiment of the present disclosure, a semiconductor structure comprises: a logic die 700 comprising sense amplifiers 72S, logic-die bonding pads 788, and electrically conductive paths ECP electrically connecting the sense amplifiers 72S to the logic-die bonding pads 788; and a plurality of memory dies 900 bonded to the logic die 700. Each of the plurality of memory dies 900 comprises a respective memory array 920, a respective set of first bit lines 128 electrically connected to the respective memory array 920, and a respective array of memory-die bonding pads 988, wherein each first bit line 128 within the respective set of first bit lines is electrically connected to a respective one of the memory-die bonding pads 988. Each array of memory-die bonding pads 988 of the plurality of memory dies 900 is bonded to a respective subset of the logic-die bonding pads 788; the electrically conductive paths ECP comprise second bit lines 778 located between the logic-die bonding pads 788 and the sense amplifiers 72S; and a first subset of the second bit lines 778 laterally extends from within an area of one of the plurality of memory dies 900 to outside the area of said one of the plurality of memory dies 900 in a plan view along a vertical direction that is perpendicular to an interface between the logic die 700 and the plurality of memory dies 900.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A semiconductor structure, comprising:
a memory die comprising a memory array, first bit lines electrically connected to the memory array, and an array of memory-die bonding pads, wherein a first subset of the memory-die bonding pads is electrically connected to a respective one of the first bit lines; and
a logic die comprising sense amplifiers, an array of logic-die bonding pads bonded to the memory-die bonding pads, and electrically conductive paths electrically connecting the sense amplifiers to the logic-die bonding pads, wherein the electrically conductive paths comprise second bit lines located between the logic-die bonding pads and the sense amplifiers and laterally extending from within an area of the memory die to an area beyond the memory die.

2. The semiconductor structure of claim 1, wherein:
the memory die has a first planar projection shape in a plan view along a vertical direction;
the logic die has a second planar projection shape in the plan view, wherein the second planar projection shape contains an entirety of the first planar projection shape and a first additional planar projection shape located on an outside of a periphery of the first planar projection shape; and
the second bit lines extend from an area within the first planar projection shape to an area within the first additional planar projection shape in the plan view.

3. The semiconductor structure of claim 2, wherein:
a first subset of the sense amplifiers is located at least partly within the first additional planar projection shape in the plan view; and
a second subset of the sense amplifiers is located entirely within the first planar projection shape in the plan view.

4. The semiconductor structure of claim 2, wherein:
the first bit lines laterally extend along a bit line direction; and
the second bit lines laterally extend along the bit line direction.

5. The semiconductor structure of claim 4, wherein a subset of the second bit lines intersect a respective sidewall within a pair of parallel sidewalls of the memory die that are perpendicular to the bit line direction in the plan view.

6. The semiconductor structure of claim 4, wherein the electrically conductive paths are electrically connected to a first subset of the logic-die bonding pads which is bonded to the first subset of the memory-die bonding pads.

7. The semiconductor structure of claim 6, wherein the electrically conductive paths further comprise crossed bit lines located within the logic die between the second bit lines and the sense amplifiers, and laterally extending along a word line direction that is perpendicular to the bit line direction.

8. The semiconductor structure of claim 7, wherein the electrically conductive paths further comprise:
first metal via structures connecting a respective one of the crossed bit lines and a respective one of the second bit lines; and
second metal via structures connecting a respective one of the second bit lines and a respective logic-die bonding pad.

9. The semiconductor structure of claim 8, wherein the second metal via structures are located entirely within the area of the first planar projection shape in the plan view.

10. The semiconductor structure of claim 2, wherein:
the first planar projection shape is a first rectangular shape; and
the first additional planar projection shape is a frame-shaped shape that is derived from a second rectangular shape by removing an area of the first rectangular shape.

11. The semiconductor structure of claim 2, further comprising a backside insulating layer located on a planar surface of the memory die that is located on an opposite side of the logic die, wherein the backside insulating layer has a set of outer sidewalls that defines a third planar projection shape containing the entirety of the first planar projection shape and a second additional planar projection shape located on the outside of the periphery of the first planar projection shape in the plan view.

12. The semiconductor structure of claim 11, further comprising backside bonding pads embedded within the backside insulating layer, wherein one of the backside bonding pads is electrically connected to one of the logic-die bonding pads through one of the memory-die bonding pads and through a subset of memory-die metal interconnect structures within the memory die.

13. The semiconductor structure of claim 2, further comprising a molding compound frame laterally surrounding the memory die and contacting a horizontal surface of the logic die.

14. The semiconductor structure of claim 13, wherein outer sidewalls of the molding compound frame are located within a set of vertical planes that defines a planar projection shape that is the same as the second planar projection shape in the plan view.

15. The semiconductor structure of claim 1, wherein the memory array comprises:
an alternating stack of insulating layers and electrically conductive layers;
memory openings vertically extending through the alternating stack; and
memory opening fill structures located in the memory openings, wherein each of the memory opening fill structures comprises a respective vertical stack of memory elements located at levels of the electrically conductive layers and a vertical semiconductor channel.

16. A method of forming a semiconductor structure, comprising:
providing a memory die comprising a memory array, first bit lines electrically connected to the memory array, and an array of memory-die bonding pads, wherein a first subset of the memory-die bonding pads is electrically connected to a respective one of the first bit lines;
providing a wafer including a two-dimensional array of logic dies, wherein one of the logic dies comprises sense amplifiers, an array of logic-die bonding pads bonded to the memory-die bonding pads, and electrically conductive paths electrically connecting the sense amplifiers to the logic-die bonding pads; and
bonding the array of memory-die bonding pads of the memory die to the array of logic-die bonding pads of said one of the logic dies by performing a die-to-wafer bonding process, such that the electrically conductive paths comprise second bit lines located between the logic-die bonding pads and the sense amplifiers and laterally extending from within an area of the memory die to an area beyond the memory die.

17. The method of claim 16, wherein:
the memory die has a first planar projection shape in a plan view along a vertical direction;
the logic die has a second planar projection shape in the plan view, wherein the second planar projection shape contains an entirety of the first planar projection shape and a first additional planar projection shape located on an outside of a periphery of the first planar projection shape;
the second bit lines extend from an area within the first planar projection shape to an area within the first additional planar projection shape in the plan view;
a first subset of the sense amplifiers is located at least partly within the first additional planar projection shape in the plan view; and
a second subset of the sense amplifiers is located entirely within the first planar projection shape in the plan view.

18. The method of claim 17, wherein:
the first bit lines laterally extend along a bit line direction;
the second bit lines laterally extend along the bit line direction; and
a subset of the second bit lines intersect a respective sidewall of the memory die that is perpendicular to the bit line direction in the plan view.

19. The method of claim 18, wherein the electrically conductive paths further comprise crossed bit lines located within the logic die between the second bit lines and the sense amplifiers, and laterally extending along a word line direction that is perpendicular to the bit line direction.

20. The method of claim 16, further comprising:
bonding additional memory dies to additional logic dies supported by the wafer other than the one of the logic dies;
forming a molding compound matrix around the memory die and the additional memory dies over the wafer; and
forming a combination of a backside insulating layer and backside bonding pads on planar surfaces of the memory die and the additional memory dies; and
dicing a combination including the wafer, the molding compound matrix, and the backside insulating layer, to form diced bonded assemblies including a bonded pair of a respective one of the logic dies and a respective one of the memory die or one of the additional memory dies.
